(19) United States
(12) Patent Application Publication
(10) Pub. No.: US 2025/0014973 A1
(43) Pub. Date: Jan. 9, 2025

(54) POWER PACKAGE CONFIGURED WITH ADDITIONAL FUNCTIONALITY

(71) Applicant: WOLFSPEED, INC., Durham, NC (US)

(72) Inventors: Paul WHEELER, Allen, TX (US); Brice MCPHERSON, Fayetteville, AR (US); Roberto Marcelo SCHUPBACH, Fayetteville, AR (US); Leonardo MONTOYA, Munich (DE); Brandon PASSMORE, Durham, NC (US); Mohammad Hazzaz MAHMUD, Durham, NC (US); Ben SAMPLES, Durham, NC (US); Prasana Obala BHUVANESH, Leander, TX (US); Ajit R. KANALE, Raleigh, NC (US)

(21) Appl. No.: 18/346,561

(22) Filed: Jul. 3, 2023

(51) Int. Cl. H01L 23/498; H01L 25/07; H01L 25/18

(52) U.S. Cl. CPC H01L 23/49811; H01L 23/49844; H01L 25/072; H01L 25/18; H01L 23/34; H01L 24/40; H01L 24/48; H01L 2224/40137; H01L 2224/40225; H01L 2224/48091; H01L 2224/48137; H01L 2224/48139; H01L 2224/48145; H01L 2224/48225

(57) ABSTRACT

A device includes a power substrate and a first power device on the power substrate. A housing having housing sides having at least a first housing side and a second housing side, the housing configured to house at least the power substrate and the first power device. A plurality of power terminals extending from at least one of the housing sides. The plurality of power terminals having at least a first power terminal and a second power terminal. A plurality of signal terminals extending from at least one of the housing sides. The plurality of signal terminals having at least a source kelvin signal terminal, a gate driver signal terminal, and at least one additional signal terminal.

### BACKGROUND OF THE DISCLOSURE

Power electronics packages typically implement one or more power devices, such as Silicon Carbide (SiC) power devices, which offer a high level of performance benefits, including high voltage blocking, low on-resistance, high current, fast switching, low switching losses, high junction temperatures, and high thermal conductivity. Ultimately, these power device characteristics result in a notable increase in potential power density, which is power processed per area or volume. However, typical power electronics packages have limited functionality and/or capabilities.

Accordingly, what is needed is power electronics packages which implement layouts, structures, and/or configurations that can provide increased functionality and/or capability.

### SUMMARY OF THE DISCLOSURE

In one aspect, a power package includes a power substrate. The power package in addition includes a first power device on the power substrate. The package moreover includes a housing having housing sides having at least a first housing side and a second housing side, the housing configured to house at least the power substrate and the first power device. The package also includes a plurality of power terminals extending from at least one of the housing sides. The package further includes the plurality of power terminals having at least a first power terminal and a second power terminal. The package in addition includes a plurality of signal terminals extending from at least one of the housing sides. The package moreover includes the plurality of signal terminals having at least a source kelvin signal terminal, a gate driver signal terminal, and at least one additional signal terminal.

In one aspect, a power package includes a power substrate. The power package in addition includes a first power device on the power substrate. The package moreover includes a housing having housing sides having at least a first housing side and a second housing side, the housing 200 configured to house at least the power substrate and the first power device. The package also includes a plurality of power terminals extending from at least one of the housing sides. The package further includes the plurality of power terminals having at least a first power terminal and a second power terminal. The package in addition includes a plurality of signal terminals extending from at least one of the housing sides. The package moreover includes the plurality of signal terminals having at least a source kelvin signal terminal and a gate driver signal terminal. The package also includes a common source connection connected between the first power device and a second power device.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a top side perspective view of an external configuration a power package according to aspects of the disclosure.

FIG. 2 illustrates a top side view of an external configuration a power package according to FIG. 1.

FIG. 3 illustrates a top view of a configuration of a plurality of implementations of the power package according to FIG. 1.

FIG. 4 illustrates a top view of a configuration of a plurality of implementations of the power package according to FIG. 1.

FIG. 5A illustrates a partial top view of the power package according to aspects of the disclosure.

FIG. 5B illustrates a partial schematic of the power package according to FIG. 5A.

FIG. 6 illustrates a partial top perspective view of the power package according to aspects of the disclosure.

FIG. 7 illustrates a partial top view of the power package according to aspects of the disclosure.

FIG. 8 illustrates a partial top perspective view of the power package according to aspects of the disclosure.

FIG. 9 illustrates a partial top view of the power package according to aspects of the disclosure.

FIG. 10 illustrates a partial top view of the power package according to aspects of the disclosure.

FIG. 11 illustrates a partial top view of the power package according to aspects of the disclosure.

FIG. 12 illustrates a partial top perspective view of the power package according to aspects of the disclosure.

FIG. 13 illustrates various arrangements of a plurality of power terminals and/or a plurality of signal terminals within various implementations of a power package according to aspects of the disclosure.

FIG. 14 illustrates a top view of a configuration of a plurality of implementations of the power package according to FIG. 1.

FIG. 15 illustrates a top side view of an external configuration of the power package according to FIG. 1.

FIG. 16 illustrates a schematic of the power package according to FIG. 15.

FIG. 17 illustrates a top side view of an external configuration of the power package according to FIG. 1.

FIG. 18 illustrates a top side view of an external configuration of the power package according to FIG. 1.

FIG. 19 illustrates a schematic of the power package according to FIG. 18.

FIG. 20 illustrates a top side view of an external configuration of the power package according to FIG. 1.

FIG. 21 illustrates a top perspective view of the power package according to FIG. 1.

FIG. 22 illustrates a side view of the power package according to FIG. 21.

FIG. 23 illustrates a top view of a power package according to aspects of the disclosure.

FIG. 24 illustrates a top view of a power package according to aspects of the disclosure.

FIG. 25 illustrates a schematic of a power package according to aspects of the disclosure.

FIG. 26 illustrates a partial perspective top view of a package according to the disclosure.

FIG. 27 illustrates a perspective view of the package according to FIG. 26.

FIG. 28 illustrates a perspective bottom view of the package according to FIG. 26.

FIG. 29 illustrates a schematic of a cascode configuration according to aspects of the disclosure.

FIG. 30 illustrates a perspective view of a cascode configuration according to FIG. 29.

FIG. 31 illustrates a top view of a power package implementing the cascode configuration according to FIG. 29.

FIG. 32 illustrates a partial perspective view of a power package implementing the cascode configuration according to FIG. 29.

FIG. 33 illustrates a partial perspective view of a power package implementing the cascode configuration according to FIG. 29.

FIG. 34 illustrates a top view of a power package implementing the cascode configuration according to FIG. 29.

FIG. 35 illustrates a partial top perspective view of the power package according to FIG. 34.

FIG. 36 illustrates a perspective view of an implementation of a power substrate according to aspects of the disclosure.

FIG. 37 illustrates a perspective view of another implementation of a power substrate 402 according to aspects of the disclosure.

FIG. 38 illustrates a perspective view of an implementation of a power package according to aspects of the disclosure.

FIG. 39 illustrates a partial perspective view of the power package of FIG. 38.

FIG. 40 illustrates a partial perspective view of the power package of FIG. 38.

FIG. 41 illustrates a partial top of a power package according to aspects of the disclosure.

FIG. 42 illustrates a partial perspective view of the power package of FIG. 41.

FIG. 43 illustrates a partial perspective view of the power package of FIG. 41.

FIG. 44 illustrates a partial top of a power package according to aspects of the disclosure.

FIG. 45 illustrates a partial perspective view of the power package of FIG. 44.

FIG. 46 illustrates a partial perspective view of the power package of FIG. 44.

FIG. 47 illustrates a partial top of a power package according to aspects of the disclosure.

FIG. 48 illustrates a partial perspective view of the power package of FIG. 47.

FIG. 49 illustrates a top view of a power package to aspects of the disclosure.

FIG. 50 illustrates a side view of the power package according to FIG. 49.

FIG. 51 illustrates a configuration of two implementations of a power package according to aspects of the disclosure.

FIG. 52 illustrates a configuration of implementations of a power package according to aspects of the disclosure.

FIG. 53 illustrates a configuration of implementations of a power package according to aspects of the disclosure.

FIG. 54 illustrates a configuration of multiple implementations of a power package according to aspects of the disclosure.

FIG. 55 illustrates a configuration of multiple implementations of a power package according to aspects of the disclosure.

FIG. 56 illustrates a topside view of a configuration of multiple implementations of a power package according to aspects of the disclosure.

FIG. 57 illustrates a backside view of the configuration of multiple implementations of a power package according to FIG. 56.

FIG. 58 illustrates a cross-sectional view of a configuration of multiple implementations of a power package according to aspects of the disclosure.

FIG. 59 illustrates a perspective view of the configuration of multiple implementations of a power package according to FIG. 58.

FIG. 60 illustrates a perspective view of an implementation of a power substrate according to aspects of the disclosure.

FIG. 61 illustrates a perspective view of another implementation of a power substrate according to aspects of the disclosure.

FIG. 62 illustrates a top view of an implementation of a power package according to aspects of the disclosure.

FIG. 63 illustrates a perspective view of an implementation of a power package according to FIG. 62.

FIG. 64 illustrates a top view of a power package according to aspects of the disclosure.

FIG. 65 illustrates a top perspective view of the power package according to FIG. 64.

FIG. 66 illustrates a top view of a power package according to aspects of the disclosure.

FIG. 67 illustrates a top perspective view of the power package according to FIG. 66.

FIG. 68 illustrates a partial top of a power package according to aspects of the disclosure.

FIG. 69 illustrates a partial perspective view of the power package of FIG. 68.

FIG. 70 illustrates a top view of a power package to aspects of the disclosure.

FIG. 71 illustrates a side view of the power package according to FIG. 70.

FIG. 72 illustrates a configuration of two implementations of a power package according to aspects of the disclosure.

FIG. 73 illustrates a configuration of implementations of a power package according to aspects of the disclosure.

FIG. 74 illustrates a configuration of two implementations of a power package according to aspects of the disclosure.

FIG. 75 illustrates a partial top of a power package according to aspects of the disclosure.

FIG. 76 illustrates a partial perspective view of the power package of FIG. 75.

FIG. 77 illustrates a partial perspective view of the power package of FIG. 75.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

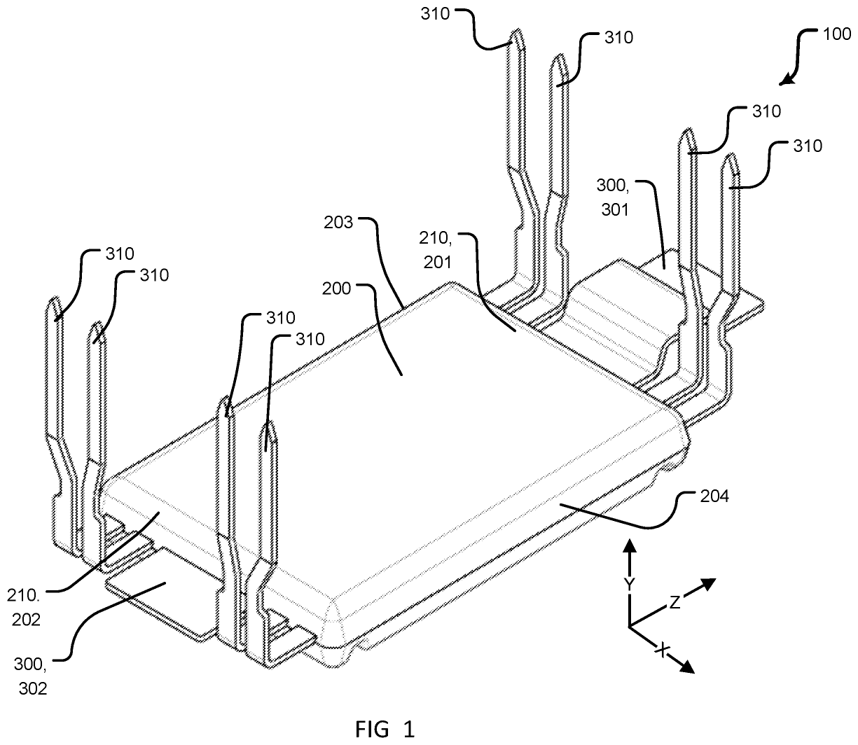

FIG. 1 illustrates a top side perspective view of an external configuration a power package according to aspects of the disclosure.

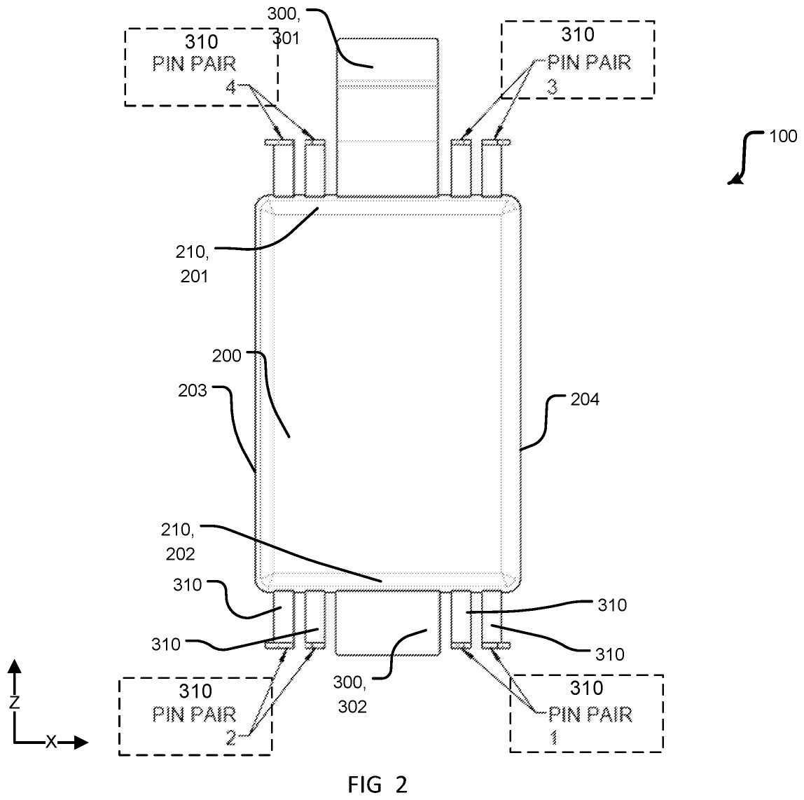

FIG. 2 illustrates a top side view of an external configuration a power package according to FIG. 1. In particular, FIG. 1 illustrates a power package 100 that may include a housing 200 having housing sides 210 that may include at least a first housing side 201, a second housing side 202, a third housing side 203, and a fourth housing side 204. In aspects, the first housing side 201 may be connected to the third housing side 203 and the fourth housing side 204; and the second housing side 202 may be connected to the third housing side 203 and the fourth housing side 204. Further, the housing 200 may be configured with corners between the first housing side 201 and the third housing side 203, the first housing side 201 and the fourth housing side 204, the second housing side 202 and the third housing side 203, and the second housing side 202 and the fourth housing side 204.

Additionally, the power package 100 may include a plurality of power terminals 300 extending from at least one of the housing sides 210. The plurality of power terminals 300 may include at least a first power terminal 301 and a second power terminal 302.

Further, the power package 100 may include a plurality of signal terminals 310 extending from at least one of the housing sides 210. In aspects, the plurality of signal terminals 310 may include at least a source kelvin signal terminal, a gate driver signal terminal, and optionally may include at least one additional signal terminal.

In one aspect, the first power terminal 301 may extend from the first housing side 201 and the second power terminal 302 may extend from the second housing side 202; and at least one of the plurality of signal terminals 310 may extend from the first housing side 201 and at least one of the plurality of signal terminals 310 may extend from the second housing side 202. In other aspects of the power package 100, the plurality of power terminals 300 and/or the plurality of signal terminals 310 may be implemented with other configurations.

In aspects, the power package 100 may implement the plurality of signal terminals 310 to include at least one additional electrical terminal that may be configured to deliver additional capabilities to the power package 100 that may include current protection, such as overcurrent protection, desaturation protection, and/or the like. Further, the power package 100 may implement at least one additional electrical terminal that may be configured to deliver additional capabilities in temperature sensing, current sensing, and/or the like. In aspects, the at least one additional electrical terminal may be configured to provide more insight into what is happening inside of the power package 100.

In aspects of the power package 100, the plurality of power terminals 300 may be modified in size to allow room for the at least one additional electrical terminal. For example, a width of the plurality of power terminals 300 may be reduced along the X axis as illustrated in FIG. 2. In aspects, the power package 100 may be implemented as a four terminal single switch package implementation of the power package 100.

With reference to FIG. 1 and FIG. 2, a pinout of the plurality of signal terminals 310 with four potential pin positions is illustrated that may be utilized for features as described herein. However, the power package 100 may implement any number of the plurality of signal terminals 310 described herein.

In aspects, all of the pin positions of the plurality of signal terminals 310 of the power package 100 may be used, some of which only some of these pin positions are used for the power package 100. In some embodiments, only the necessary pins of the power package 100 would be used, with the rest of the room used by the plurality of power terminals 300. In other embodiments, all pins are present and used for a function. In other embodiments, all pin positions are present but only some are used for a function.

Further, the additional pins/functionality/flexibility may be used in the disclosed implementation of the power package 100. Further, any similar generic package layout may be implemented with the disclosed implementations of the plurality of power terminals 300 and/or the plurality of signal terminals 310 and associated functionality of the power package 100.

In aspects, the first power terminal 301 may extend from the first housing side 201 and the second power terminal 302 may extend from the second housing side 202. In aspects, the first power terminal 301 may extend from the second housing side 202 and the second power terminal 302 may extend from the first housing side 201.

In aspects, some of the plurality of signal terminals 310 may extend from the first housing side 201 and some of the plurality of signal terminals 310 may extend from the second housing side 202. In aspects, all of the plurality of signal terminals 310 may extend from the second housing side 202. In aspects, all of the plurality of signal terminals 310 may extend from the first housing side 201.

In aspects, at least two of the plurality of signal terminals 310 may extend from the first housing side 201 and at least two of the plurality of signal terminals 310 may extend from the second housing side 202. In aspects, at least two of the plurality of signal terminals 310 may extend from the second housing side 202 and at least two of the plurality of signal terminals 310 may extend from the first housing side 201.

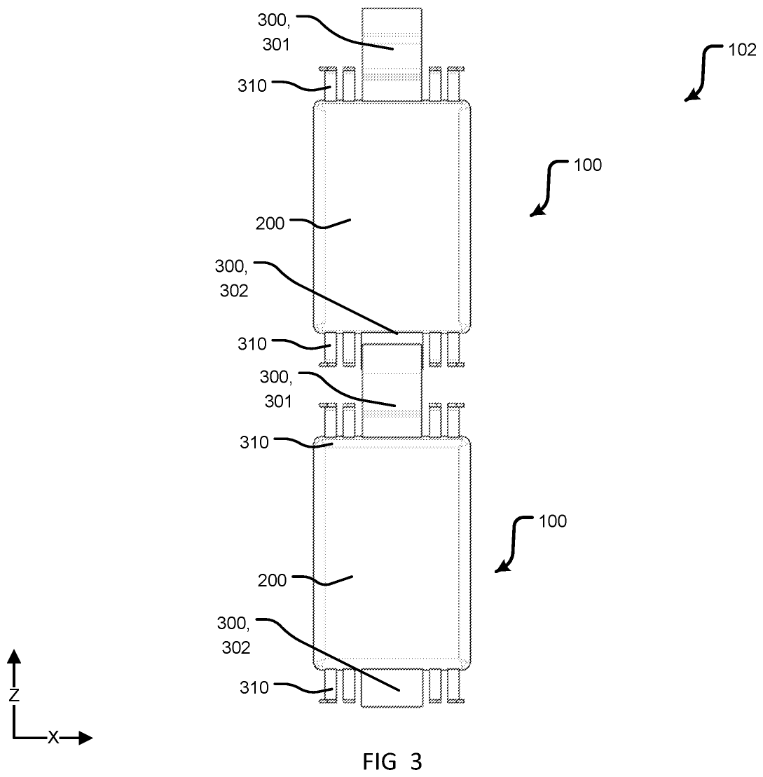

FIG. 3 illustrates a top view of a configuration of a plurality of implementations of the power package according to FIG. 1.

In particular, FIG. 3 illustrates a top view of a configuration 102 of a plurality of implementations of the power package 100 according to FIG. 1. In this regard, additional flexibility may be found in implementing arrangements of the power package 100 to form topologies, such as a half-bridge topology, a common source topology, and/or the like. In such aspects, the plurality of signal terminals 310 may be implemented as single pins, and/or pairs of pins depending on the type of electrical connection and isolation required by the configuration 102. Additionally, aspects of the power package 100 implementing a common source topology may include any and all aspects of the common source topology implementations of the power package 100 described herein.

As illustrated in FIG. 3, the configuration 102 may have a plurality of implementations of the power package 100. In aspects, the plurality of implementations of the power package 100 may be arranged in a bridge leg configuration topology. In this regard, the first power terminal 301 of one implementation of the power package 100 may connect to the second power terminal 302 of another implementation of the power package 100 as illustrated in FIG. 3 to provide the desired topology implementation.

In other aspects, the power package 100 and/or a configuration implementing a plurality of the power package 100 may implement any number of topologies. For example, the power package 100 and/or a configuration implementing a plurality of the power package 100 may implement a single switch topology, a half bridge topology, a full bridge topology, a common source topology, a common drain topology, a three phase bridge topology, a 3 level inverter T-Type topology, a 3 level inverter NPC (neutral point clamped) topology, a 3 level inverter VSC (voltage source converter) topology, a buck topology, a boost topology, a buck-boost topology, and/or a Ćuk topology.

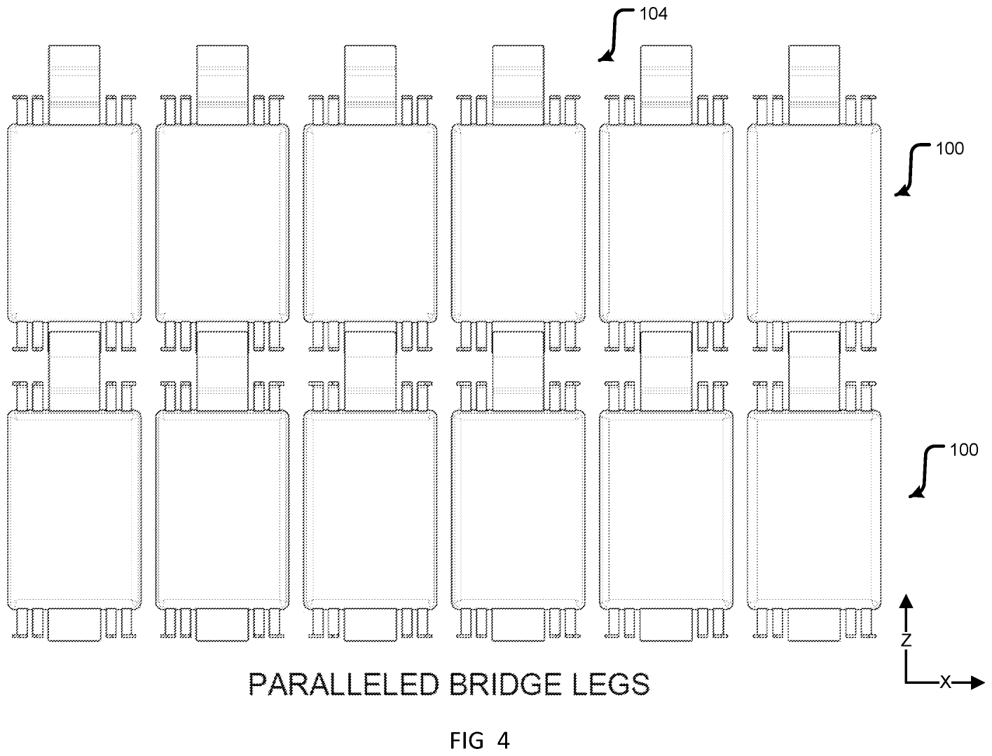

FIG. 4 illustrates a top view of a configuration of a plurality of implementations of the power package according to FIG. 1.

In particular, FIG. 4 illustrates a top view of a configuration 104 of a plurality of implementations of the power package 100 according to FIG. 1. As illustrated in FIG. 4, the configuration 104 of a plurality of implementations of the power package 100 may be arranged in paralleled bridge leg configuration topologies. In this regard, the first power terminal 301 of implementations of the power package 100 may connect to the second power terminal 302 of other implementations of the power package 100 as illustrated in FIG. 4 to provide the desired topology implementation.

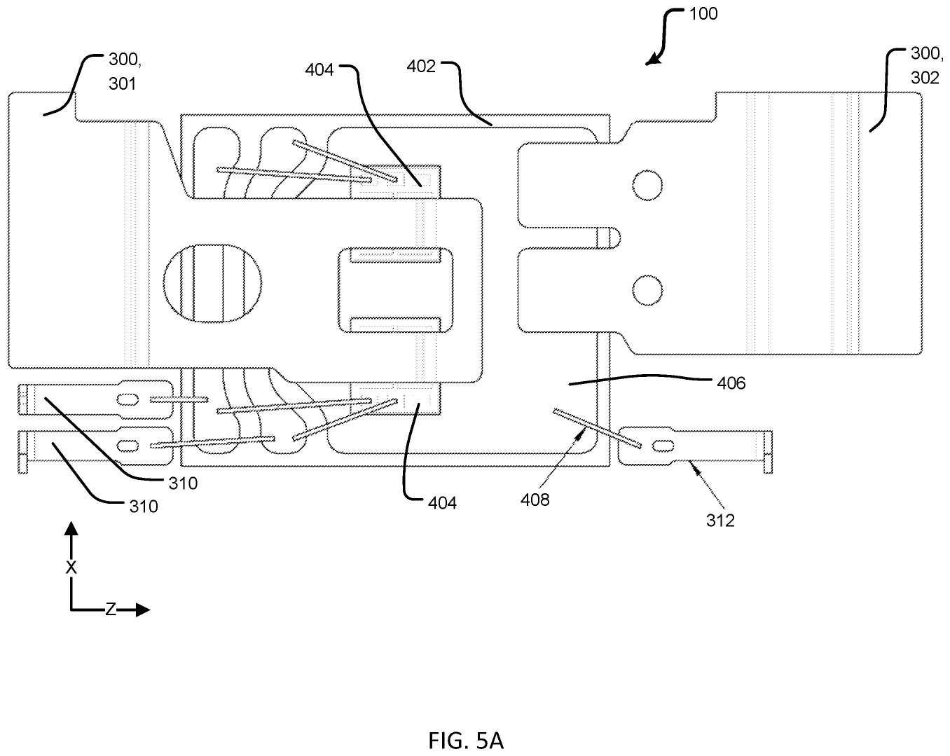

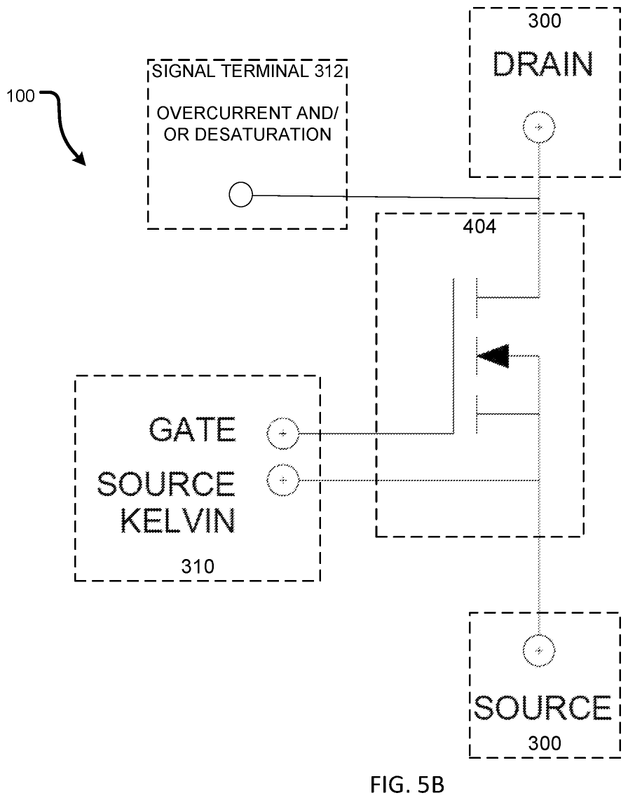

FIG. 5A illustrates a partial top view of the power package according to aspects of the disclosure.

FIG. 5B illustrates a partial schematic of the power package according to FIG. 5A.

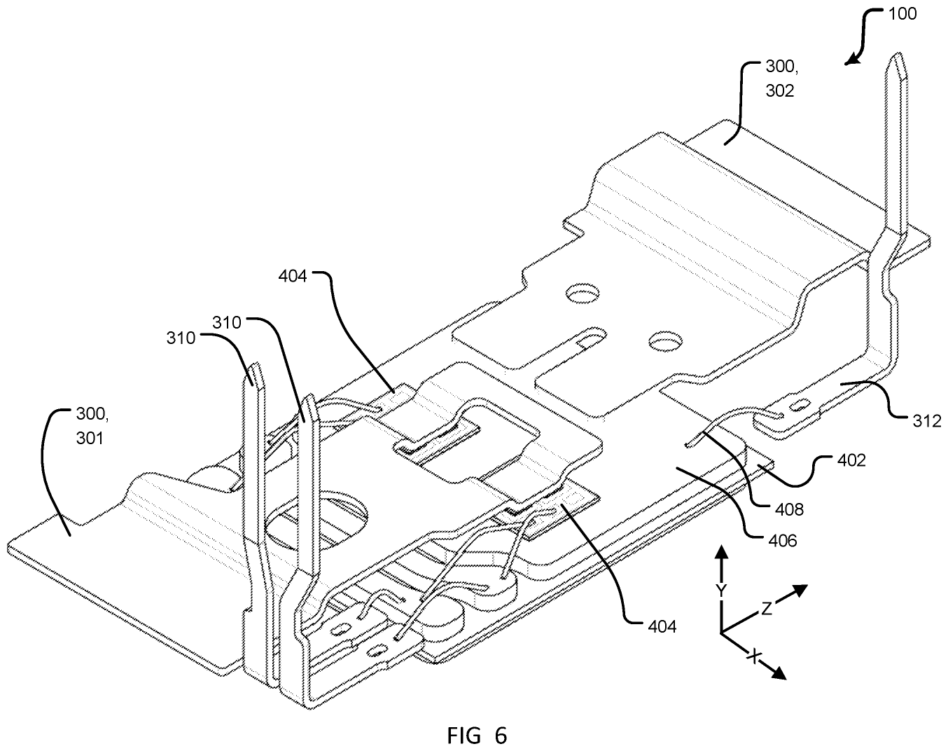

FIG. 6 illustrates a partial top perspective view of the power package according to aspects of the disclosure.

In particular, FIG. 5A illustrates a partial top view of the power package 100 according to aspects of the disclosure. The power package 100 may further include a power substrate 402 and at least one power device 404 on the power substrate 402. Further, the at least one power device 404 may include a plurality of implementations of the at least one power device 404. Additionally, the housing 200 illustrated in FIG. 1 (not shown in FIG. 5A) may be configured to house at least the power substrate 402 and the at least one power device 404. Additionally, FIG. 5B illustrates a partial schematic of the power package 100 according to FIG. 5A.

As further illustrated in FIG. 5A, the power package 100 may be configured with the plurality of signal terminals 310. In aspects, at least one implementation of the plurality of signal terminals 310 may be configured as an at least one additional signal terminal 312. In aspects, the at least one additional signal terminal 312 may be configured as an overcurrent/desaturation signal terminal configured to provide overcurrent signals and/or desaturation signals from the power package 100.

In aspects, the at least one additional signal terminal 312 may be configured as a signal pin that may connect to a drain pad 406 on the power substrate 402. In aspects, the at least one additional signal terminal 312 may be configured to allow for a gate driver, a controller, measurement/instrumentation circuitry and/or the like to monitor a voltage across a switch position that includes the at least one power device 404. In aspects, the monitored voltage may be used as a protective feature against short circuit current events associated with the power package 100, overcurrent protection for the power package 100, and/or desaturation protection for the power package 100. In this regard, the at least one power device 404 is on, a voltage drop is typically proportional a current. Depending on device type and semiconductor characteristics, the relationship between is a nonlinear curve as the at least one power device 404 saturates. This relationship can be used to predict a short circuit event where the current exceeds a safe threshold.

An example of a desaturation pin implemented by the at least one additional signal terminal 312 is illustrated in FIG. 5A. In this regard, only one pin may be needed for this functionality. However, in other implementations two pins may be used for other reasons, such as symmetry, redundancy, etc. Other embodiments may position the at least one additional signal terminal 312 on the other side the power package 100 in either location, depending on specific configuration of the power package 100.

In aspects, the at least one additional signal terminal 312 may be electrically connected to the drain pad 406 of the power substrate 402 with an interconnect 408. In aspects, the interconnect 408 may be a wire bond between the at least one additional signal terminal 312 and the drain pad 406. In aspects, the at least one additional signal terminal 312 may also be structured and arranged to extend over the power substrate 402; and the at least one additional signal terminal 312 may be soldered, welded, sintered, and/or the like in place to form a connection to the power substrate 402. Additionally, the at least one additional signal terminal 312 may also be attached directly to the drain pad 406. In aspects, implementations of the interconnect 408 as described herein may use any type of interconnect configuration and/or interconnect process. In aspects, an interconnect configuration and/or interconnect process may include various electrical and mechanical connections including one or more wires, wire bonds, ribbons, ribbon bonds, clips, spring contacts, traces, mechanical fasteners, and/or the like. Further, the interconnect configuration and/or interconnect process may include welded portions, welding, soldered portions, soldering, soldered portions, adhesive, adhesive portions, conductive epoxy, sintering, sintered portions, sintering processes, and/or the like.

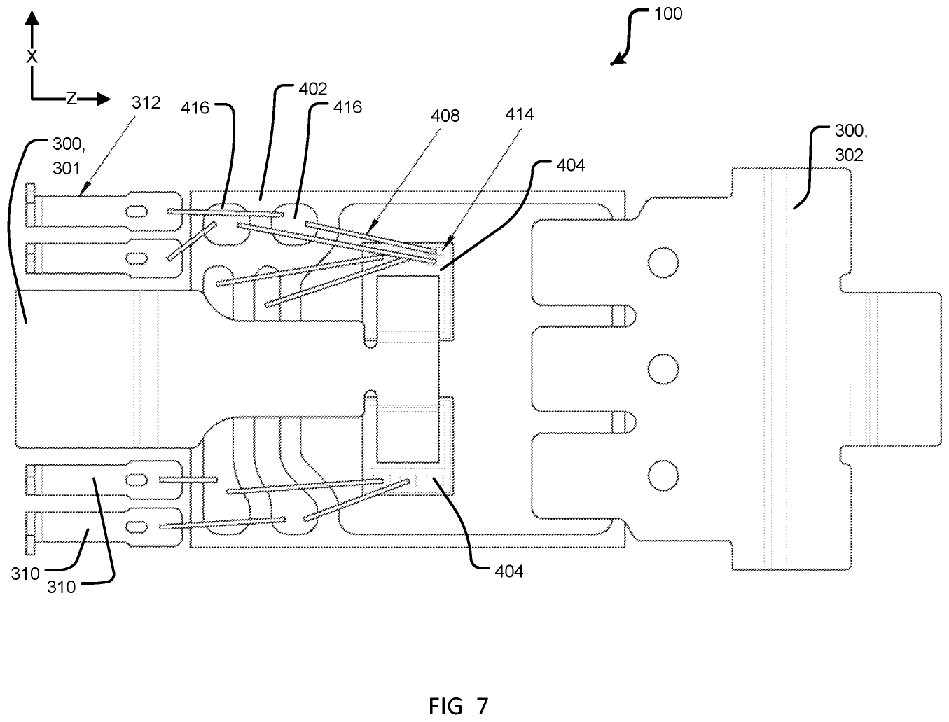

FIG. 7 illustrates a partial top view of the power package according to aspects of the disclosure.

In particular, FIG. 7 illustrates a partial top view of the power package 100 according to aspects of the disclosure. In particular, FIG. 7 illustrates an implementation of the at least one additional signal terminal 312 configured for current sensing. The current sensing may be implemented using an integrated current sensor on the at least one power device 404. Alternatively, current sensing may also be measured from a voltage drop across a series shunt resistor circuit implemented within the power package 100. Further, current sensing in the power package 100 may also be measured magnetically utilizing a sensor for measuring a magnetic field.

In aspects, the power package 100 may implement current sensing with an on-chip current sensor 414. In aspects, the on-chip current sensor 414 may be implemented with the at least one power device 404. In aspects, the on-chip current sensor 414 may utilize dedicated bonding terminals 416 on the power substrate 402.

In aspects, an interconnect 408 may extend between the on-chip current sensor 414, the dedicated bonding terminals 416, the at least one additional signal terminal 312, and/or the like. In other aspects, the interconnect 408 may be bonded directly to the at least one additional signal terminal 312, a trace on the power substrate 402 may be utilized as one or more interstitial jumpers (reducing wire bond length) for connection between the at least one additional signal terminal 312 and the on-chip current sensor 414. Depending on voltage isolation requirements of the gate driver PCB, pins on the drain side or a source side may be used to connect to the on-chip current sensor 414.

In the aspect illustrated in FIG. 7, the at least one additional signal terminal 312 may be implemented as two pins added on the other side of the source side of the power package 100. Further, two bond pads on the at least one power device 404 may be used to connect to the on-chip current sensor 414, which may be wire bonded down to the dedicated bonding terminals 416 on the power substrate 402. Alternatively, the interconnect 408 may extend from the on-chip current sensor 414 to the at least one additional signal terminal 312. In this regard, a specific implementation may depend on a size, a location, a bond pad configuration, and/or the like of the at least one power device 404, which can vary across multiple device types and applications. In aspects, the at least one additional signal terminal 312 may also be structured and arranged to extend over the power substrate 402; and the at least one additional signal terminal 312 may be soldered, welded, sintered, and/or the like in place to form a connection to the power substrate 402. Additionally, the at least one additional signal terminal 312 may also be attached directly to the drain pad 406.

While FIG. 7 illustrates using an implementation of the on-chip current sensor 414, other implementations for current measurements are contemplated using dedicated sensing elements, which may be shunts, sensors, and/or the like. Further, the sensing elements may be implemented as additional components, integrated into the at least one power device 404, embedded directly into the at least one power device 404, and/or the like, which may include an electrical connection between to the dedicated bonding terminals 416 and/or the at least one additional signal terminal 312.

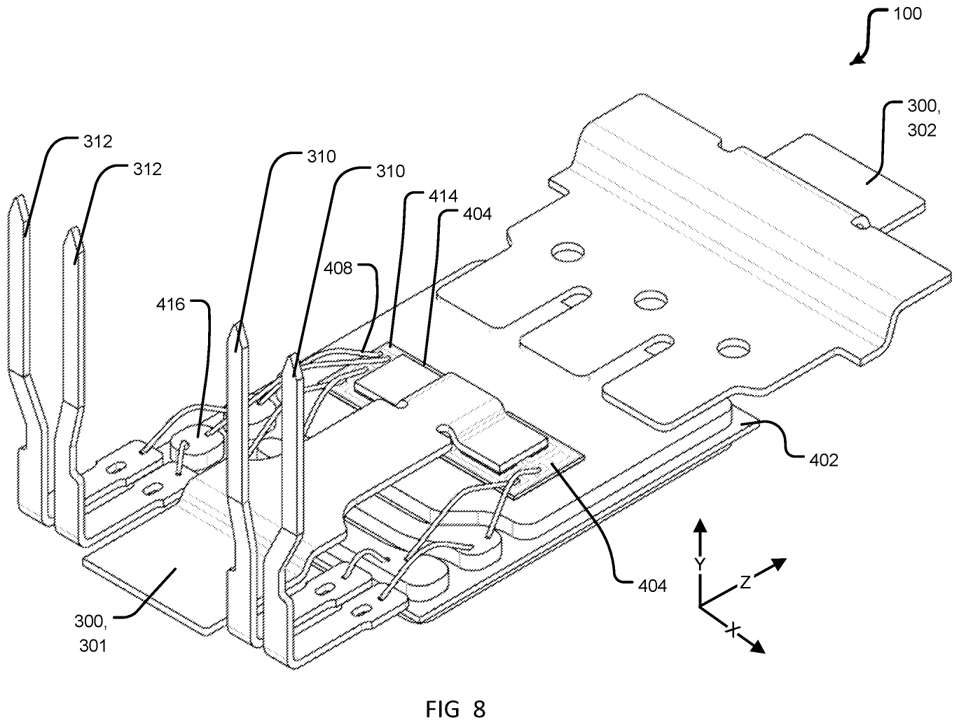

FIG. 8 illustrates a partial top view of the power package according to aspects of the disclosure.

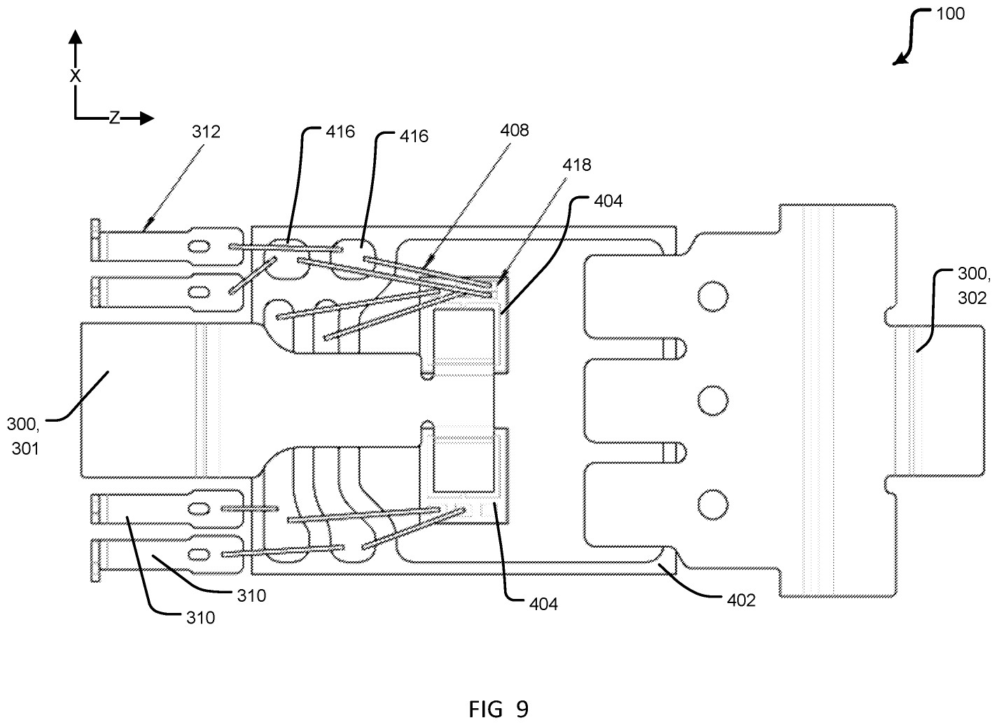

FIG. 9 illustrates a partial top perspective view of the power package according to aspects of the disclosure.

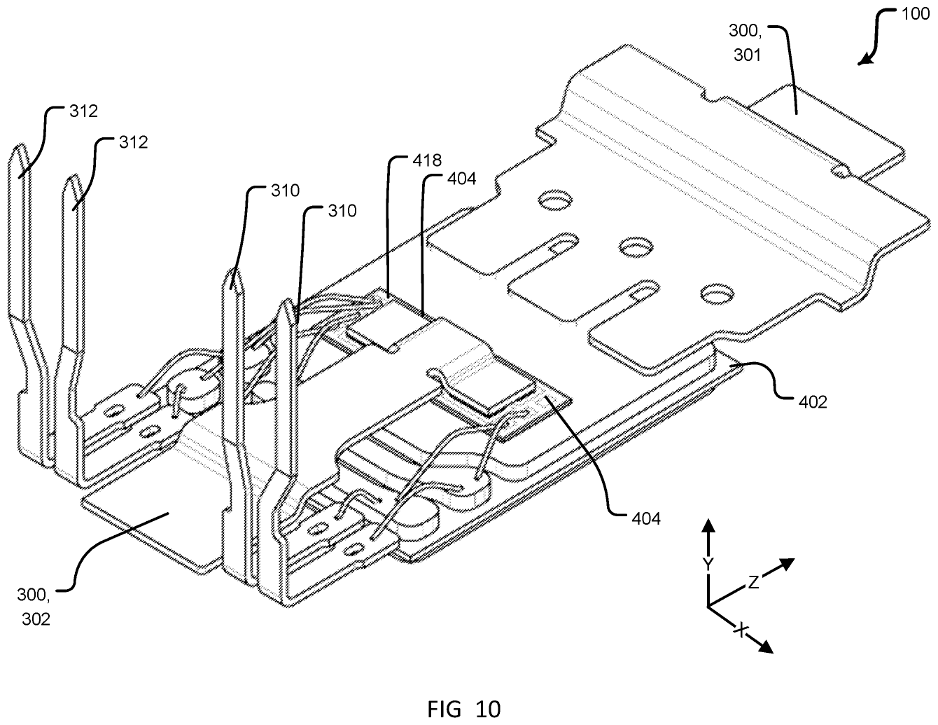

FIG. 10 illustrates a partial top view of the power package according to aspects of the disclosure.

In particular, FIG. 8 illustrates a partial top view of the power package 100 according to aspects of the disclosure. In particular, FIG. 8 illustrates an implementation of the at least one additional signal terminal 312 configured for temperature sensing. Temperature sensing may provide insight into many important factors during operation of the power package 100. Knowing a temperature of the at least one power device 404 and/or other components of the power package 100 may allow for precise control over how much current, power, and/or the like can be processed the power package 100. Further, temperature sensing may also be utilized to detect overcurrent events, overheating events, and/or the like as a safety mechanism for the power package 100. Temperature sensing may also help a system implementing the power package 100 best assess product lifetime using calibrated lifetime models, mission profiles, and/or the like that align product lifetime with temperature deltas under various operating conditions of the power package 100.

Temperature sensing within the power package 100 may be achieved through multiple methods. In one aspect, temperature sensing may be implemented by an on-chip temperature sensor 418. In aspects, the on-chip temperature sensor 418 may use an implementation of the dedicated bonding terminals 416, the interconnect 408, and/or the like generally consistent with the implementation of the on-chip current sensor 414 described above.

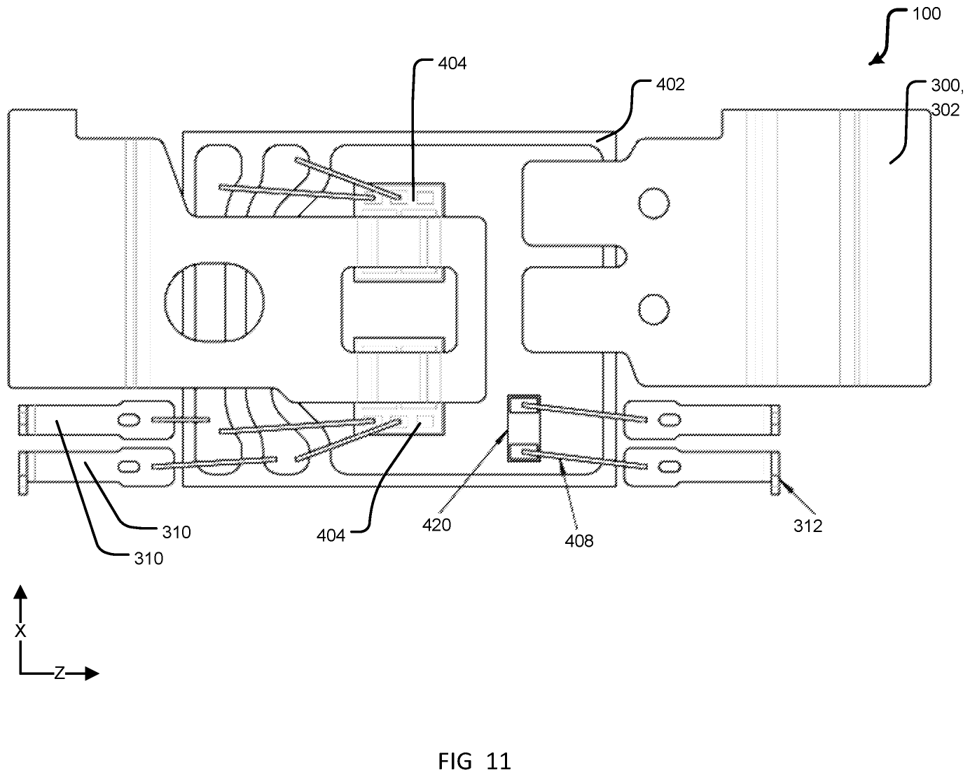

FIG. 11 illustrates a partial top view of the power package according to aspects of the disclosure.

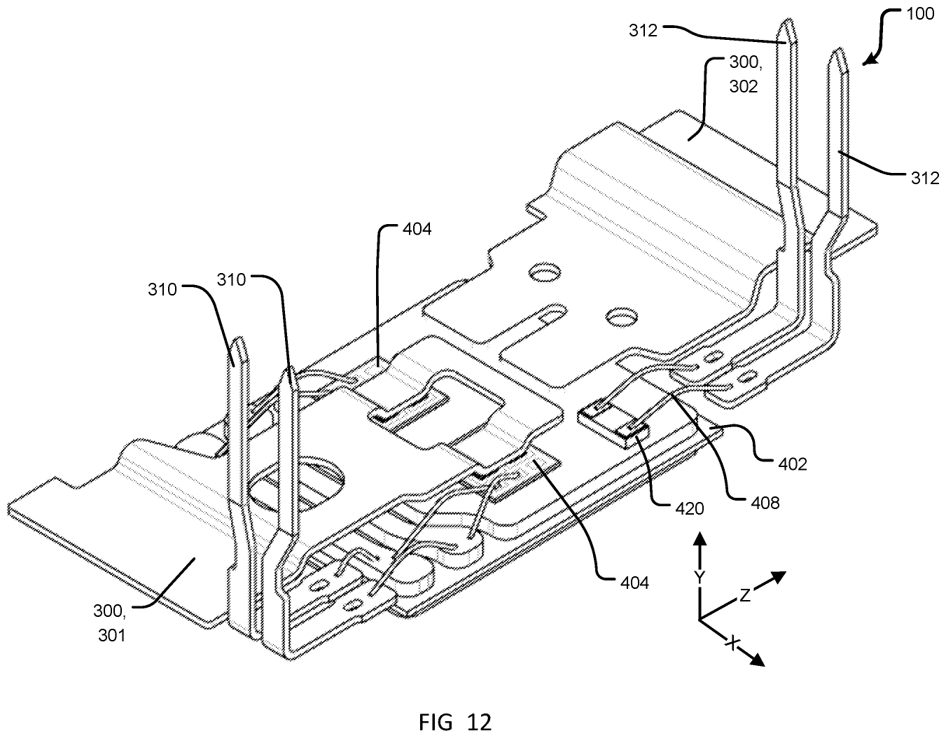

FIG. 12 illustrates a partial top perspective view of the power package according to aspects of the disclosure.

In particular, FIG. 11 illustrates a partial top view of the power package 100 according to aspects of the disclosure. In particular, FIG. 11 illustrates an implementation of the at least one additional signal terminal 312 configured for temperature sensing where a temperature may be sensed with a temperature sensing chip or temperature sensing device 420, such as a Negative Temperature Coefficient (NTC) resistor, a Resistive Temperature Device (RTD), a sensor integrated in the power substrate 402, and/or the like. In aspects, some temperature sensing devices may have built in electrical isolation while some temperature sensing devices may require placement on an isolated pad on the power substrate 402. In this regard, the temperature sensing device 420 may be implemented as an isolated the temperature sensing device and/or may be implemented as an non-isolated the temperature sensing device. Additionally, the placement the temperature sensing device 420 may be near a drain contact of the at least one power device 404, near a source contact of the at least one power device 404, and/or the like and may include associated structural changes to the power package 100, such as a lead frame and the power substrate 402 to accommodate the specific device format.

Additionally, while the figures depict implementation of the on-chip temperature sensor 418, the temperature sensing device 420, other implementations for temperature measurements are contemplated using dedicated sensing elements, such as NTCs, RTDs, thermistors, and/or the like, either as additional components or integrated/embedded directly into the power substrate 402.

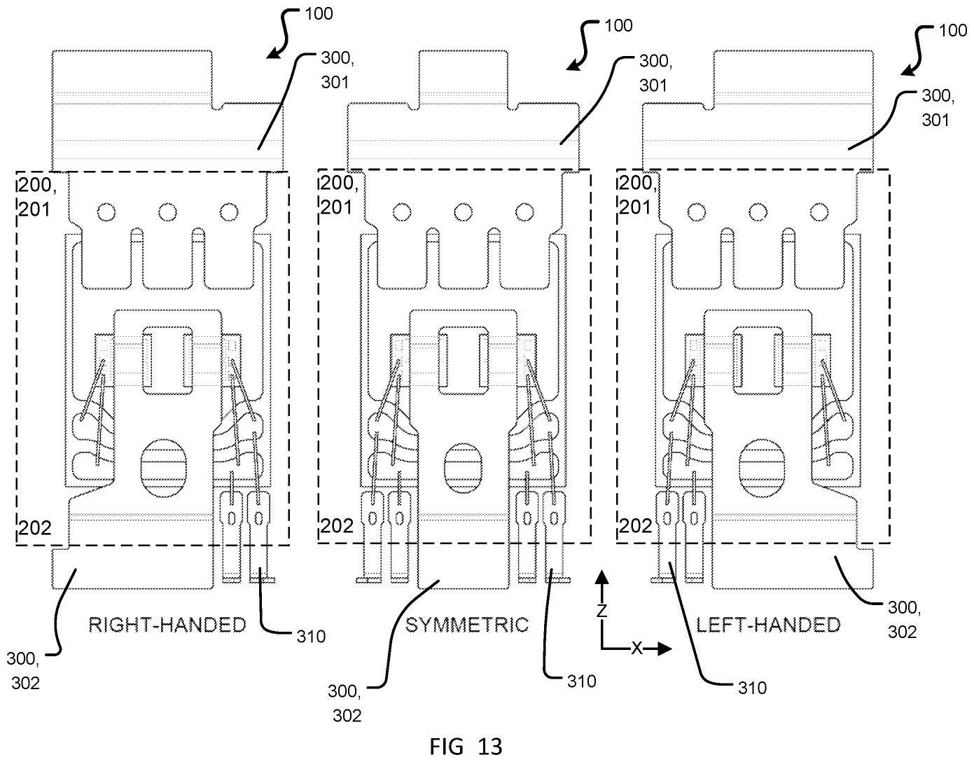

FIG. 13 illustrates various arrangements of a plurality of power terminals and/or a plurality of signal terminals within various implementations of a power package according to aspects of the disclosure.

In particular, FIG. 13 illustrates various arrangements of the plurality of power terminals 300 and/or the plurality of signal terminals 310 within various implementations of the power package 100 according to aspects of the disclosure. In this regard, with the four possible pin positions of the plurality of signal terminals 310, there may be room for implementation of the plurality of signal terminals 310 as gate and source kelvin connections on the left side of the housing 200 of the power package 100, right side of the housing 200 of the power package 100, or both sides side of the housing 200 of the power package 100.

These implementations of the plurality of signal terminals 310 may find use in some implementations of the power package 100 where a low, matched impedance is desired for the signal loop between paralleled implementations of the power package 100. Examples of the various arrangements of the plurality of signal terminals 310 and/or the plurality of power terminals 300 on the housing 200 of the power package 100 are illustrated in FIG. 13. In aspects, a drain power contact of the plurality of power terminals 300 may be modified to provide clearance to the plurality of signal terminals 310 when the positions are arranged in series as bridge legs.

In aspects, the plurality of signal terminals 310 may be symmetrically arranged on the housing sides 210. In aspects, the plurality of signal terminals 310 may be asymmetrically arranged on the housing sides 210. In aspects, the plurality of signal terminals 310 may be symmetrically arranged on either the first housing side 201 or the second housing side 202. In aspects, all of the plurality of signal terminals 310 may be asymmetrically arranged on either the first housing side 201 or the second housing side 202. In aspects, the first power terminal 301 may extend from the first housing side 201 and the second power terminal 302 extends from the second housing side 202; and the plurality of signal terminals 310 may from the second housing side 202.

In aspects, all of the plurality of signal terminals 310 may be on either the first housing side 201 or the second housing side 202; and all of the plurality of signal terminals 310 may be on a side of one of plurality of power terminals 300. In aspects, all of the plurality of signal terminals 310 may be on either the first housing side 201 or the second housing side 202; and all of the plurality of signal terminals 310 may be on both sides of one of the plurality of power terminals 300.

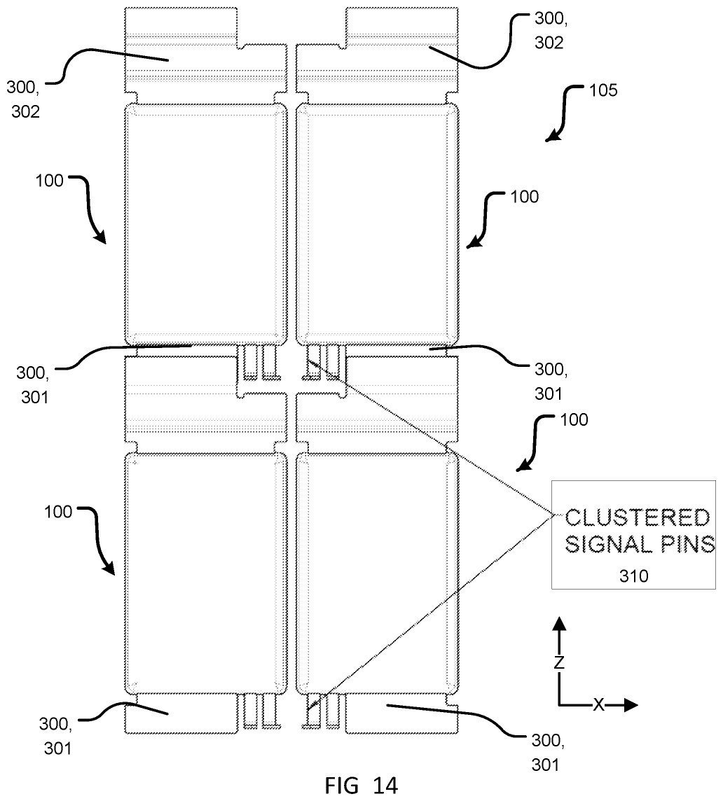

FIG. 14 illustrates a top view of a configuration of a plurality of implementations of the power package according to FIG. 1.

In particular, FIG. 14 illustrates a top view of a configuration 105 of a plurality of implementations of the power package 100 according to FIG. 1. As an example, if paralleling two implementations of the power package 100 per bridge leg is preferred, a right-handed implementation of the power package 100 and a left-handed implementation of the power package 100 pair could be joined such that their respective implementations of the plurality of signal terminals 310 are located close together. These implementations of the power package 100 with such implementations of the plurality of signal terminals 310 may be defined as signal pin clusters that may be grouped such that an effective path from a gate driver to each individual implementation of the power package 100, through the signal loops, for example may be as closely matched as possible. In such aspects, the configuration 105 may also simplify a routing, a layout, and/or the like of components of the system implementing the power package 100, such as a gate driver PCB.

In aspects, a configuration of at least two implementations of the power package 100 may be implemented such that all of the plurality of signal terminals 310 of the at least two implementations of the power package 100 may be arranged to be clustered along adjacent corners of the at least two implementations of the power package 100.

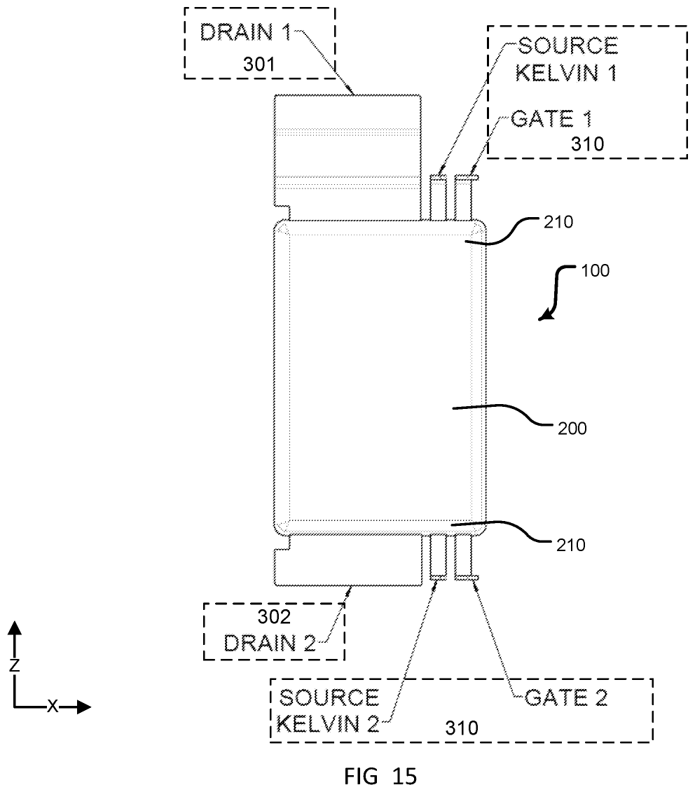

FIG. 15 illustrates a top side view of an external configuration of the power package according to FIG. 1.

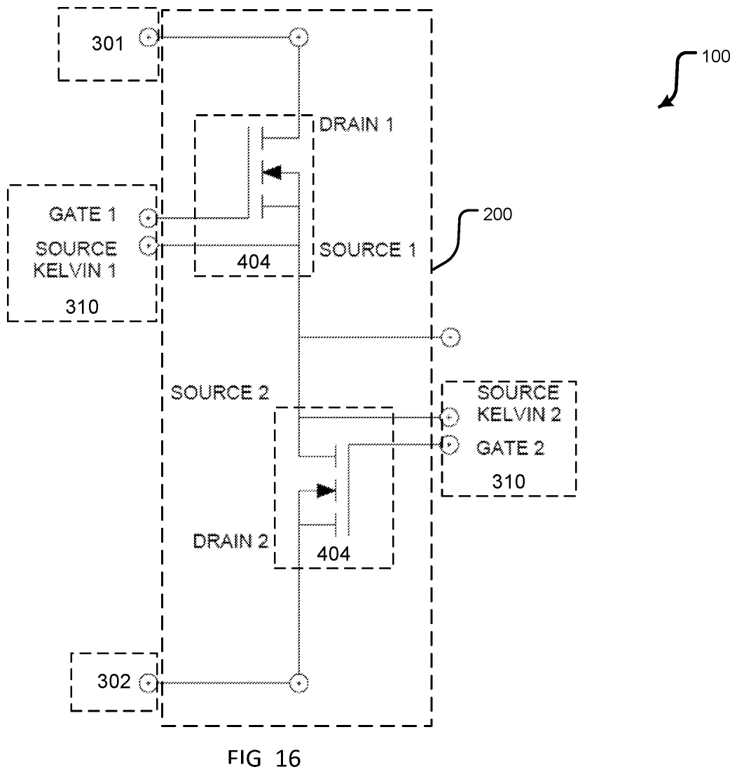

FIG. 16 illustrates a schematic of the power package according to FIG. 15.

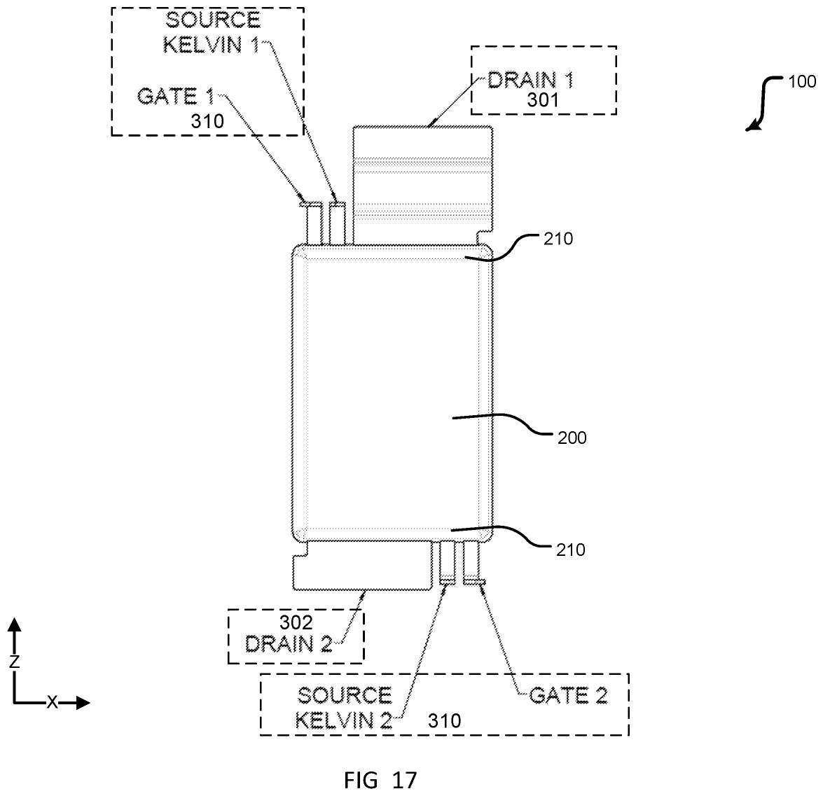

FIG. 17 illustrates a top side view of an external configuration of the power package according to FIG. 1.

In particular, the power package 100 is configured to allow for implementation with multiple sites and locations for power and signal pins that include the previously discussed implementations of the plurality of power terminals 300 and the plurality of signal terminals 310. Further, the power package 100 may be used for other topologies that use multiple switch positions.

In this regard, FIG. 15 illustrates an implementation of the power package 100 configured with a common source module topology. In aspects, the FIG. 15 implementation of the power package 100 may have at least two implementations of the at least one power device 404 joined together at respective sources for each as illustrated in FIG. 16.

In particular, the FIG. 15 implementation of the power package 100 may include implementations of the plurality of power terminals 300 configured as two power terminals and annotated as DRAIN 1 and DRAIN 2. Additionally, the FIG. 15 implementation of the power package 100 may include implementations of the plurality of signal terminals 310 configured as four signal terminals and annotated as SOURCE KELVIN 1, SOURCE KELVIN 2, GATE 1, and GATE 2.

As illustrated in FIG. 15, the power package 100 may be configured with an example external layout such that for each of the two switch positions, the plurality of signal terminals 310 are arranged on one side of the housing sides 210 of the power package 100 and the plurality of power terminals 300 are arranged on another side of the housing sides 210 of the power package 100.

As illustrated in FIG. 17, the power package 100 may alternatively implement a configuration where the plurality of signal terminals 310 are arranged on opposite corners of the housing 200. In aspects, the arrangement of the power package 100 illustrated in FIG. 17 may allow for a more logical internal layout and improved manufacturability/footprint utilization.

In aspects of the power package 100 configured with a common source topology, the first power terminal 301 may extend from the first housing side 201; the second power terminal 302 may extend from the second housing side 202; a first implementation of the plurality of signal terminals 310 may extend from the first housing side 201; and a second implementation of the plurality of signal terminals 310 extends from the second housing side 202. In aspects of the power package 100, the first implementation of the plurality of signal terminals 310 may be arranged adjacent the third housing side 203; and the second implementation of the plurality of signal terminals 310 may be arranged adjacent the third housing side 203. In aspects of the power package 100, the first implementation of the plurality of signal terminals 310 may be arranged adjacent the third housing side 203; and the second implementation of the plurality of signal terminals 310 may be arranged adjacent a fourth housing side.

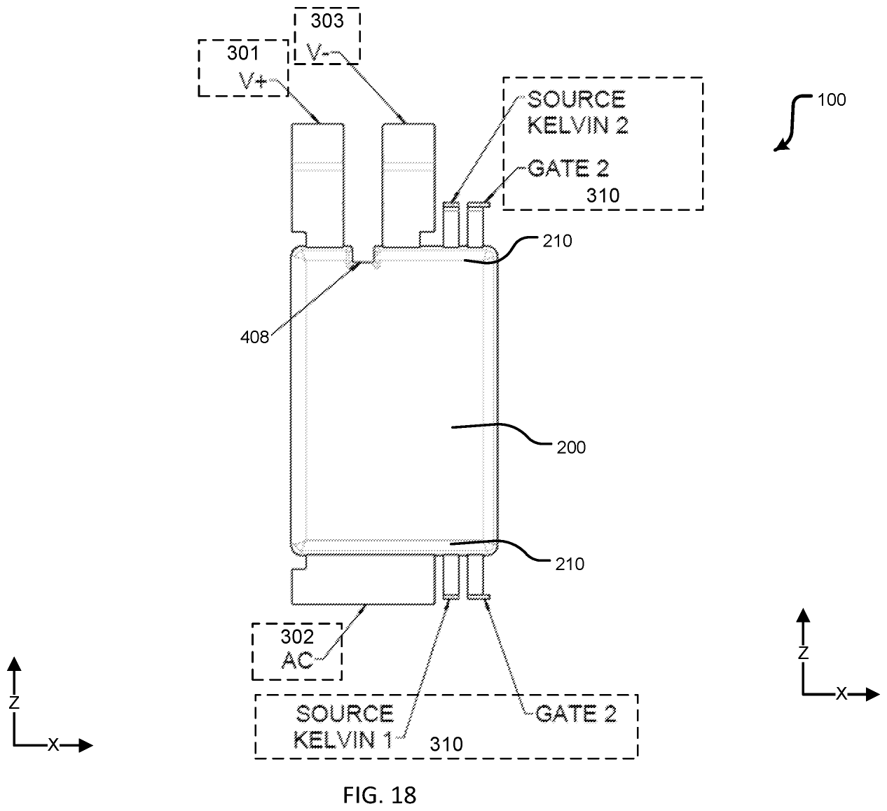

FIG. 18 illustrates a top side view of an external configuration of the power package according to FIG. 1.

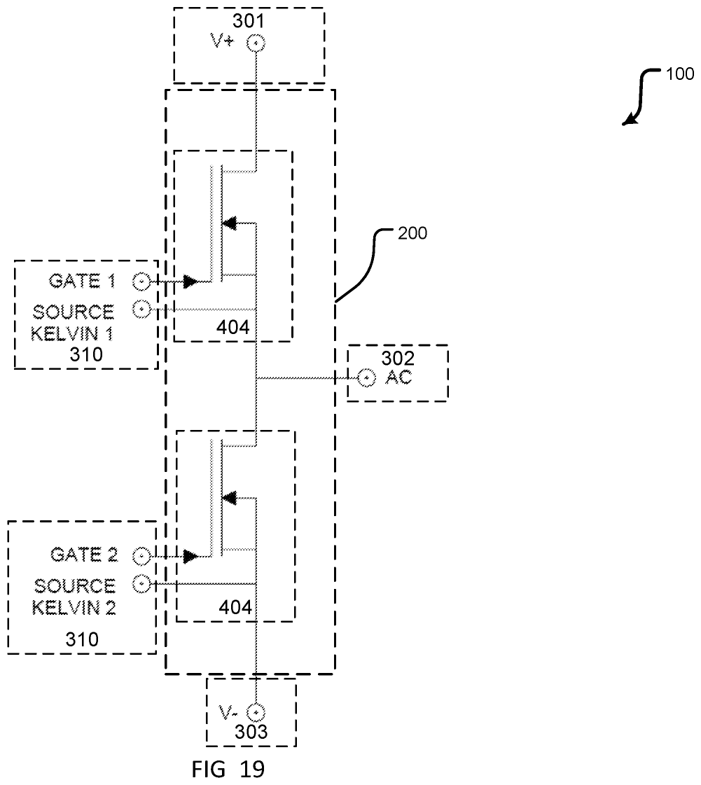

FIG. 19 illustrates a schematic of the power package according to FIG. 18.

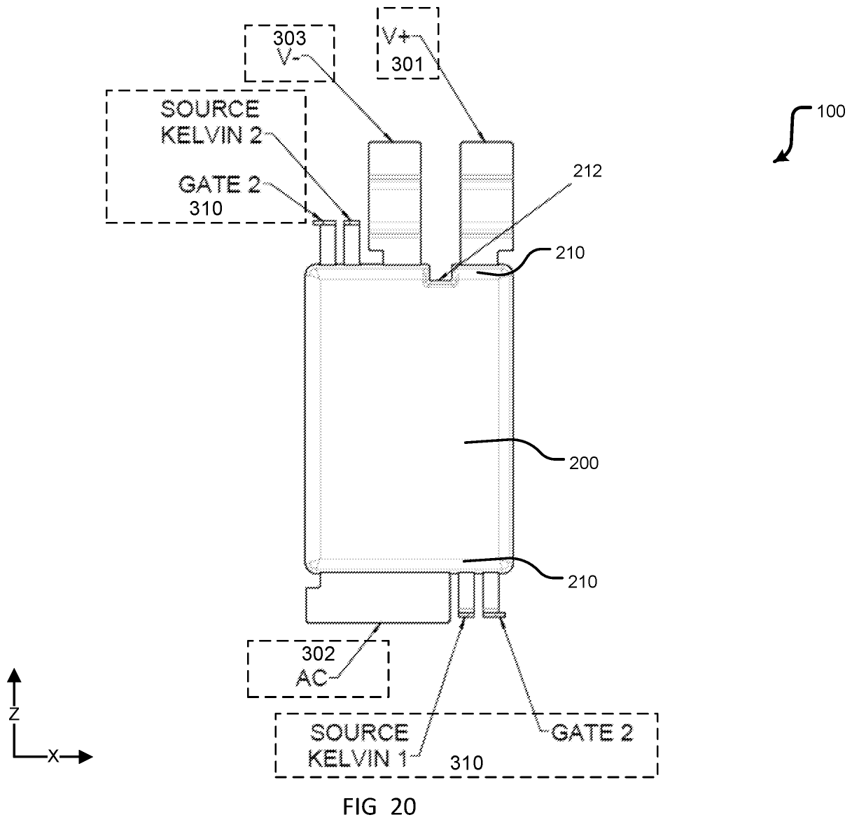

FIG. 20 illustrates a top side view of an external configuration of the power package according to FIG. 1.

In particular, the power package 100 is configured with another potentially useful topology, which in this case may be a half bridge topology. While two of the single switch position packages can be strung together to form one, in some cases a lower current and more compact module may be a more ideal solution.

In this regard, aspects of the power package 100 may be configured to implement four implementations of the at least one power device 404. Accordingly, the power package 100 may be configured to arrange the at least one power device 404 to implement a half-bridge topology in the same general footprint. Further, the power package 100 implementing a half-bridge topology may further include a third power terminal 303.

FIG. 19 schematically illustrates the arrangement and connections between the plurality of signal terminals 310, the first power terminal 301, the second power terminal 302, and the third power terminal 303 for implementation of the power package 100 with half bridge topology.

As illustrated in FIG. 18, the plurality of signal terminals 310, the first power terminal 301, the second power terminal 302, and the third power terminal 303 may be structured and arranged for easier external connections. As illustrated in FIG. 18, the power package 100 may be configured such that the plurality of signal terminals 310 are arranged on one side of the housing sides 210 of the power package 100 and the first power terminal 301, the second power terminal 302, and the third power terminal 303 are arranged on another side of the housing sides 210 of the power package 100.

Alternatively, the plurality of signal terminals 310, the first power terminal 301, the second power terminal 302, and the third power terminal 303 may be structured and arranged with the power package 100 as illustrated in FIG. 20 that may have a more logical internal layout, the power package 100 may be configured with flexibility to allow additional implementations and locations of the plurality of signal terminals 310 that may allow for many embodiments to the power package 100 to be implemented. As illustrated in FIG. 20, the power package 100 may implement a configuration where the plurality of signal terminals 310 are arranged on opposite corners of the housing 200. Additionally, although the various figures illustrate annotated arrangements and/or locations of the plurality of signal terminals 310 as gate, source Kelvin, and/or the like, aspects of the power package 100 may arrange the plurality of signal terminals 310 in any manner or location. For example, implementation and/or location of the plurality of signal terminals 310 as gate, source Kelvin, and/or the like may be swapped.

In aspects of the power package 100 configured with a half-bridge topology, the plurality of power terminals 300 may include at least a third power terminal 303; the third power terminal 303 may extend from the first housing side 201; the first power terminal 301 may extend from the first housing side 201; the second power terminal 302 may extend from the second housing side 202; a first implementation of the plurality of signal terminals 310 may extend from the first housing side 201; and a second implementation of the plurality of signal terminals 310 may extend from the second housing side 202.

In further aspects, the power package 100 may implement a creepage extender 212. In some aspects, the creepage extender 212 may be between the second power terminal 302 and the third power terminal 303 to meet voltage safety standards. In aspects, the creepage extender 212 may increase a surface distance along an insulator that may include the housing 200 and may be implemented as trenches (as shown) or alternatively may be implemented as ribs. In aspects, the creepage extender 212 may be arranged on the first housing side 201 between the third power terminal 303 and the first power terminal 301. In other aspects, the creepage extender 212 may be arranged anywhere on the housing 200, the housing sides 210, between any of the implementations of the plurality of power terminals 300, between any implementations of the plurality of signal terminals 310, on any surfaces of the power package 100. Further, there may be multiple implementations of the creepage extender 212.

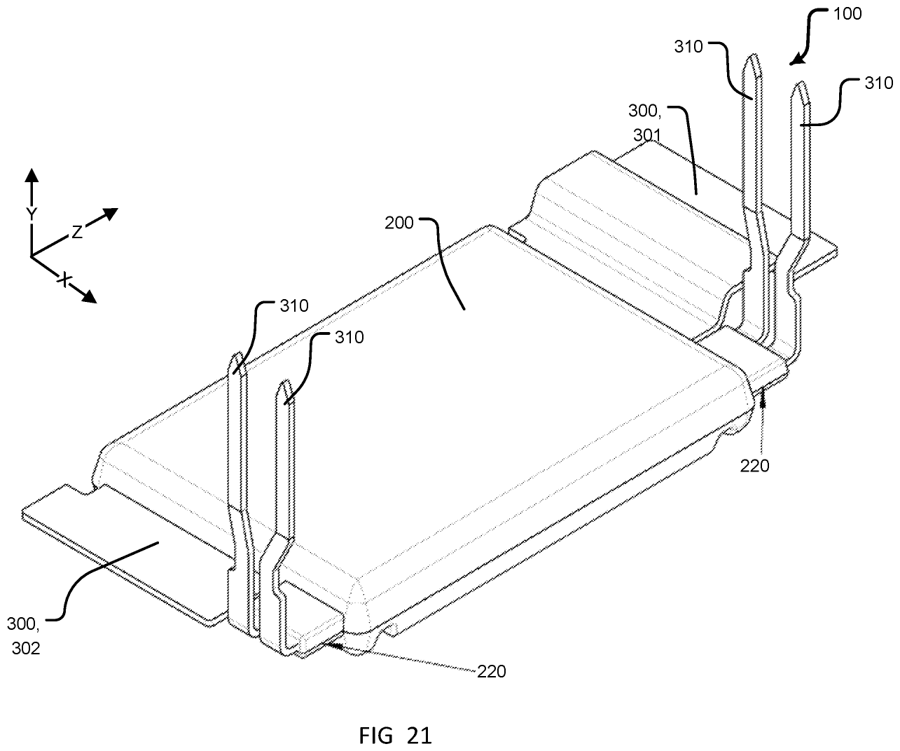

FIG. 21 illustrates a top perspective view of the power package according to FIG. 1.

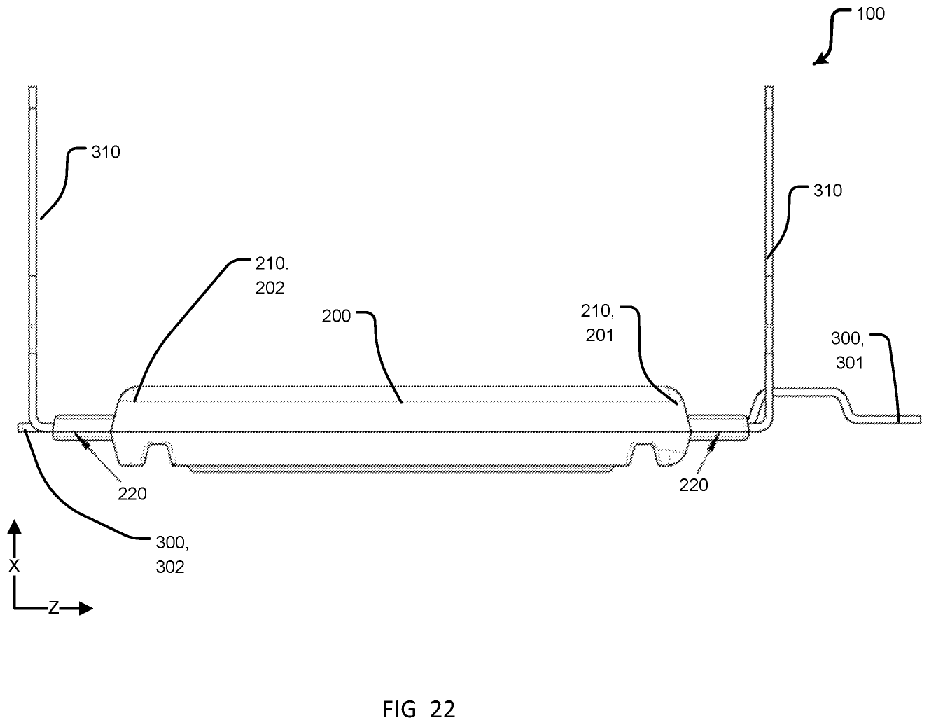

FIG. 22 illustrates a side view of the power package according to FIG. 21.

In aspects, it may be beneficial to provide the power package 100 with additional structural support. In this regard, with implementations of the plurality of power terminals 300 and/or the plurality of signal terminals 310 added to multiple sides of the power package 100, there may be more strain placed on the plurality of signal terminals 310 from the gate driver, as the pins are all bonded to the same rigid body.

In this case, the ‘shoulder’ of the pins could receive additional support by implementation of a sleeve structure 220 on the housing 200. In particular, the sleeve structure 220 may be arranged on the housing 200 and may be formed of a mold compound utilized to form the housing 200. In this regard, the sleeve structure 220 may provide mechanical support where the plurality of signal terminals 310 joined to a body of the housing 200 formed by, for example, mold compound. In aspects, the sleeve structure 220 may be configured to surround and mechanically support at least one of plurality of signal terminals 310.

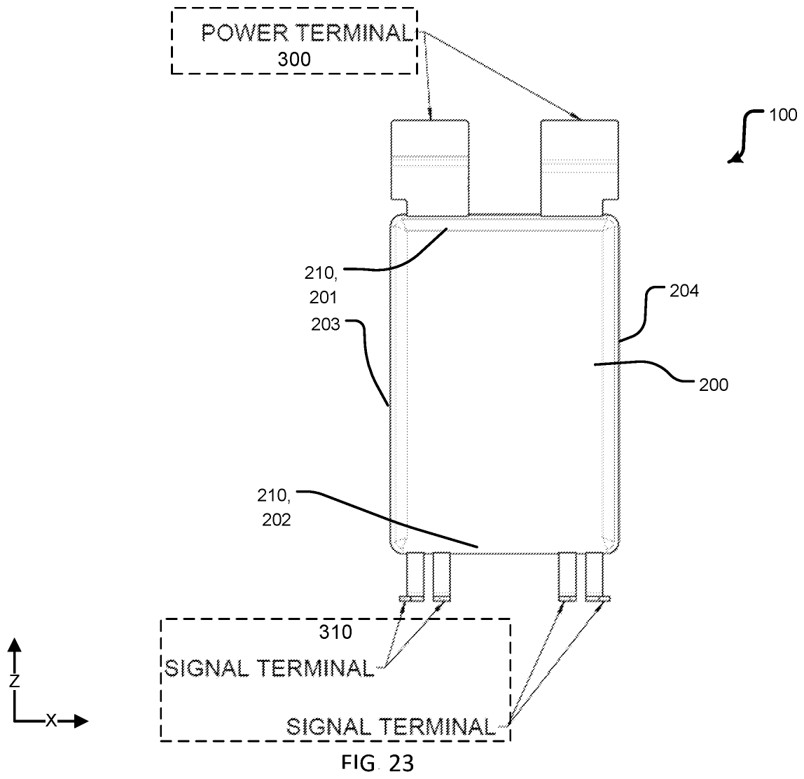

FIG. 23 illustrates a top view of a power package according to aspects of the disclosure.

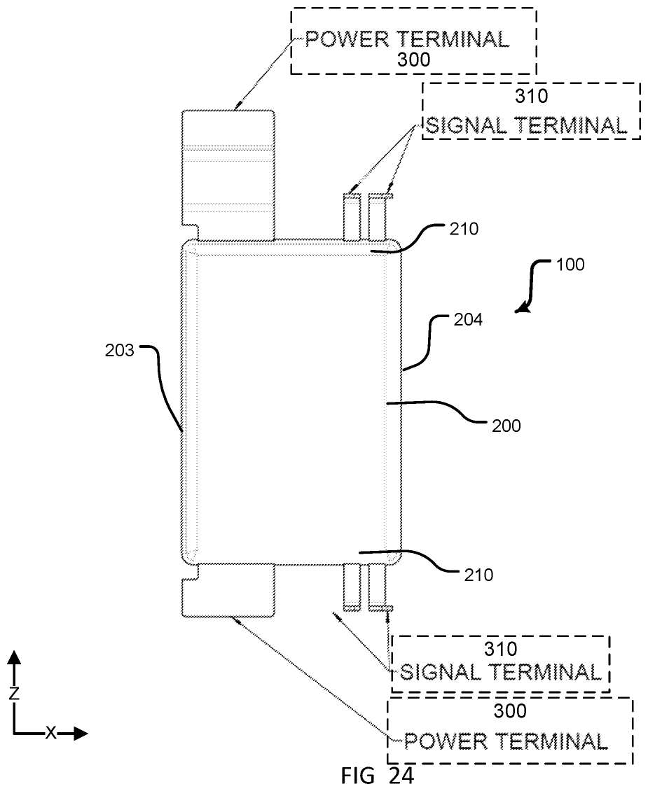

FIG. 24 illustrates a top view of a power package according to aspects of the disclosure.

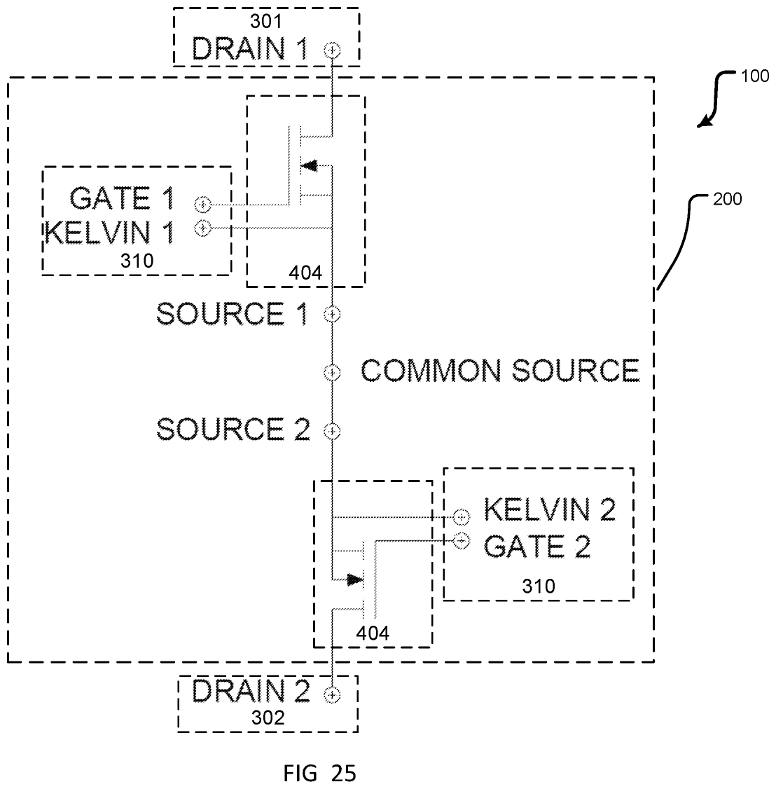

FIG. 25 illustrates a schematic of a power package according to aspects of the disclosure.

In particular, the power package 100 illustrated in FIG. 23, FIG. 24, and FIG. 25 may be configured to include additional electrical terminals to accommodate the power and signal terminals specific to a common source topology. Further, the power package 100 may optionally include any other aspects as described and illustrated herein.

In aspects, the power package 100 may be configured such that the plurality of power terminals 300 are arranged on one side of the housing 200, and the at least one of plurality of signal terminals 310 are arranged on another side of the housing 200. For example, the plurality of power terminals 300 may be arranged on the first housing side 201 and the at least one of plurality of signal terminals 310 may be arranged on the second housing side 202; or the plurality of power terminals 300 may be arranged on the second housing side 202 and the at least one of plurality of signal terminals 310 may be arranged on the first housing side 201.

In other aspects, the power package 100 may be configured such that the plurality of power terminals 300 are arranged on both sides of the housing 200, and the at least one of plurality of signal terminals 310 are arranged on both sides of the housing 200. For example, some of the plurality of power terminals 300 may be arranged on the first housing side 201, some of the at least one of plurality of signal terminals 310 may be arranged on the first housing side 201, some of the plurality of power terminals 300 may be arranged on the second housing side 202, and some of the at least one of plurality of signal terminals 310 may be arranged on the second housing side 202.

In aspects, the plurality of power terminals 300 may be at a high voltage potential and may need to be configured and/or structured on the housing 200 with an appropriate surface distance (creepage) and air distance (clearance) between implementations of the plurality of power terminals 300 to meet safety standards according to the system voltage level. In other aspects, the power package 100 may be configured with an implementation of the creepage extender 212 on the housing 200 as previously described (not shown). On the other hand, the at least one of plurality of signal terminals 310 may be at a low voltage potential and may not need large distances for electrical isolation. Additionally, the implementation illustrated in FIG. 23 and the implementation illustrated in FIG. 24 may each find usage for different system level approaches, described later in the disclosure. Further, FIG. 25 illustrates an exemplary schematic of the power package 100 configured with the common source topology as described herein.

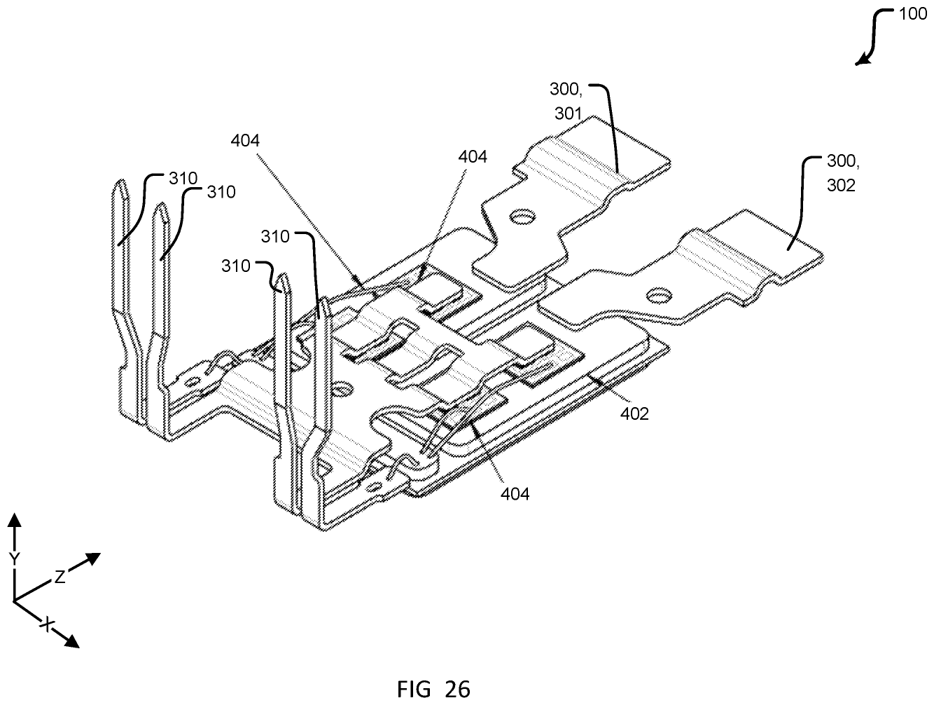

FIG. 26 illustrates a partial perspective top view of a package according to the disclosure.

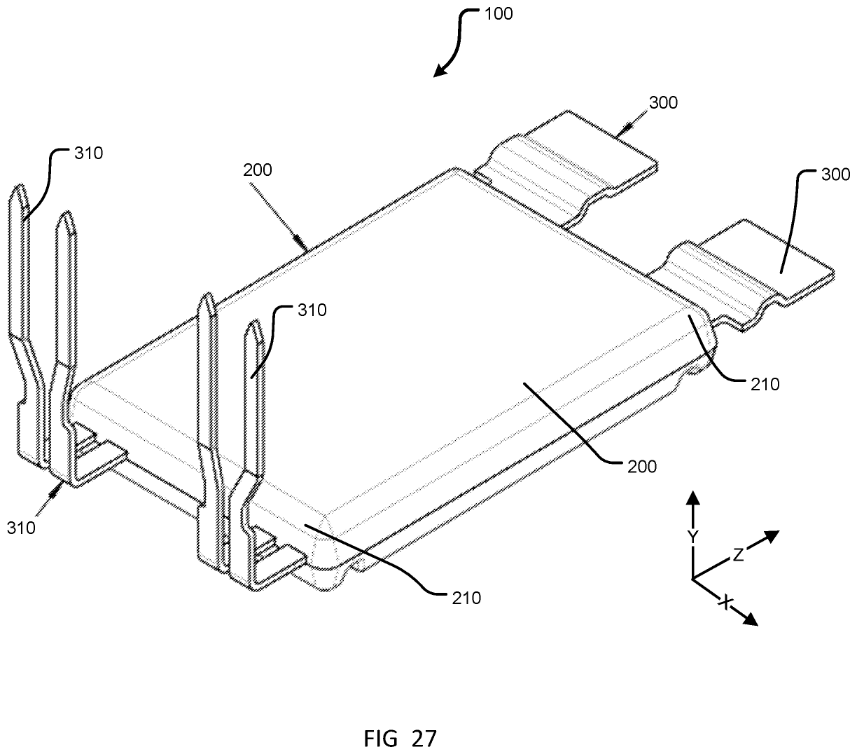

FIG. 27 illustrates a perspective view of the package according to FIG. 26.

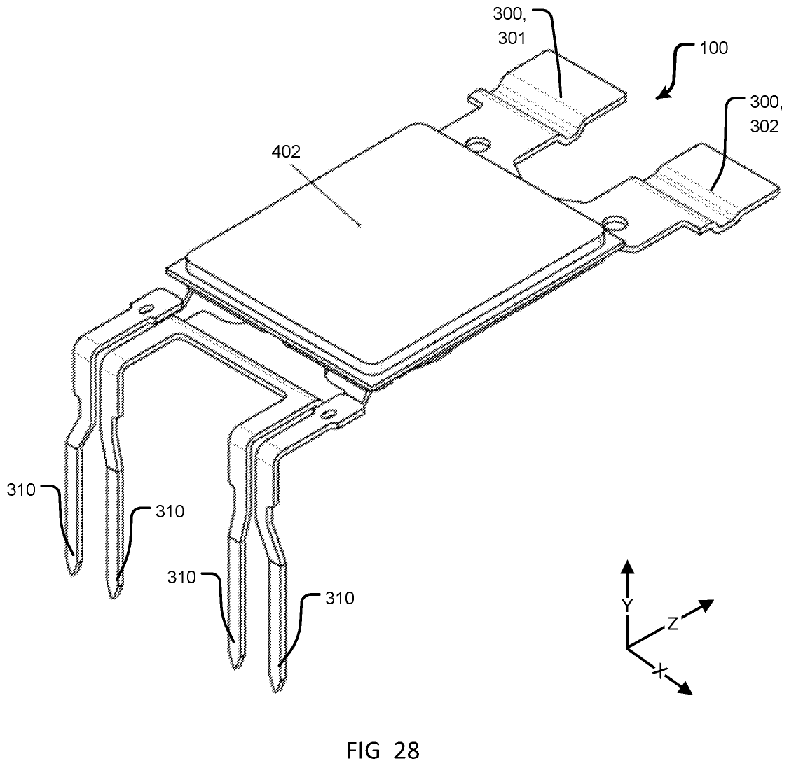

FIG. 28 illustrates a perspective bottom view of the package according to FIG. 26.

Aspects of the power package 100 may include external features such as the housing 200, which may be configured with a mold compound, creepage distance extenders, which may increase voltage safety, the plurality of power terminals 300, the at least one of plurality of signal terminals 310, and/or the like. Aspects of the power package 100 may include internal features that may include the at least one power device 404, the power substrate 402, power interconnections, and signal interconnections. It should be noted that specific implementations of the power package 100 may vary in the format and layout of the internal structure. For example, implementations of the power package 100 may include power wire bonds or ribbon may be used in place of a clip for the power interconnection. A clip is used in all examples in this disclosure. However, the power package 100 may utilize implementations with other interconnection methods including an interconnect configuration and/or interconnect process as described herein.

Further, the power package 100 as disclosed may be configured such that multiple embodiments can be realized for the approaches and structures as described herein. As an example, the power package 100 may be implemented with different numbers the at least one power device 404 (1, 2, 3, 4, etc.) and can be laid out through at least two methods: the power package 100 may be configured to keep all device locations the same, and only populate the positions needed for the given output current requirement; and/or the power package 100 may be configured to place devices in the optimal position on an optimized layout for the given number of the at least one power device 404.

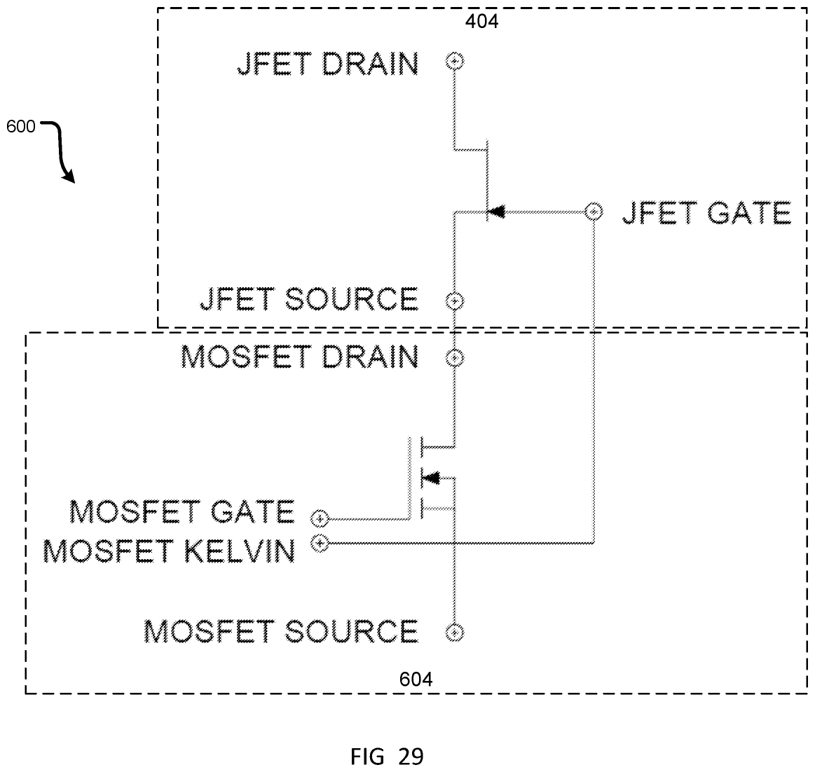

FIG. 29 illustrates a schematic of a cascode configuration according to aspects of the disclosure.

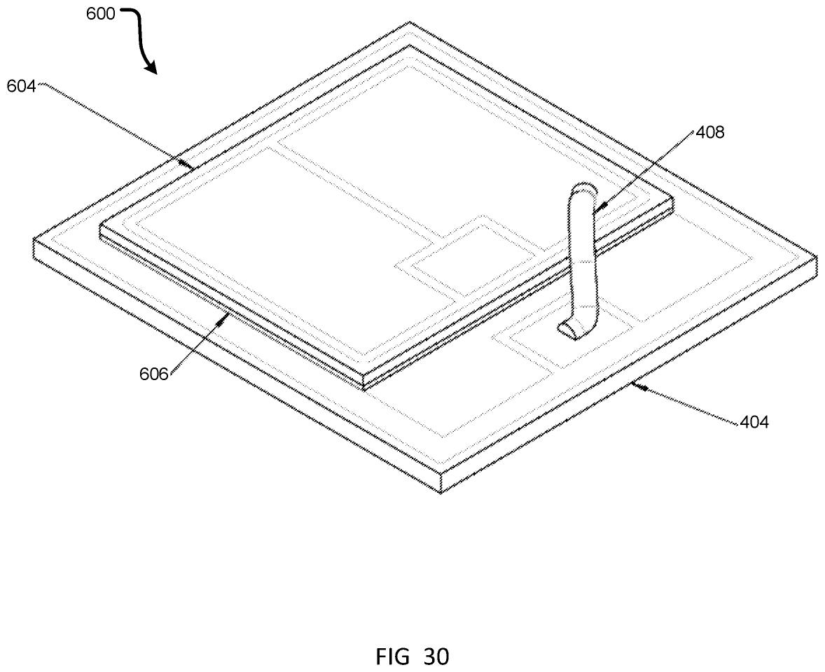

FIG. 30 illustrates a perspective view of a cascode configuration according to FIG. 29.

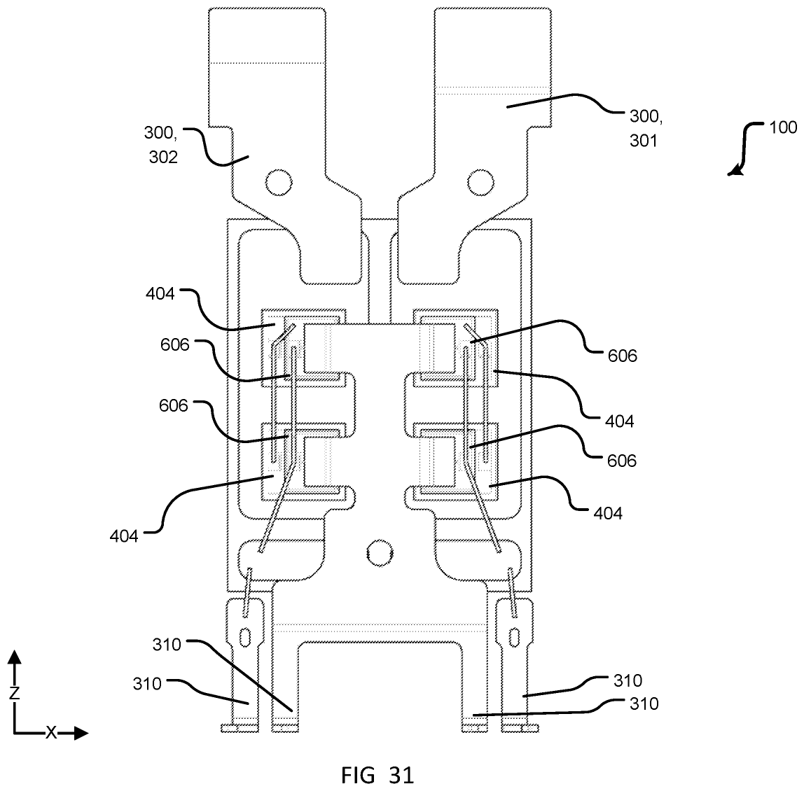

FIG. 31 illustrates a top view of a power package implementing the cascode configuration according to FIG. 29.

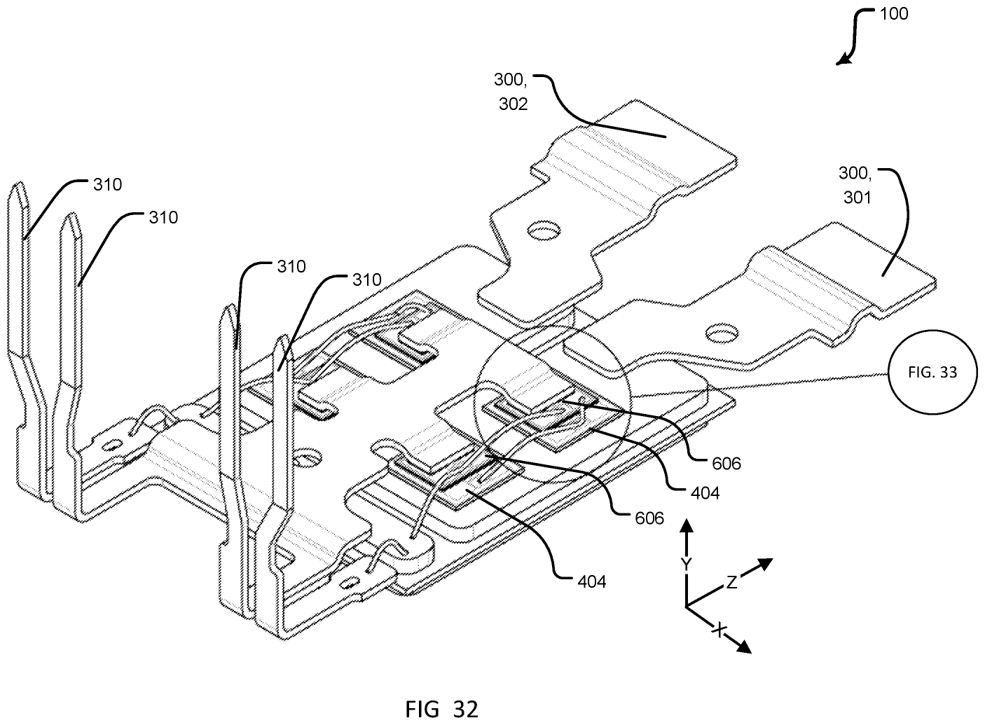

FIG. 32 illustrates a partial perspective view of a power package implementing the cascode configuration according to FIG. 29.

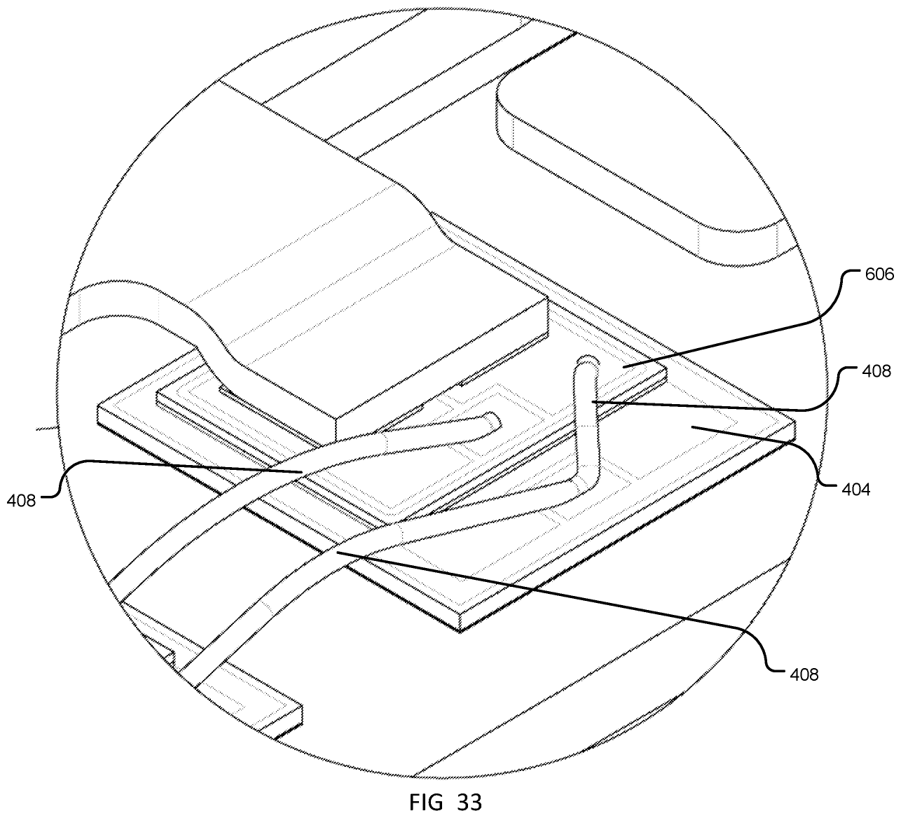

FIG. 33 illustrates a partial perspective view of a power package implementing the cascode configuration according to FIG. 29.

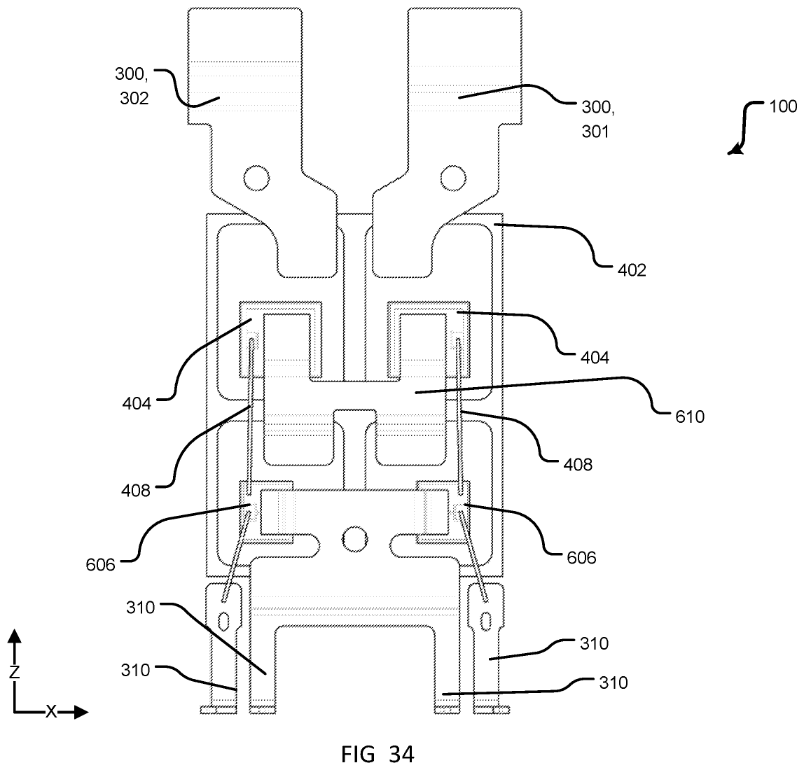

FIG. 34 illustrates a top view of a power package implementing the cascode configuration according to FIG. 29.

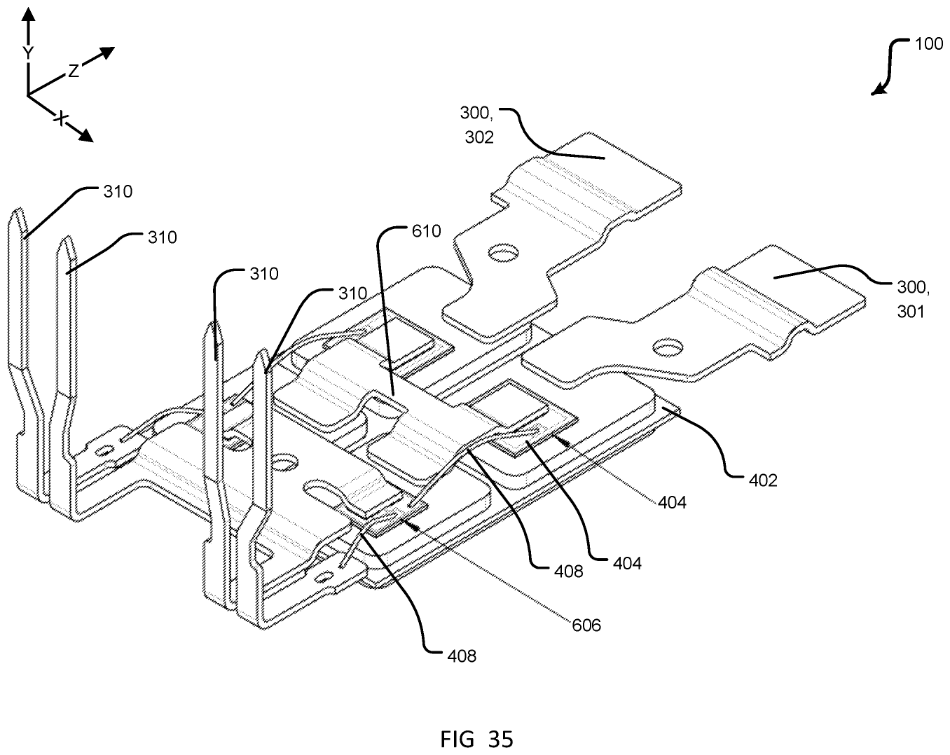

FIG. 35 illustrates a partial top perspective view of the power package according to FIG. 34.

In particular, FIG. 29 illustrates a schematic of a cascode configuration 600. The cascode configuration 600 may be utilized in any aspects of the power package 100 described herein. Further, the cascode configuration 600 may be utilized with any implementation type of the at least one power device 404 implemented by the power package 100.

The following exemplary implementation of the cascode configuration 600 in the power package 100 may relate to, for example, particular implementations of the at least one power device 404. In this regard, implementations of the at least one power device 404, such as for normally on devices, such as JFETs (Junction Field Effect Transistors), and similar depletion mode devices, the cascode configuration 600 may be configured to add a normally off low voltage device 604, such as MOSFET (metal-oxide-semiconductor field-effect transistor) to form a cascode topology. The MOSFET may be connected in series with the JFET, such that a source of the JFET is connected to a drain of the MOSFET, and a source of the MOSFET may be connected to a gate of the JFET. When the MOSFET is off, its drain-source voltage surpasses the JFETs pinch-off voltage. When the MOSFET is on, the JFET is allowed to go back to its normally on state.

With reference to FIG. 29, the cascode configuration 600 may be implemented with a cascode topology for a JFET and MOSFET. However, the cascode configuration 600 may be implemented with other types of devices. Realizing this topology in the power package 100 can be difficult, given the desire for a compact, power dense footprint. Further, adding additional devices, which are in the high current path, requires design considerations and tradeoffs. As the devices are effectively placed in series for a power loop, for example a JFET drain, a JFET source, a MOSFET drain, a MOSFET source, and/or the like.

Accordingly, aspects of the cascode configuration 600 may be implemented with a configuration and/or method which may stack the normally off low voltage device 604, such as a low voltage MOSFET on top of the at least one power device 404, such as a high voltage JFET. This interconnects the JFET source and the MOSFET drain directly, with the MOSFET source to JFET drain connection being accomplished with an interconnect 408, such as a wire bond, an interconnect configuration and/or interconnect process as described herein. Further, the normally off low voltage device 604 may be attached to the at least one power device 404 with a power attach 606. The power attach 606 may include an adhesive, a solder, and/or the like

FIG. 30, FIG. 31, FIG. 32, and FIG. 33 illustrate an implementation of the power package 100 implementing the cascode configuration 600 in an exemplary stacked Cascode layout. In this regard, the power package 100, as illustrated, includes four implementations of the at least one power device 404. Note that to accomplish the paralleled devices for each switch position, the signal connections implemented by the interconnect 408 may be formed with a stitched wire bond. Stitching the wire bond may join multiple devices (the normally off low voltage device 604 and/or the at least one power device 404) together while avoiding wire bond clearance or collision issues during manufacturing. Note that in some embodiments the signal bonds may not be stitched, as shown, and may be individual bonds.

FIG. 34 and FIG. 35 illustrate an alternative layout of the cascode configuration 600 in which the normally off low voltage device 604 and the at least one power device 404 may be packaged side by side on the power substrate 402. Here, interstitial pads on the power substrate 402 may be used to form the proper interconnection of the normally off low voltage device 604 and the at least one power device 404. In FIG. 34 and FIG. 35, a clip 610 may be utilized to connect a source of the at least one power device 404, such as the high voltage JFET source, to a drain trace of the normally off low voltage device 604, such as a low voltage MOSFET on the power substrate 402. In some embodiments, this connection could be formed with wire, ribbon, similar interconnection method, and/or an interconnect configuration and/or interconnect process as described herein.

It should be noted that the implementations of the cascode configuration 600 are illustrated with single device implementations of the at least one power device 404 and the normally off low voltage device 604 (i.e. a normally off MOSFET or a normally on JFET). However, the cascode configuration 600 may be implemented with any implementation type or number of the at least one power device 404 and/or the normally off low voltage device 604.

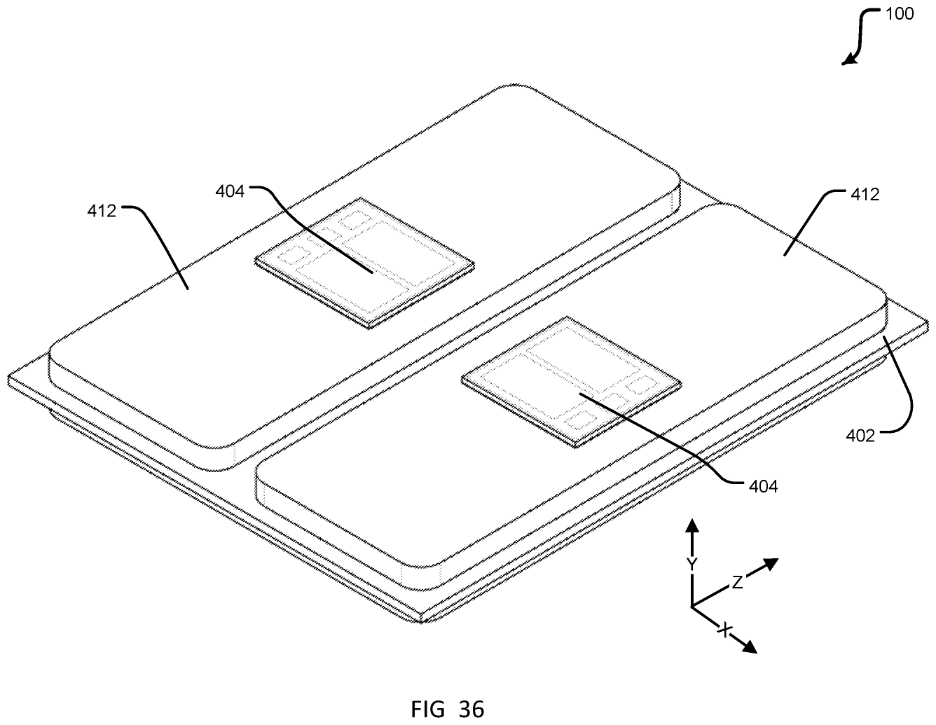

FIG. 36 illustrates a perspective view of an implementation of a power substrate according to aspects of the disclosure.

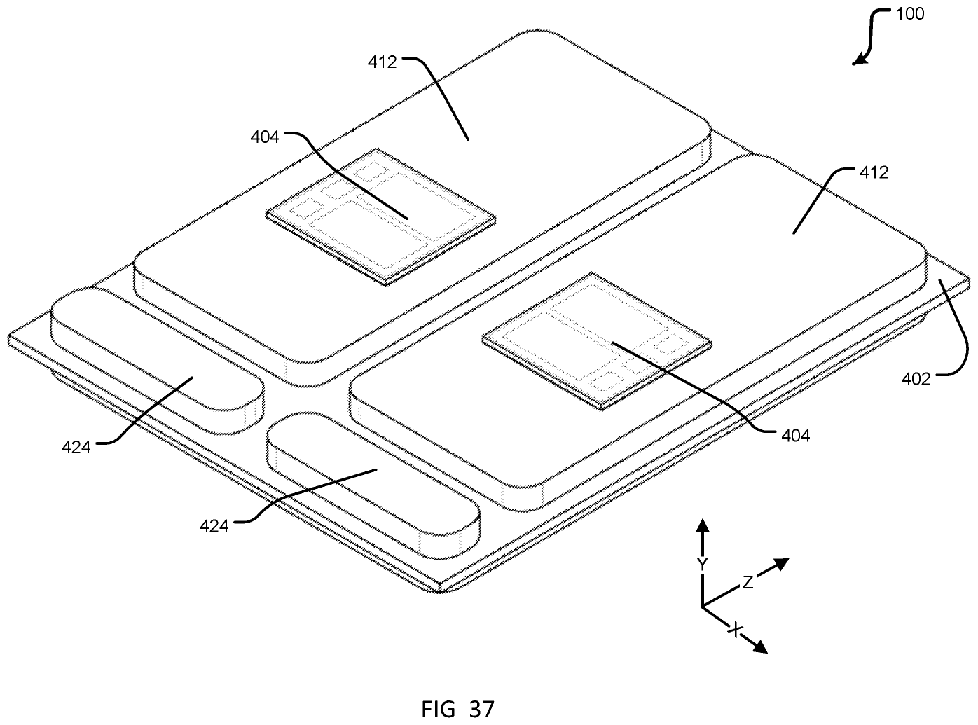

FIG. 37 illustrates a perspective view of another implementation of a power substrate 402 according to aspects of the disclosure.

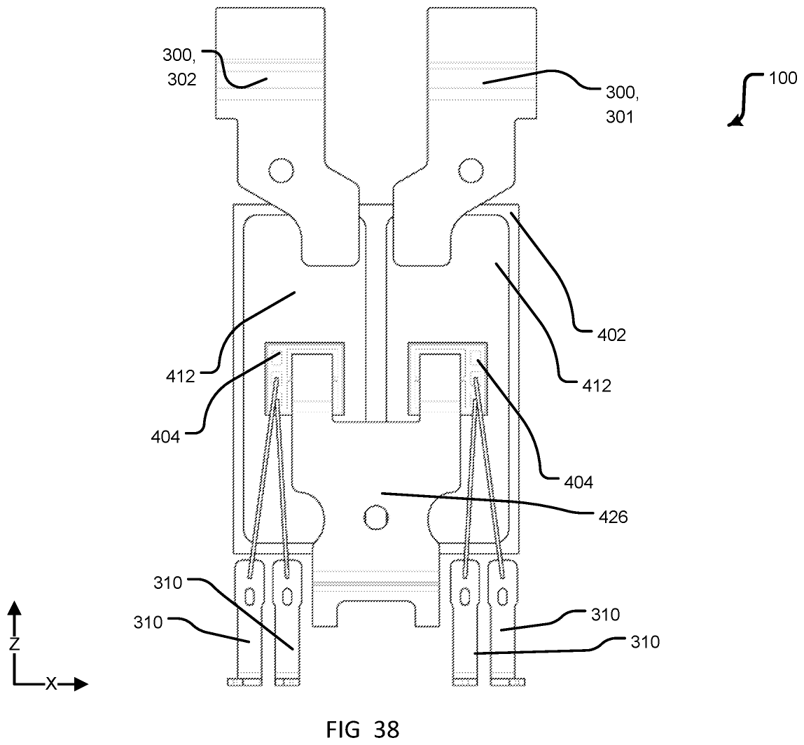

FIG. 38 illustrates a perspective view of an implementation of a power package according to aspects of the disclosure.

In particular, FIG. 38 illustrates an implementation of the power package 100 configured such that the plurality of power terminals 300 are arranged on one side of the housing 200 and/or the power substrate 402 while the at least one of plurality of signal terminals 310 are on the other side of the housing 200 and/or the power substrate 402. The internal layout of the power package 100 to accompany the external terminal arrangement may vary based on the number of the at least one power device 404, source kelvin implementation, performance optimizations, and/or the like. While the illustrated layouts of the power package 100 described and illustrated may use the same size implementation of the at least one power device 404 as a reference, other embodiments of the power package 100 are possible which take advantage of the modularity of the layout to best meet the power needs of a given system.

In aspects of the disclosure, the power package 100 may implement fully populated device locations of the at least one power device 404, partially populated device locations of the at least one power device 404, larger and smaller size implementations of the at least one power device 404, implementations of the at least one power device 404 with different gate and source pad sizes and arrangements, topside clip variations to accommodate the gate and source pad configurations of the at least one power device 404, power wire bond/ribbon interconnections instead of the topside clip, and/or an interconnect configuration and/or interconnect process as described herein.

FIG. 36 illustrates an exemplary layout of the power substrate 402 that may be implemented in any aspect of the power package 100 as described herein including the implementation illustrated in FIG. 38. As illustrated in FIG. 36, the power substrate 402 may be implemented with primary power traces 412. In aspects, the power substrate 402 may have two implementations of the primary power traces 412 for each drain connection of the at least one power device 404. Implementations of the at least one power device 404 may be attached to the primary power traces 412. In aspects, implementations of the at least one power device 404 may be attached in center locations of the primary power traces 412 to minimize thermal resistance by maximizing the effect of heat spreading.

As illustrated in FIG. 37, in some cases, the power substrate 402 may be implemented with additional traces 424 added to the power substrate 402 to accommodate additional functionality. In one case, one or multiple implementations of the additional traces 424 may be added to the power substrate 402 to act as interstitial sites to reduce wire bond length. In other cases, implementations of the power substrate 402 may be configured as isolated traces that may be added to the power substrate 402 in order to accommodate sensing elements such as a temperature sensor as described herein.

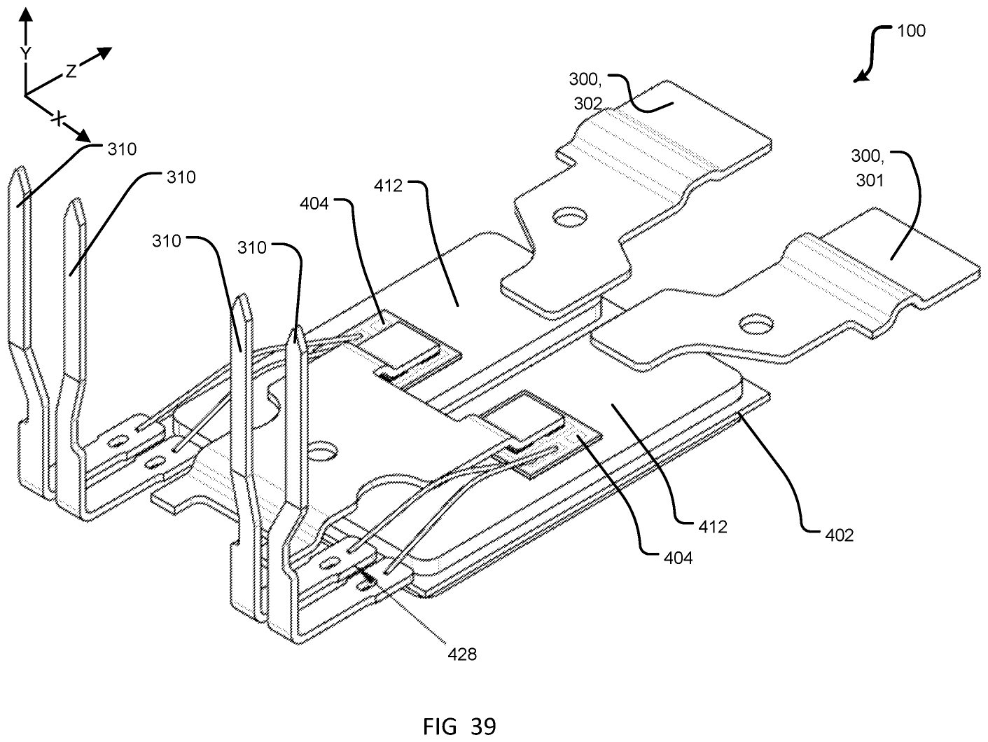

FIG. 39 illustrates a partial perspective view of the power package of FIG. 38.

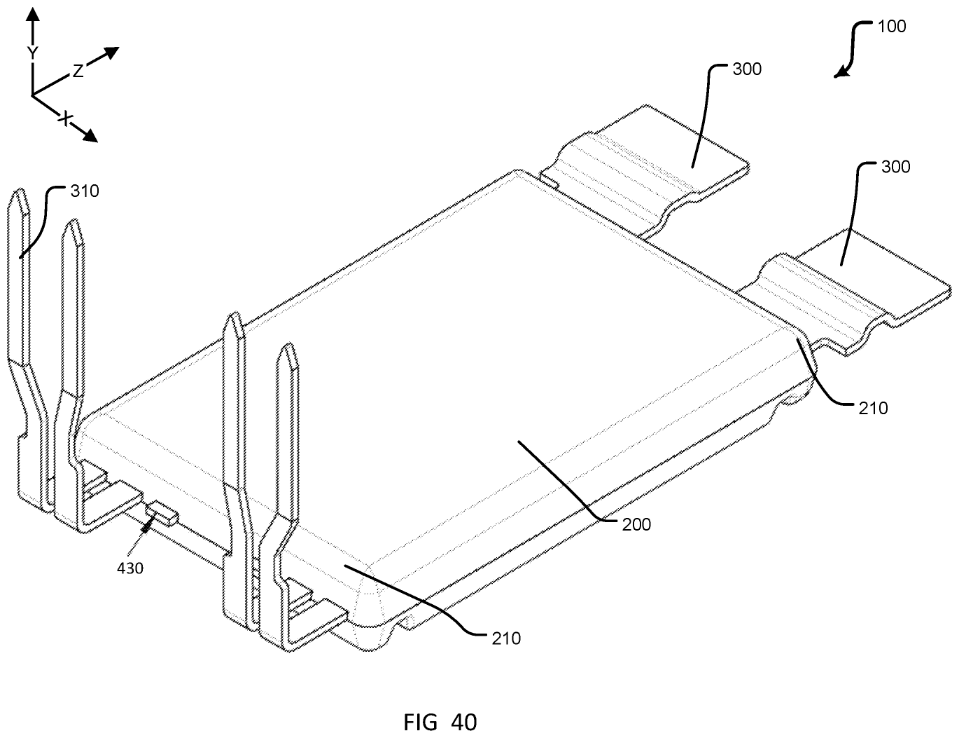

FIG. 40 illustrates a partial perspective view of the power package of FIG. 38.

FIG. 39 illustrates an aspect of the power package 100 configured with two implementations of the at least one power device 404. Here, the power substrate 402 may be divided into two configurations of the primary power traces 412. Additionally, the power package 100 is further configured with a clip 426. In aspects, the clip 426 may be attached to topsides of the at least one power device 404 and configured to form the common source connection.

The at least one power device 404 may be configured with signal pads that may be configured to be directly wire bonded to the at least one of plurality of signal terminals 310. In aspects, this connection may form a true source kelvin signal loop 428. In further aspects, the clip 426 may be integrated into an overall lead frame, with a linkage sites 430 remaining after the power package 100 is trimmed from the lead frame assembly. This may be possible as the source may be the same voltage potential as the source kelvin, so no voltage creepage or clearance distance is required.

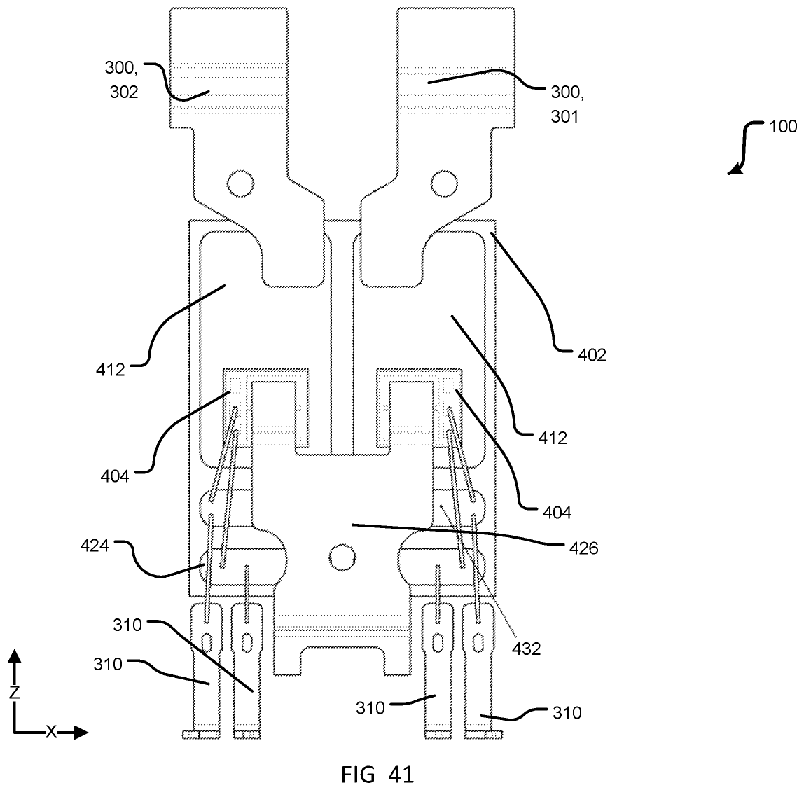

FIG. 41 illustrates a partial top of a power package according to aspects of the disclosure.

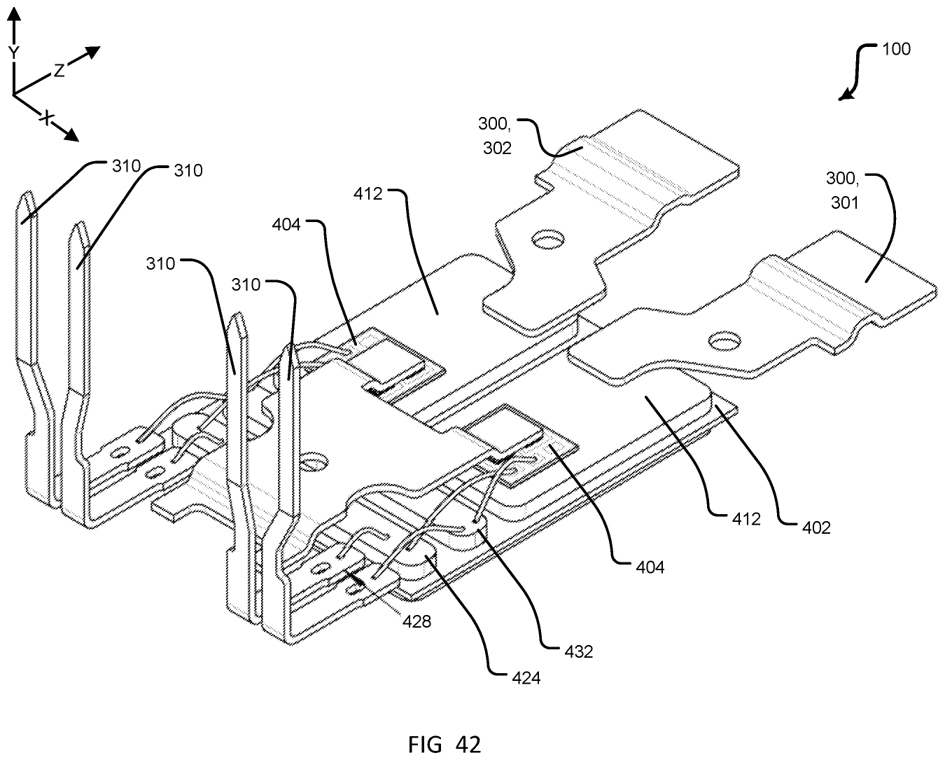

FIG. 42 illustrates a partial perspective view of the power package of FIG. 41.

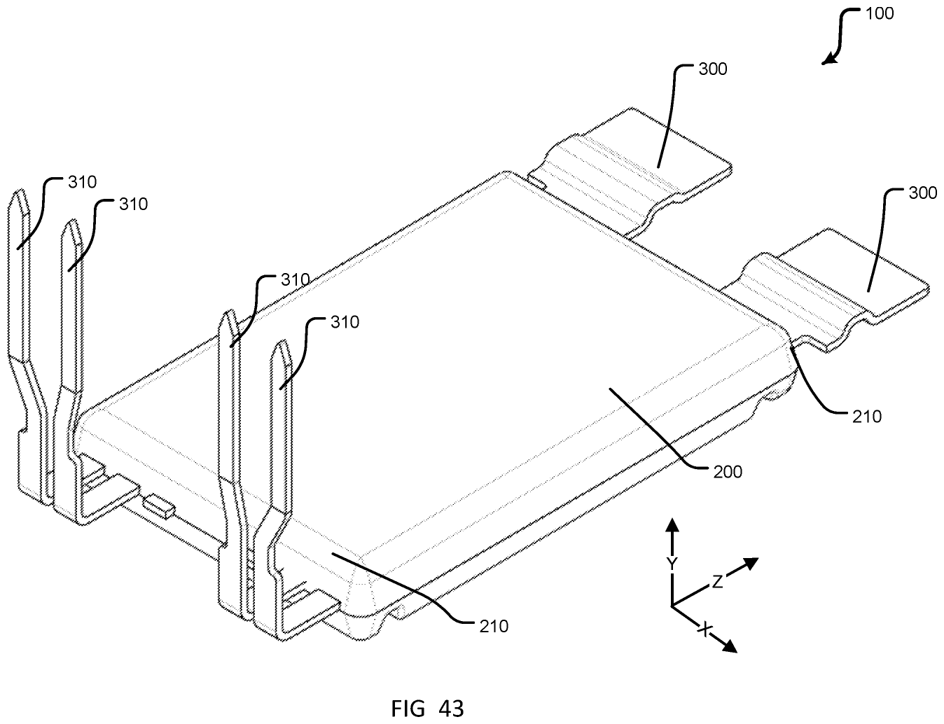

FIG. 43 illustrates a partial perspective view of the power package of FIG. 41.

In particular, FIG. 41, FIG. 42, and FIG. 43 illustrate an implementation of the power package 100 configured with an isolated island trace 432 that may be arranged on the power substrate 402 to act as an interstitial point to bond to, reducing overall wire bond length. In this aspect of the power package 100, this configuration may improve manufacturability of the wire bonds and to prevent wire sweep during a molding process associated with the housing 200. Additionally, there may be room available if the power package 100 includes two implementations of the at least one power device 404. Accordingly, a true kelvin bond is possible.

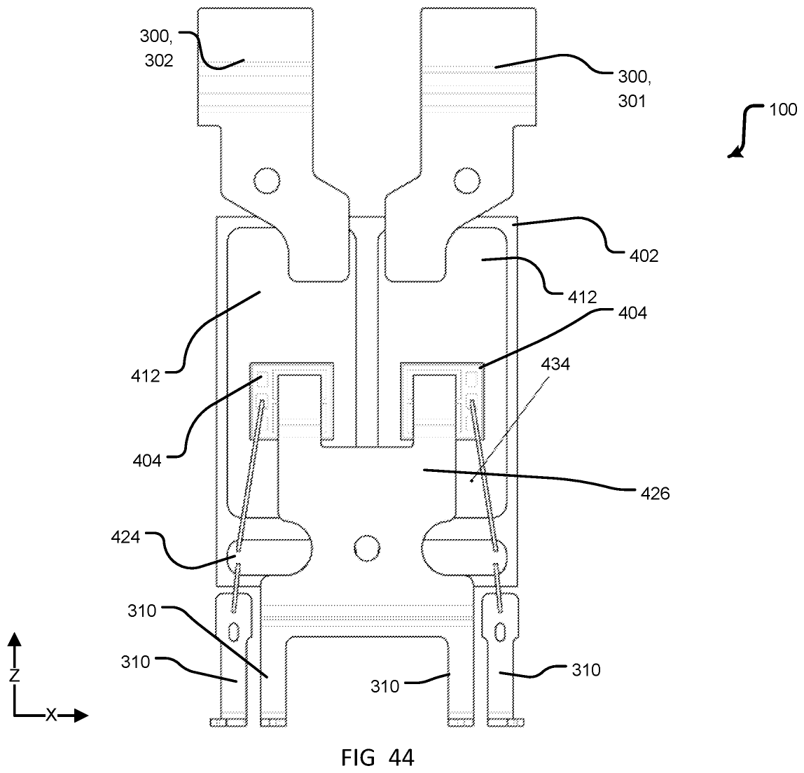

FIG. 44 illustrates a partial top of a power package according to aspects of the disclosure.

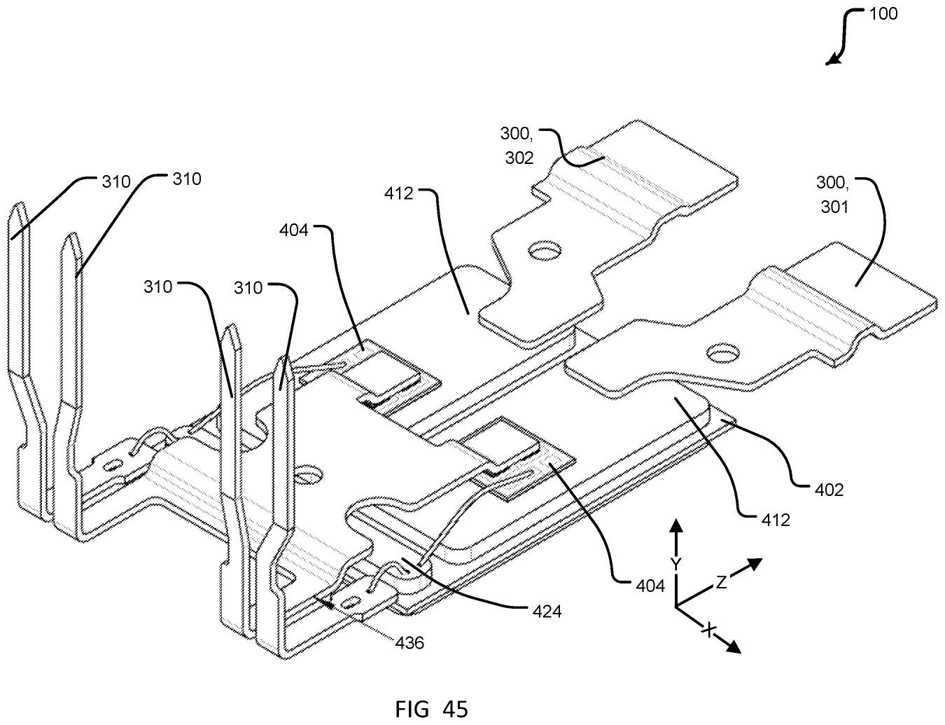

FIG. 45 illustrates a partial perspective view of the power package of FIG. 44.

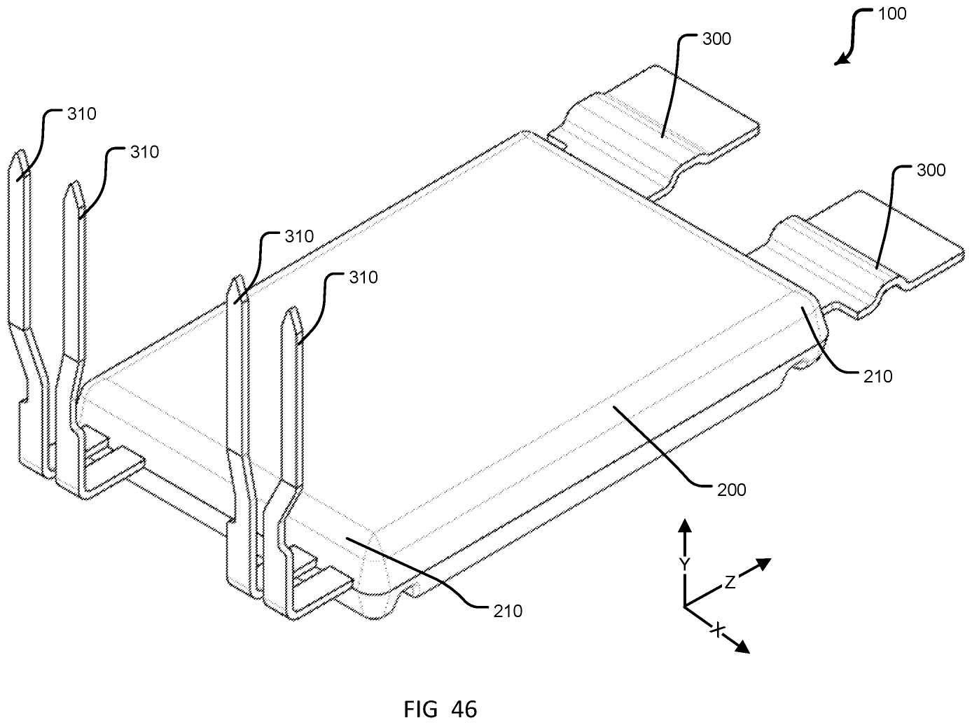

FIG. 46 illustrates a partial perspective view of the power package of FIG. 44.

With reference to FIG. 44, FIG. 45, and FIG. 46, in some implementation cases of the power package 100, a pseudo source kelvin configuration 436 may be sufficient for operation. Accordingly, additional metal around the at least one power device 404 may be used for enhanced heat spreading. This additional metal may form an enhanced thermal region 434. Here, only the gate bond and their associated bonding island may be necessary, which may be implemented by the additional traces 424.

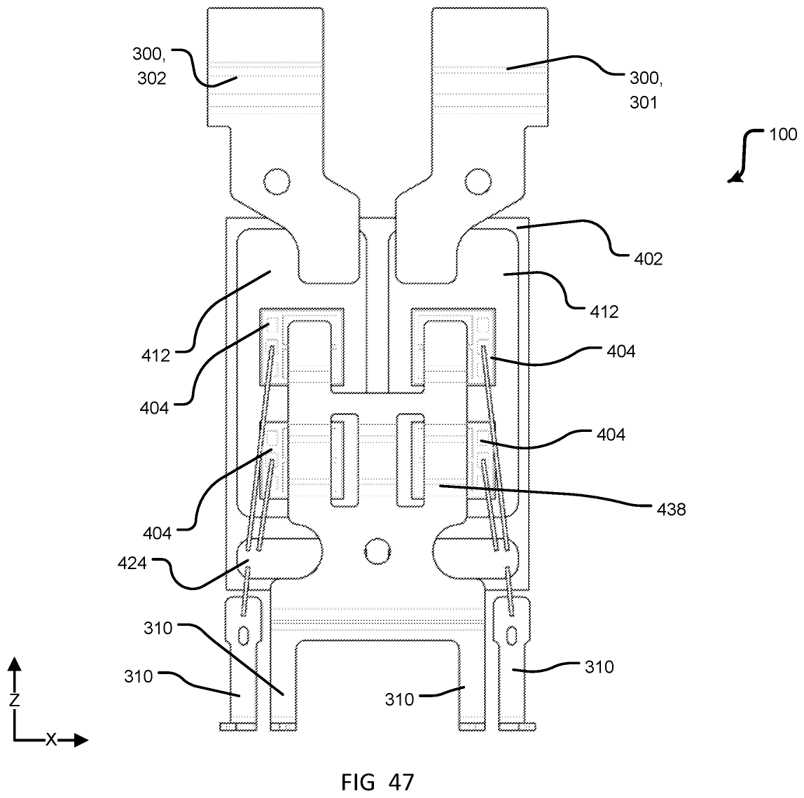

FIG. 47 illustrates a partial top of a power package according to aspects of the disclosure.

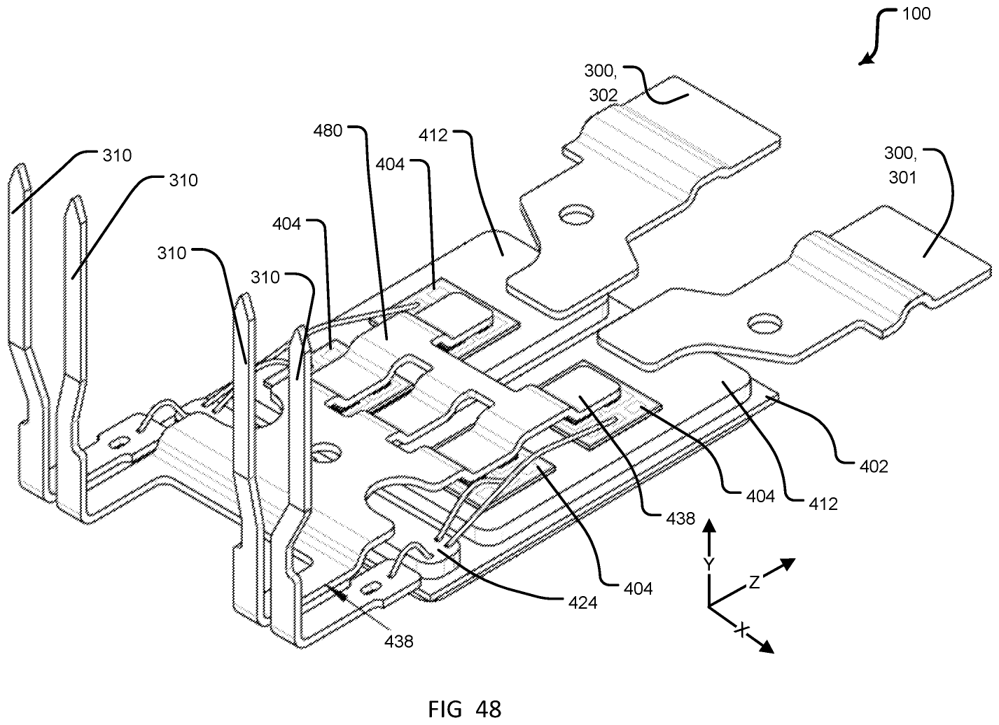

FIG. 48 illustrates a partial perspective view of the power package of FIG. 47.

With reference to FIG. 47 and FIG. 48, in aspects of the power package 100 may be configured with another row of the at least one power device 404. This configuration of the power package 100 may significantly increase output power.

Additionally, as illustrated in FIG. 48, the power package 100 may further include a source contact 438. Additionally, the source contact 438 may have a ripple 480 to connect and upper row of the at least one power device 404. Note that while in the figure each implementation of the at least one power device 404 may be configured with individual gate bonds, in some cases it may be useful to stitch the gate bonds together for each switch position of the power package 100.

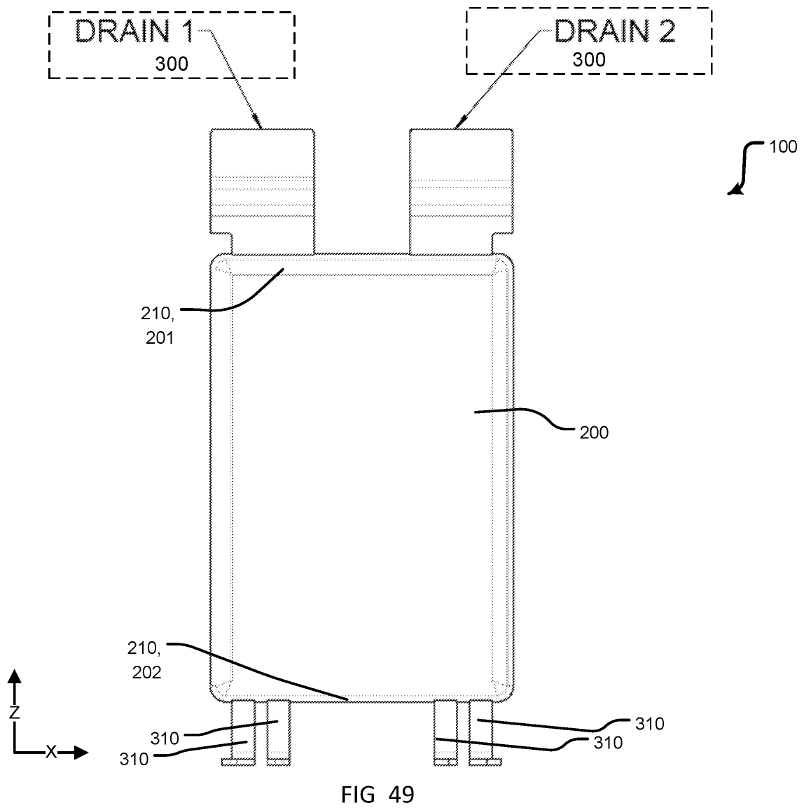

FIG. 49 illustrates a top view of a power package to aspects of the disclosure.

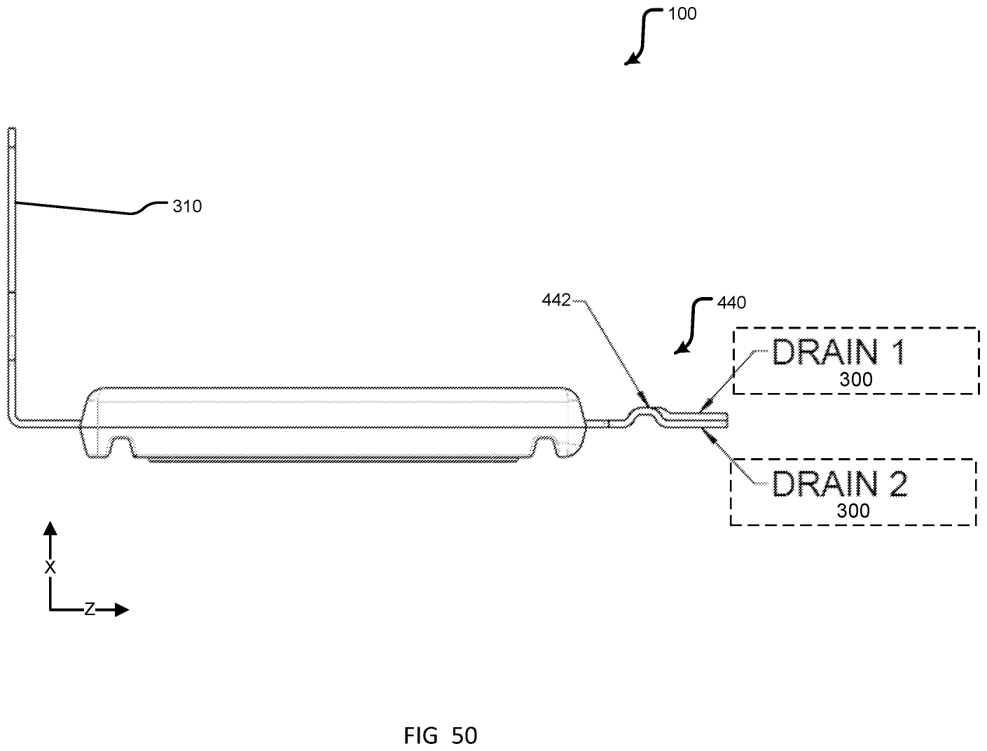

FIG. 50 illustrates a side view of the power package according to FIG. 49.

In particular, FIG. 49 and FIG. 50 illustrate implementations of the power package 100 where the plurality of power terminals 300 that may be offset such that two adjacent implementations of the power package 100 may be placed back-to-back to effectively parallel the switch positions of the power package 100 to increase total output current. In aspects, the offset 440 may arrange one implementation of the plurality of power terminals 300 spaced from another implementation of the plurality of power terminals 300 along the X axis as illustrated in FIG. 50.

The offset 440 may allow for interleaving between the power terminals of adjacent implementations of the power package 100, while being readily accessible for electrical and mechanical connection through welding, soldering, and/or the like. Additionally, the plurality of power terminals 300 may be configured with a bend 442. In aspects, the bend 442 may be spring-like bend is incorporated in the plurality of power terminals 300 to act as a strain relief for two implementations of the power package 100 joined together.

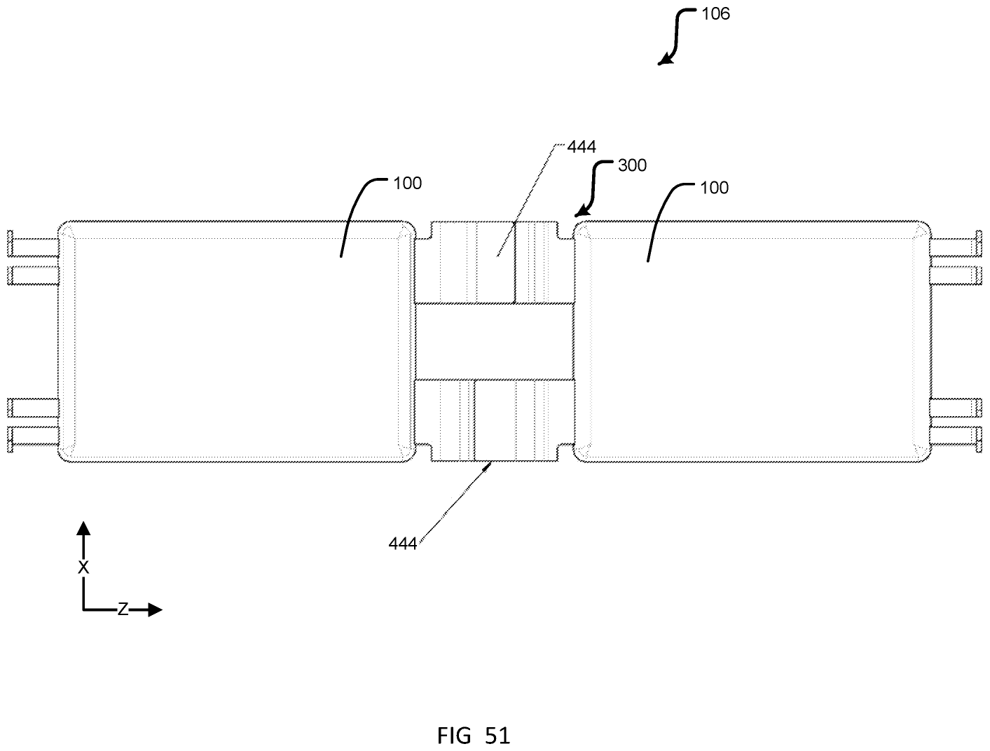

FIG. 51 illustrates a configuration of two implementations of a power package according to aspects of the disclosure.

In particular, FIG. 51 illustrates a configuration 106 of two implementations of the power package 100 according to aspects of the disclosure. In this regard, a set of two implementations of the power package 100 is shown in FIG. 49. In the configuration 106, the two implementations of the power package 100 may have interleaved power connections 444 that are formed by respective implementations of the plurality of power terminals 300. In aspects, an implementation of the plurality of power terminals 300 may be configured as a higher elevation contact from one implementation of the power package 100, which joins with a lower elevation contact implementation of the plurality of power terminals 300 from the other implementation of the power package 100.

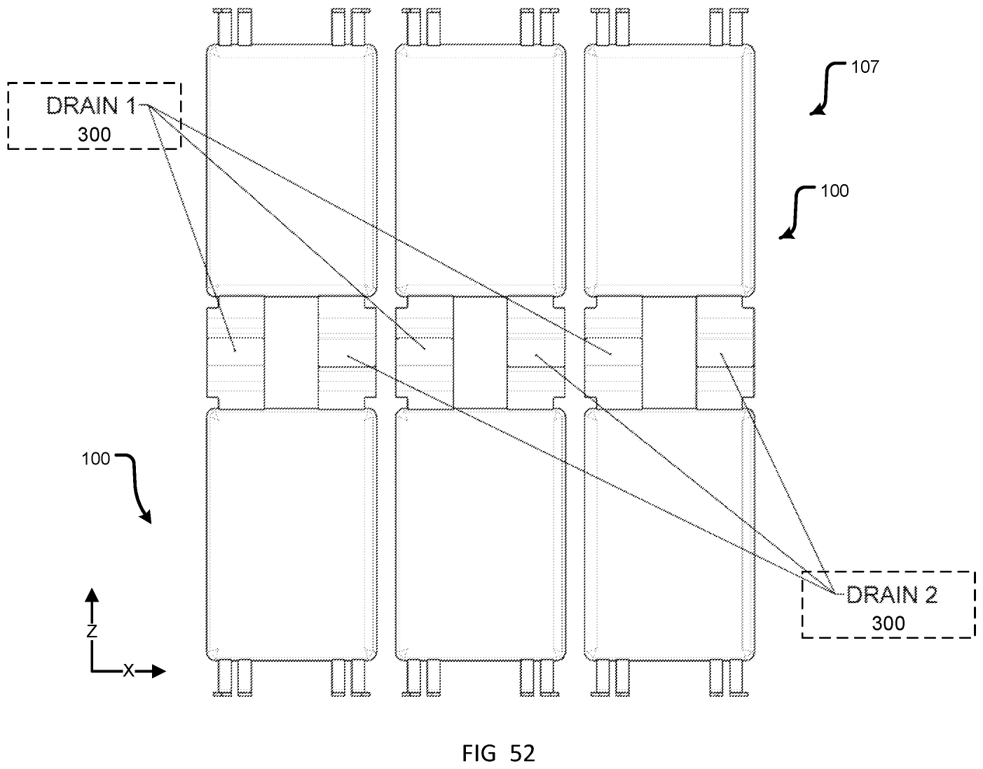

FIG. 52 illustrates a configuration of implementations of a power package according to aspects of the disclosure.

In particular, FIG. 52 illustrates a configuration 107 if more output current is needed. In particular, the configuration 107 illustrates that further paralleling can be achieved with a linear array of implementations of the power package 100.

This is a very high level of modularity and scalability, in which sets of the power package 100 may be configured internally (device count and size) and externally (paralleled packages) to best meet the needs of the system implementing the configuration 107.

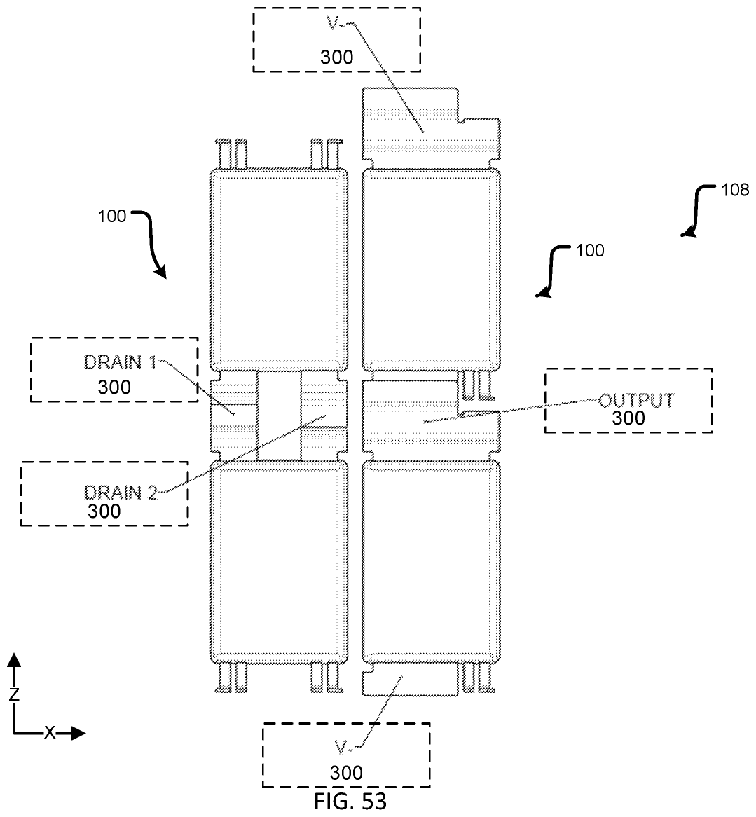

FIG. 53 illustrates a configuration of implementations of a power package according to aspects of the disclosure.

In particular, FIG. 53 illustrates a configuration 108 that may include a plurality of single switch implementations of the power package 100 that may be configured in a T-Type topology. In the configuration 108, one drain connection of the plurality of power terminals 300 implemented by a common source configuration of the power package 100 may be connected to a middle output connection of the plurality of power terminals 300 of a half-bridge leg configuration of the power package 100. This may allow for three level converters which have numerous system level benefits. The plurality of power terminals 300 on one side configuration of the power package 100 may be particularly well suited for this, as the interconnection between implementations of the power package 100 may be more straightforward. In aspects of the configuration 108, the interconnection, external bussing may connect a Drain 1 implementation of the plurality of power terminals 300 to a midpoint of a battery or a capacitor bank and a Drain 2 implementation of the plurality of power terminals 300 may be connected to the output of the bridge leg configuration of the power package 100.

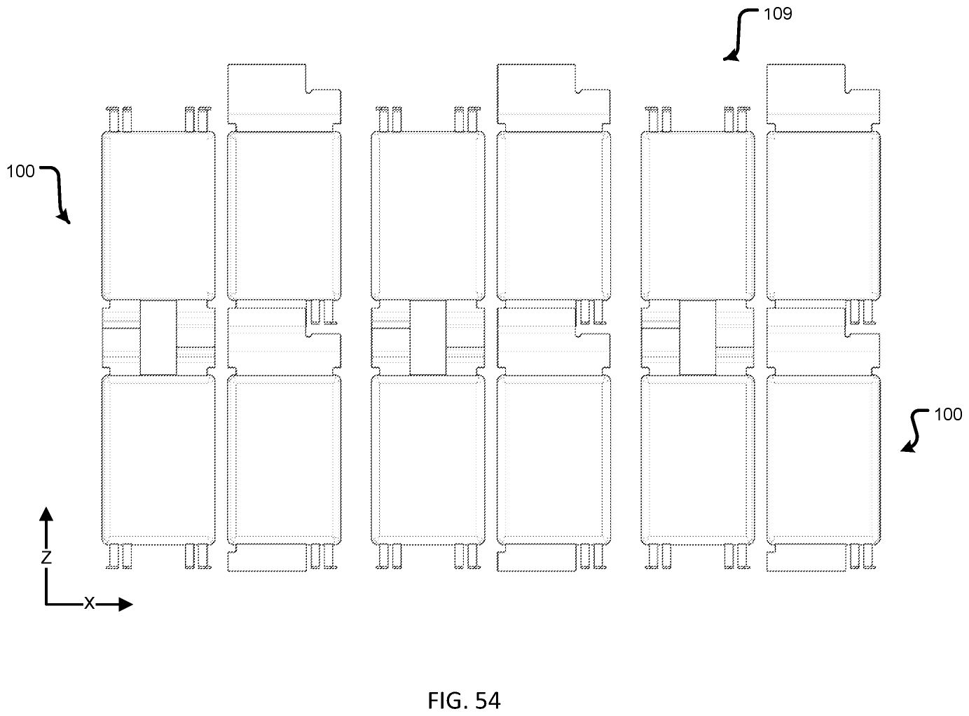

FIG. 54 illustrates a configuration of multiple implementations of a power package according to aspects of the disclosure.

In particular, FIG. 54 illustrates a configuration 109 that may include a plurality of single switch implementations of the power package 100 that may be further paralleled and configured in a T-Type topology. This paralleling may increase phase output current or introduce additional phases such as a three phase inverter.

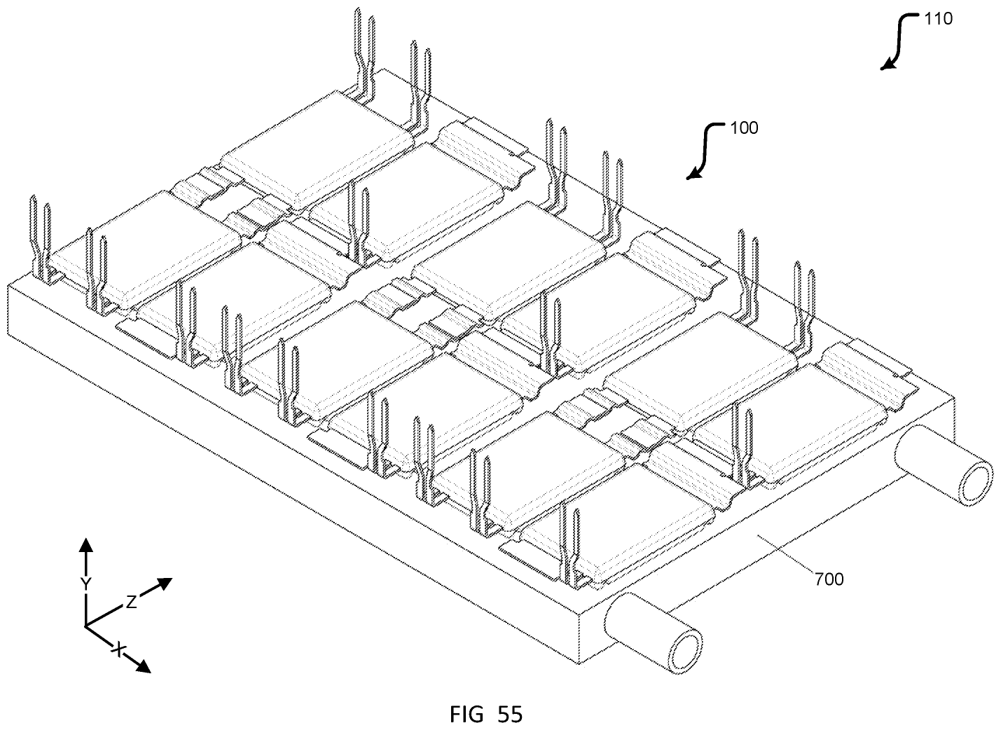

FIG. 55 illustrates a configuration of multiple implementations of a power package according to aspects of the disclosure.

In particular, FIG. 55 illustrates a configuration 110 that may be implemented in a system. In particular, multiple implementations of the power package 100 may be thermally attached to a heat sink, a cold plate 700, and/or the like. In aspects, the multiple implementations of the power package 100 may be configured in a T-Type three phase topology. Additionally, the cold plate 700 or an associated cooling system may be scaled to match the number of implementations of the power package 100 in the array.

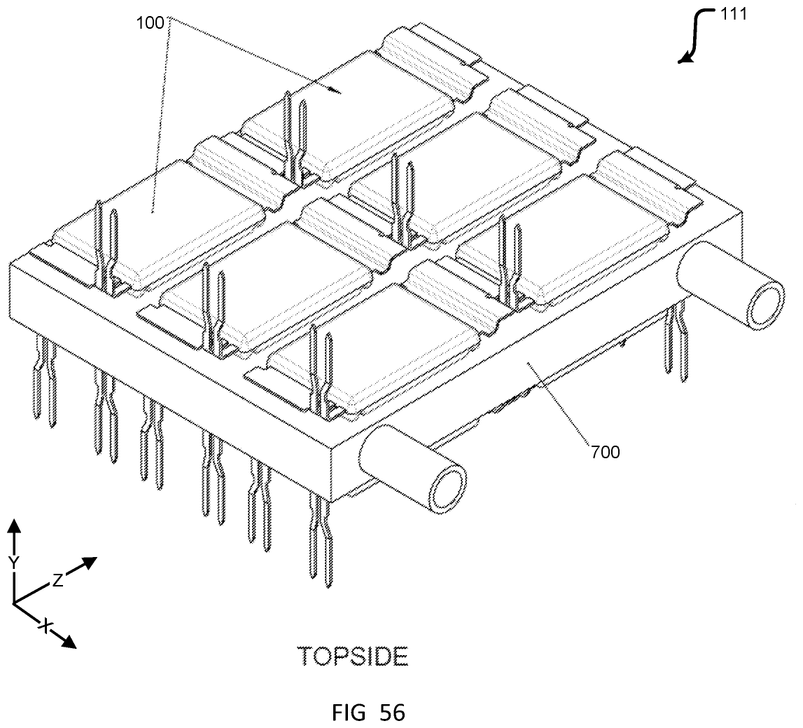

FIG. 56 illustrates a topside view of a configuration of multiple implementations of a power package according to aspects of the disclosure.

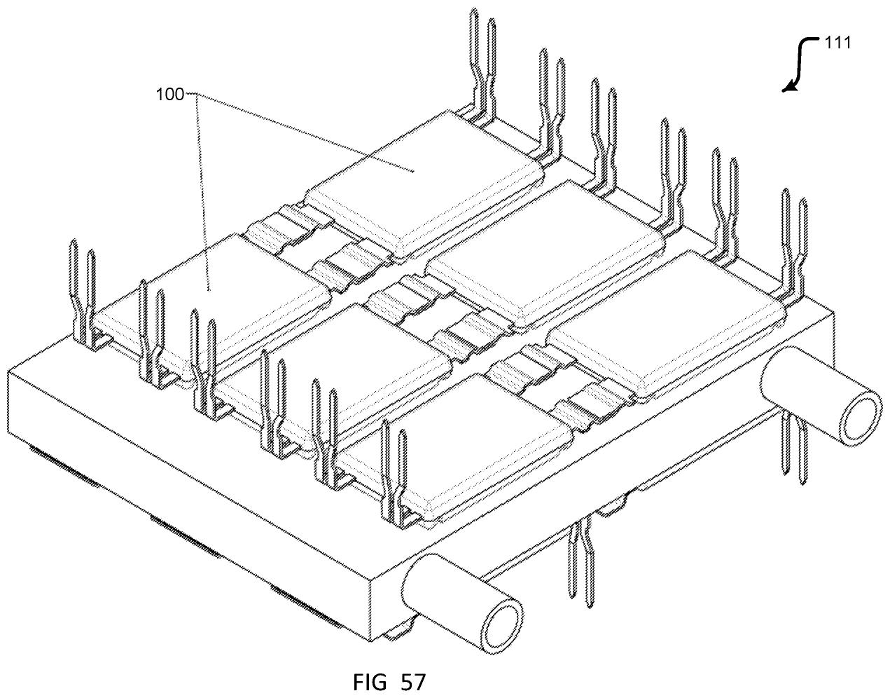

FIG. 57 illustrates a backside view of the configuration of multiple implementations of a power package according to FIG. 56.

In particular, FIG. 56 and FIG. 57 illustrate a configuration 111 where top and bottom surfaces of the cold plate 700 may be used for cooling. In this regard, in some system approaches both sides of the cold plate 700 may be populated with implementations of the power package 100. While this may introduce a more complex manufacturing method, it may result in very compact, power dense solutions.

This is shown for the case of a three phase T-Type topology where a plurality of half bridge leg topology configurations of the power package 100 are arranged on the topside of the cold plate 700 as illustrated in FIG. 56 and a plurality of common source topology configurations of the power package 100 are arranged on a bottom side of the cold plate 700 as illustrated in FIG. 57. In this regard, placing the implementations of the power package 100 on both sides of the cold plate 700 may be a compact way to parallel more packages in a small footprint.

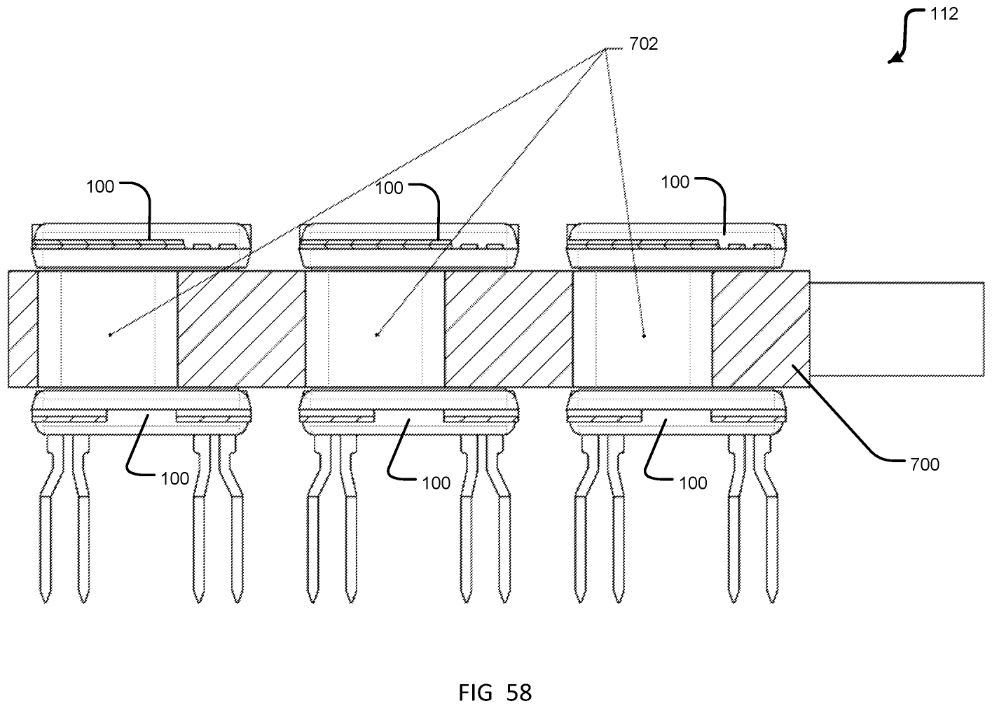

FIG. 58 illustrates a cross-sectional view of a configuration of multiple implementations of a power package according to aspects of the disclosure.

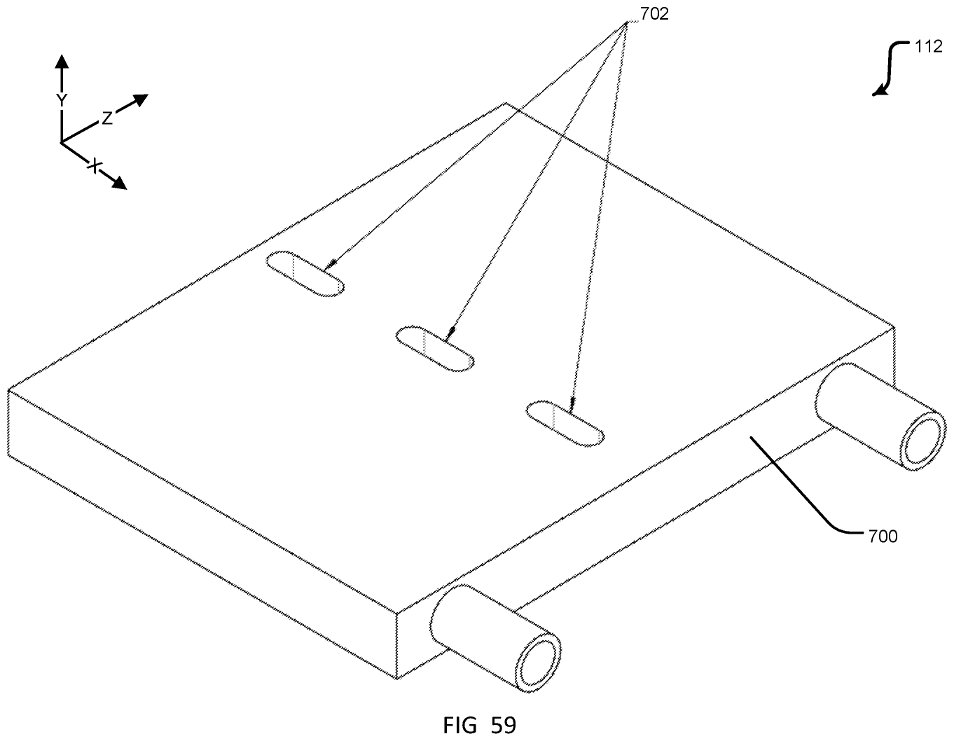

FIG. 59 illustrates a perspective view of the configuration of multiple implementations of a power package according to FIG. 58.

In particular, FIG. 58 and FIG. 59 illustrate a configuration 112 of a plurality of implementations of the power package 100 arranged on both sides of the cold plate 700. Further, interconnection between top implementations of the power package 100 and bottom side implementations of the power package 100 may be achieved with wrap-around bus bars or cables.

In other aspects, for minimal inductance and weight, the configuration 112 may be implemented with a “pass-through” conductor (not shown) that may connect to respective implementations of the plurality of power terminals 300 of other respective implementations of the power package 100. In aspects, the cold plate 700 may be configured with through holes 702 in the cold plate 700. For the T-Type Inverter, for example, the drain connection of the plurality of power terminals 300 of the common source configuration of the power package 100 may pass through with an isolated bus bar up to AC output terminals of the bridge leg configurations of the power package 100.

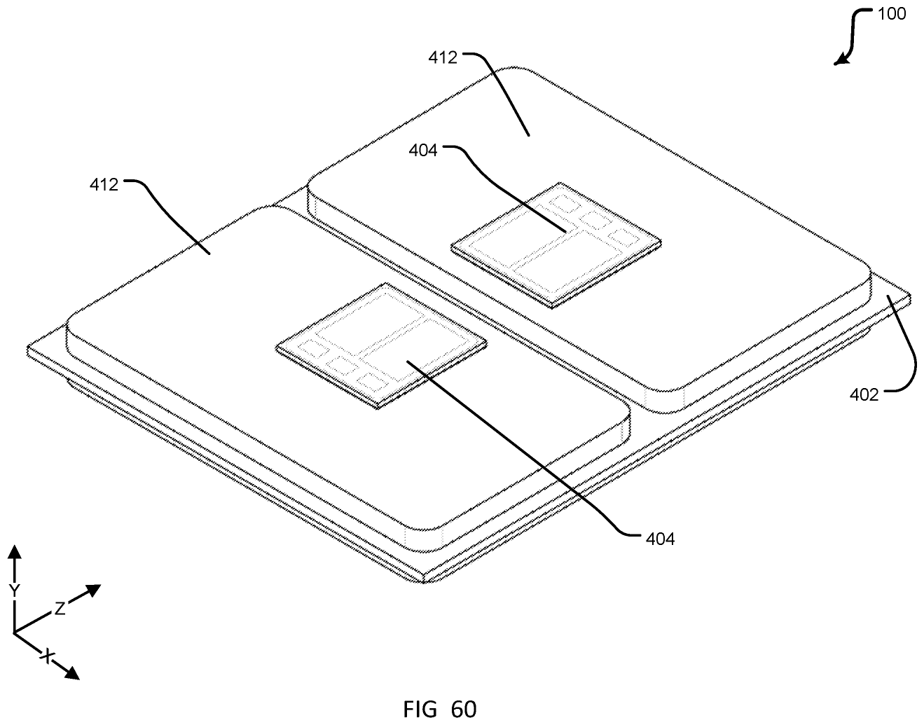

FIG. 60 illustrates a perspective view of an implementation of a power substrate according to aspects of the disclosure.

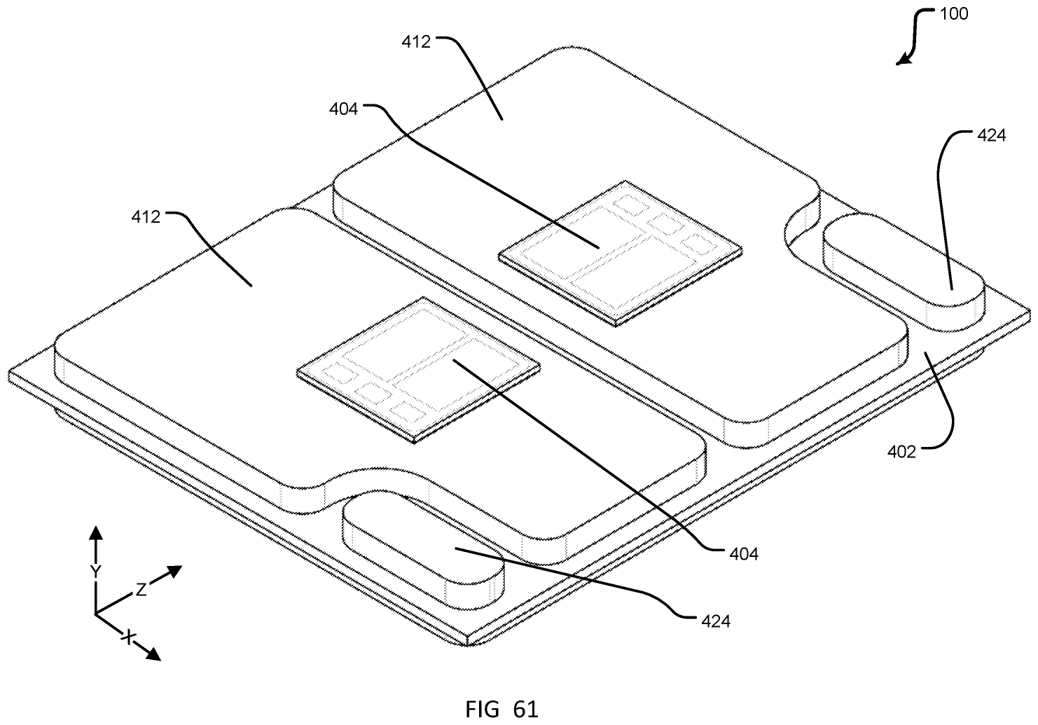

FIG. 61 illustrates a perspective view of another implementation of a power substrate according to aspects of the disclosure.

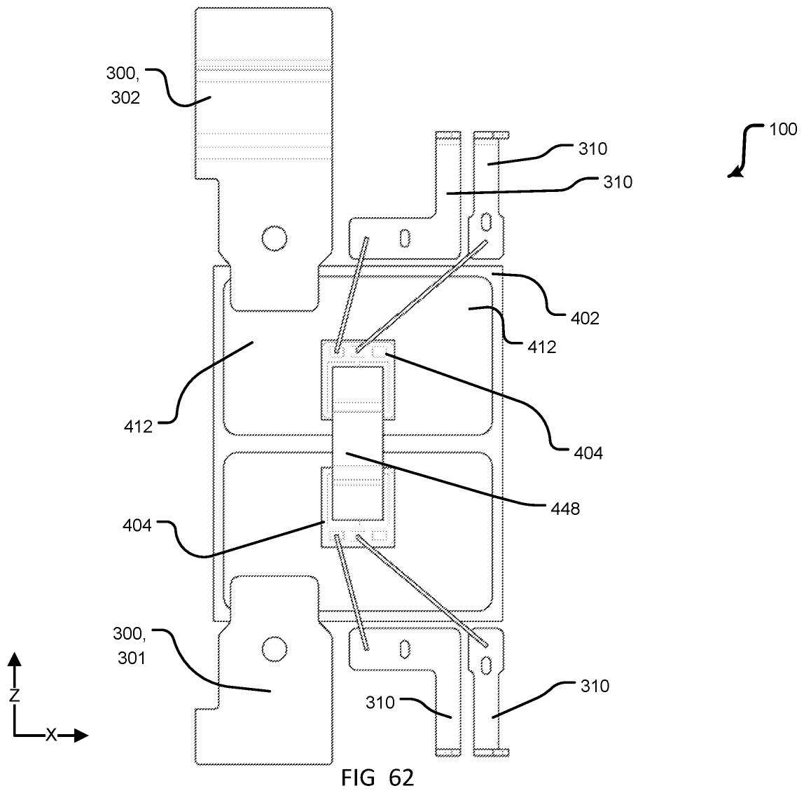

FIG. 62 illustrates a top view of an implementation of a power package according to aspects of the disclosure.

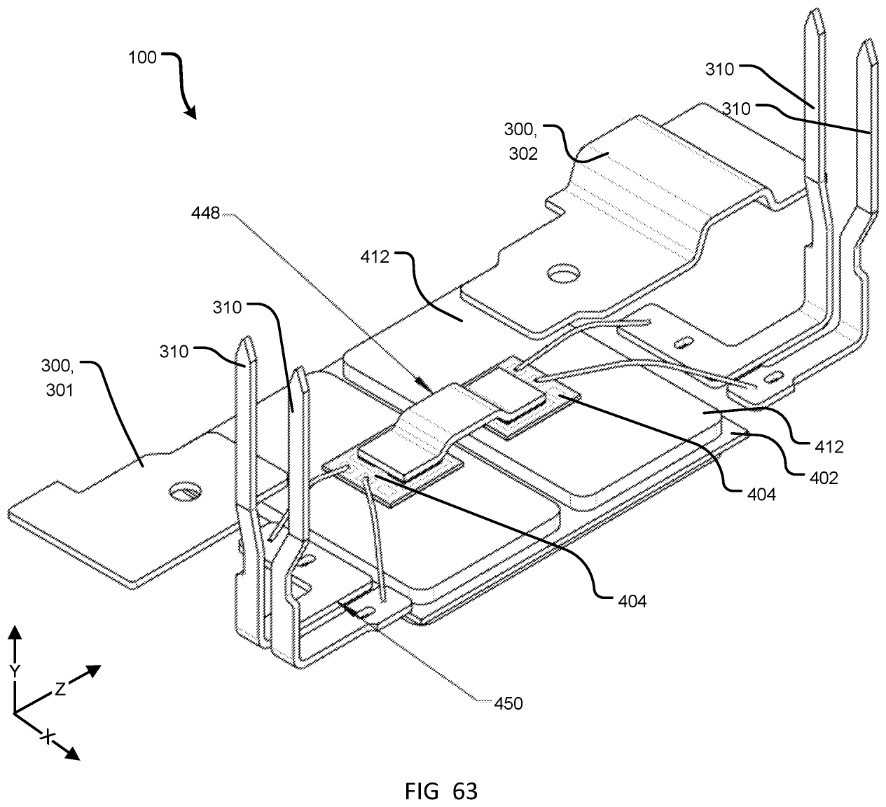

FIG. 63 illustrates a perspective view of an implementation of a power package according to FIG. 62.

In particular, FIG. 62 illustrates an implementation of the power package 100 that may include the plurality of power terminals 300 and the at least one of plurality of signal terminals 310 on both sides of the power package 100. The internal layout to accompany the external terminal arrangement of the power package 100 may vary based on the number of the at least one power device 404, source kelvin implementation, performance optimizations, and/or the like.

While the illustrated layouts of the power package 100 illustrated and described may use the same size implementation of the at least one power device 404 as a reference, other embodiments of the power package 100 are possible which take advantage of the modularity of the layout of the power package 100 to best meet the power needs of a given system. In aspects, the power package 100 may be configured with fully populated device locations of the at least one power device 404, partially populated device locations of the at least one power device 404, larger and smaller device size implementations of the at least one power device 404, implementations of the at least one power device 404 configured with different gate and source pad sizes and arrangements, topside clip variations to accommodate the gate and source pad configurations, and/or power wire bond/ribbon interconnections instead of the topside clip.

FIG. 60 illustrates an exemplary layout of the power substrate 402 that may be implemented in any aspect of the power package 100 as described herein including the implementation illustrated in FIG. 62. As illustrated in FIG. 60, the power substrate 402 may be implemented with primary power traces 412. In aspects, the power substrate 402 may have two implementations of the primary power traces 412 for each drain connection of the at least one power device 404. Implementations of the at least one power device 404 may be attached to the primary power traces 412. In aspects, implementations of the at least one power device 404 may be attached in center locations of the primary power traces 412 to minimize thermal resistance by maximizing the effect of heat spreading.

As illustrated in FIG. 61, in some cases, the power substrate 402 may be implemented with additional traces 424 added to the power substrate 402 to accommodate additional functionality. In one case, one or multiple implementations of the additional traces 424 may be added to the power substrate 402 to act as interstitial sites to reduce wire bond length. In other cases, implementations of the power substrate 402 may be configured as isolated traces that may be added to the power substrate 402 in order to accommodate sensing elements such as a temperature sensor as described herein.

As further illustrated in FIG. 62, the power package 100 may have a configuration for two implementations of the at least one power device 404. Here, the power substrate 402 may be divided into two implementations of the primary power traces 412. Additionally, the power package 100 may be implemented with a source clip 448. In aspects, the source clip 448 may be attached to topsides of the at least one power device 404 to form a common source connection 450. In aspects, signal pads on the at least one power device 404 may be directly wire bonded to at least one of the plurality of signal terminals 310, forming a true source kelvin signal loop. The source clip 448 may be a standalone piece or joined to an external lead frame through a linkage (not shown). Additionally, the source clip 448 may also be configured using wire bonds, ribbon, an interconnect configuration and/or interconnect process as described herein, and/or the like.

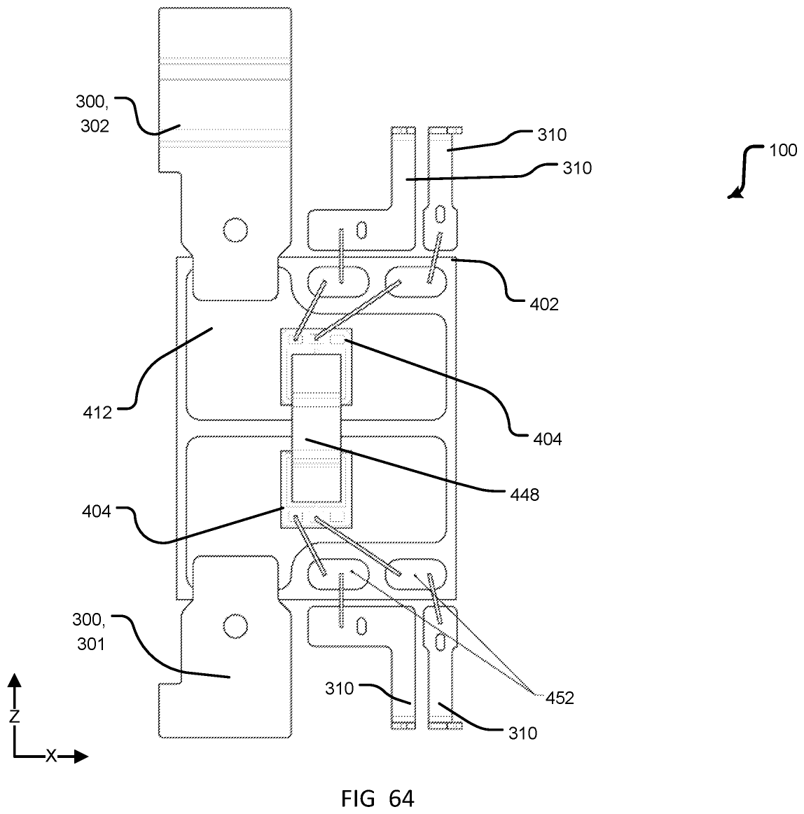

FIG. 64 illustrates a top view of a power package according to aspects of the disclosure.

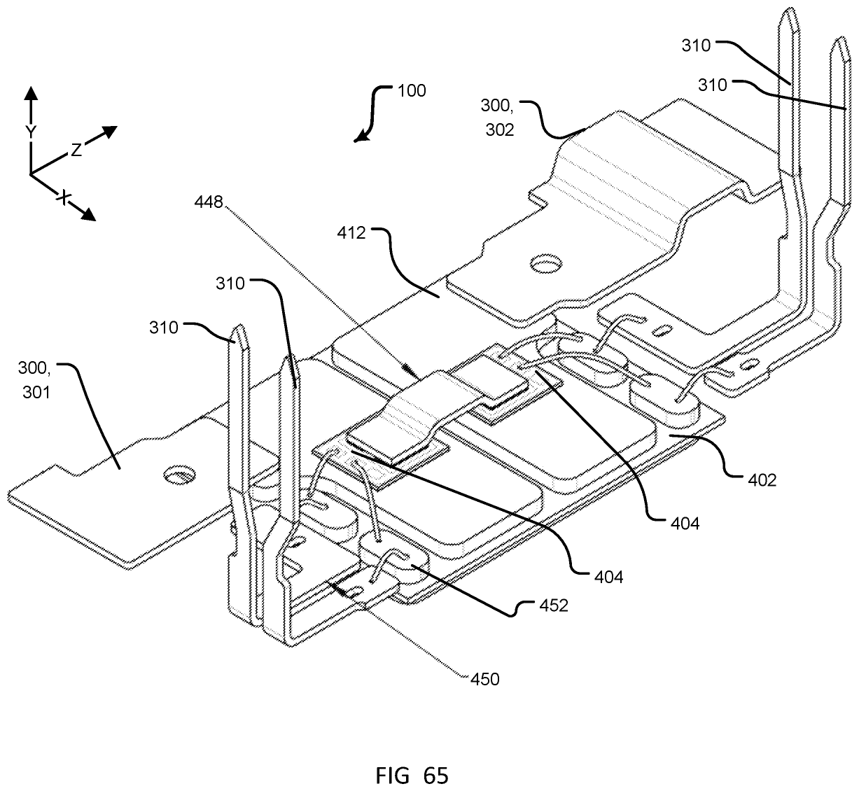

FIG. 65 illustrates a top perspective view of the power package according to FIG. 64.

In particular, FIG. 64 and FIG. 65 illustrate an aspect of the power package 100 that may further include isolated island traces 452 on the power substrate 402 that may be configured to act as an interstitial point to bond to, reducing overall wire bond length. This may be useful to improve manufacturability of the wire bonds and to prevent wire sweep during a molding process for the housing 200. With the room available on the power substrate 402 by only using two implementations of the at least one power device 404, a true kelvin bond may be possible.

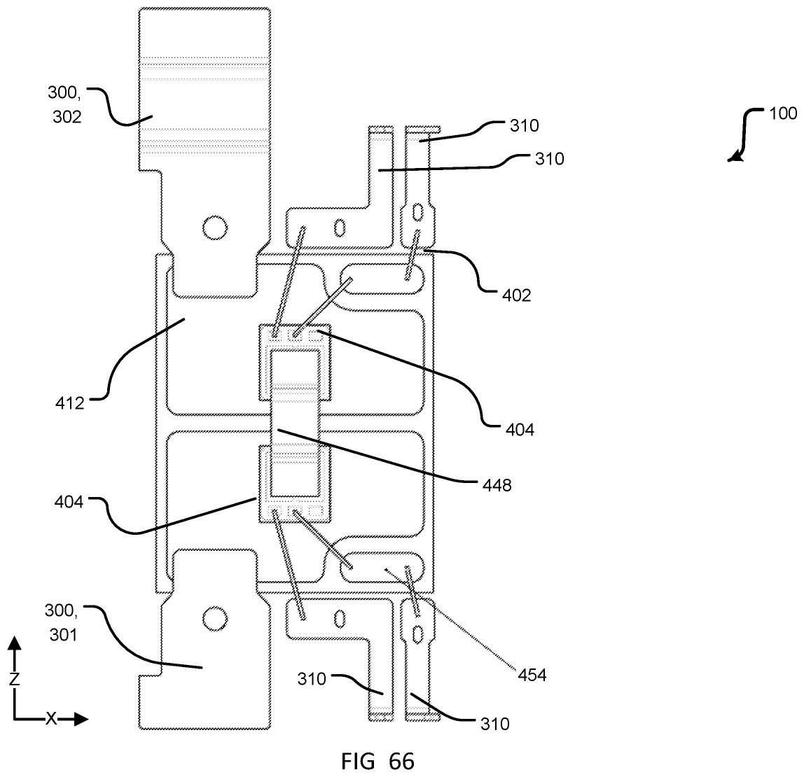

FIG. 66 illustrates a top view of a power package according to aspects of the disclosure.

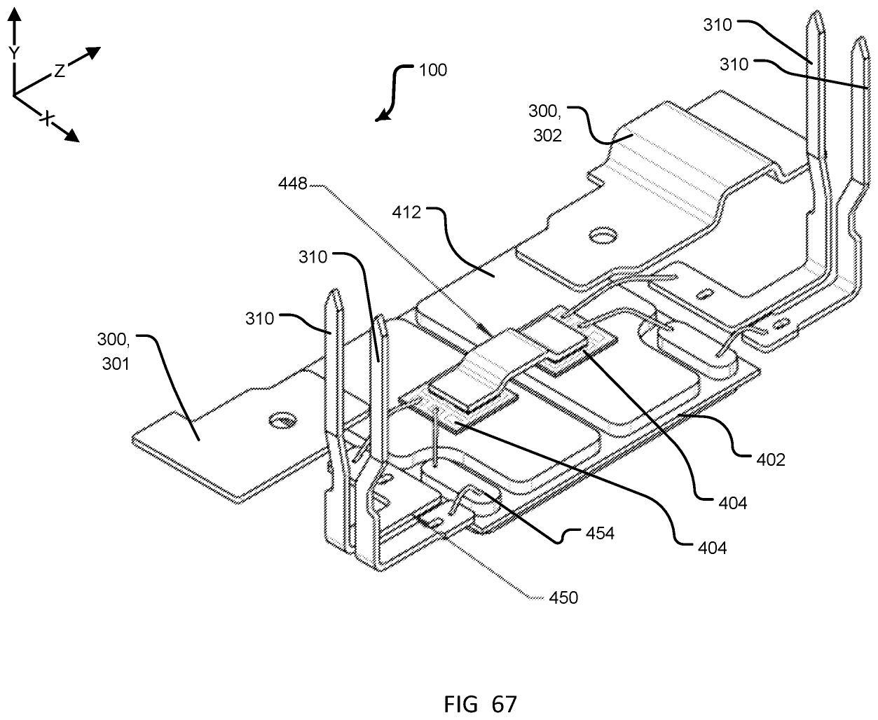

FIG. 67 illustrates a top perspective view of the power package according to FIG. 66.

In particular, FIG. 66 in FIG. 67 illustrate an aspect of the power package 100 that may further include a single island trace 454. For some implementations of the power package 100, one of the signal bonds may be short enough that it would not need the interstitial island, while others may. In this case, only one single island trace 454 may be needed, and a direct bond can be used for the other, as shown in FIG. 67. This would be useful to increase the amount of copper around the device to enhance heat spreading and thermal performance. It should also be used to free up space to add a sensing element and its associated terminals and bonds.

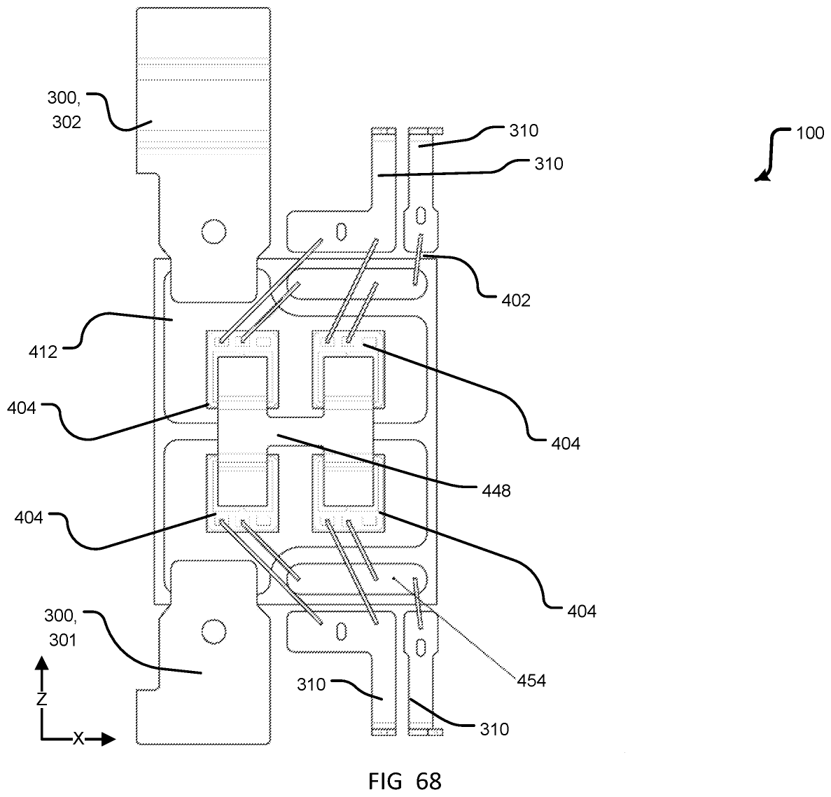

FIG. 68 illustrates a partial top of a power package according to aspects of the disclosure.

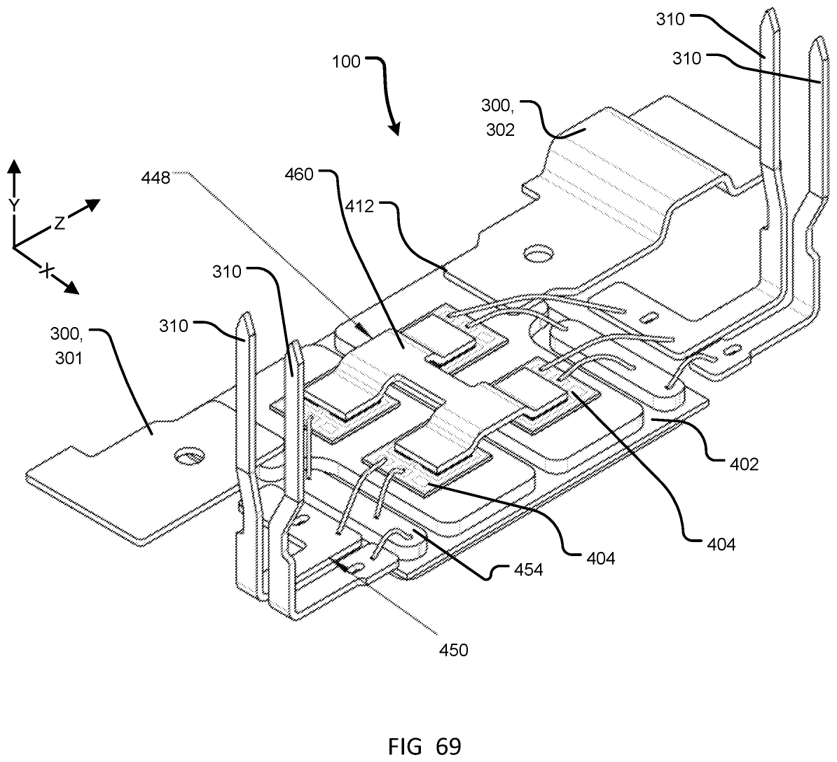

FIG. 69 illustrates a partial perspective view of the power package of FIG. 68.

With reference to FIG. 68 and FIG. 69, in aspects of the power package 100 may be configured with another row of the at least one power device 404. This configuration of the power package 100 may significantly increase output power.

Additionally, as illustrated in FIG. 68, the power package 100 may further include the source clip 448. Additionally, the source clip 448 may have a ripple 460 to connect and upper row of the at least one power device 404. Note that while in the figure each implementation of the at least one power device 404 may be configured with individual gate bonds, in some cases it may be useful to stitch the gate bonds together for each switch position of the power package 100.

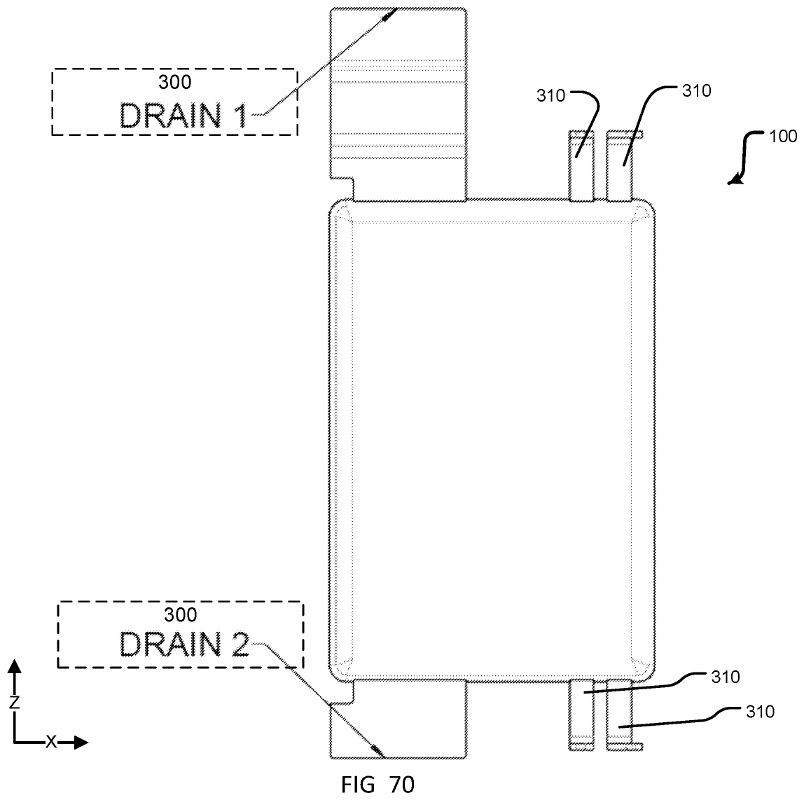

FIG. 70 illustrates a top view of a power package to aspects of the disclosure.

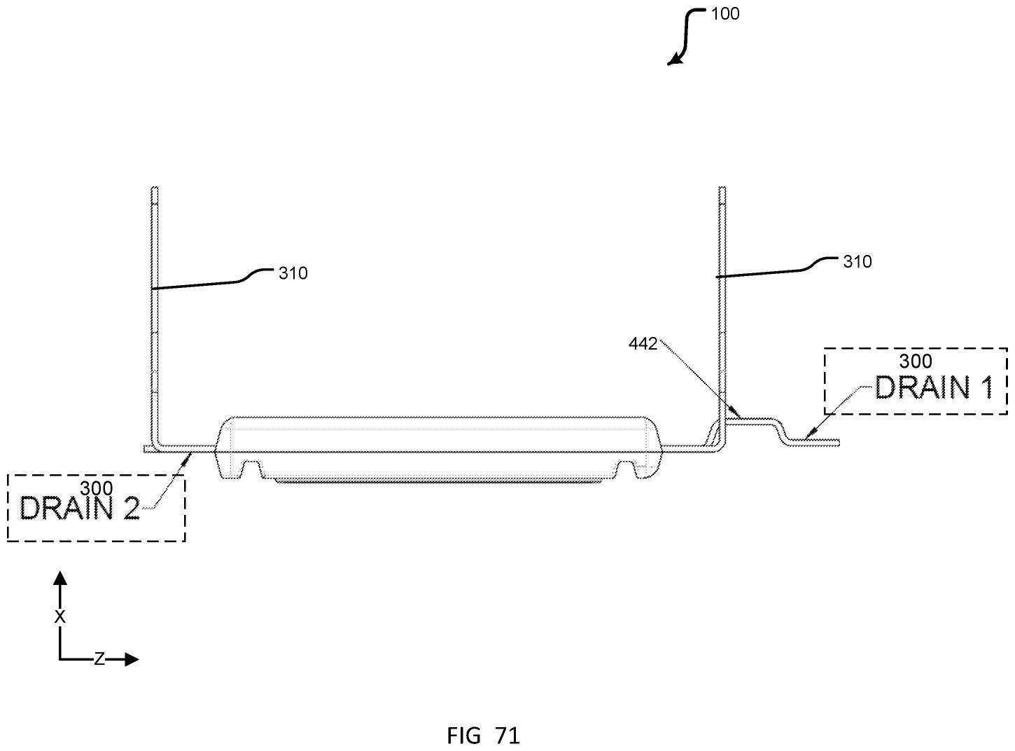

FIG. 71 illustrates a side view of the power package according to FIG. 70.

In particular, FIG. 70 and FIG. 71 illustrate implementations of the power package 100 where the plurality of power terminals 300 may be offset such that two adjacent implementations of the power package 100 may be placed back-to-back to effectively parallel the switch positions of the power package 100 to increase total output current. The offset may allow for interleaving between the plurality of power terminals 300 of adjacent implementations of the power package 100, while being readily accessible for electrical and mechanical connection through welding, soldering, and/or the like. Additionally, the plurality of power terminals 300 may be configured with a bend 442. In aspects, the bend 442 may be spring-like bend is incorporated in the plurality of power terminals 300 to act as a strain relief for two implementations of the power package 100 joined together.

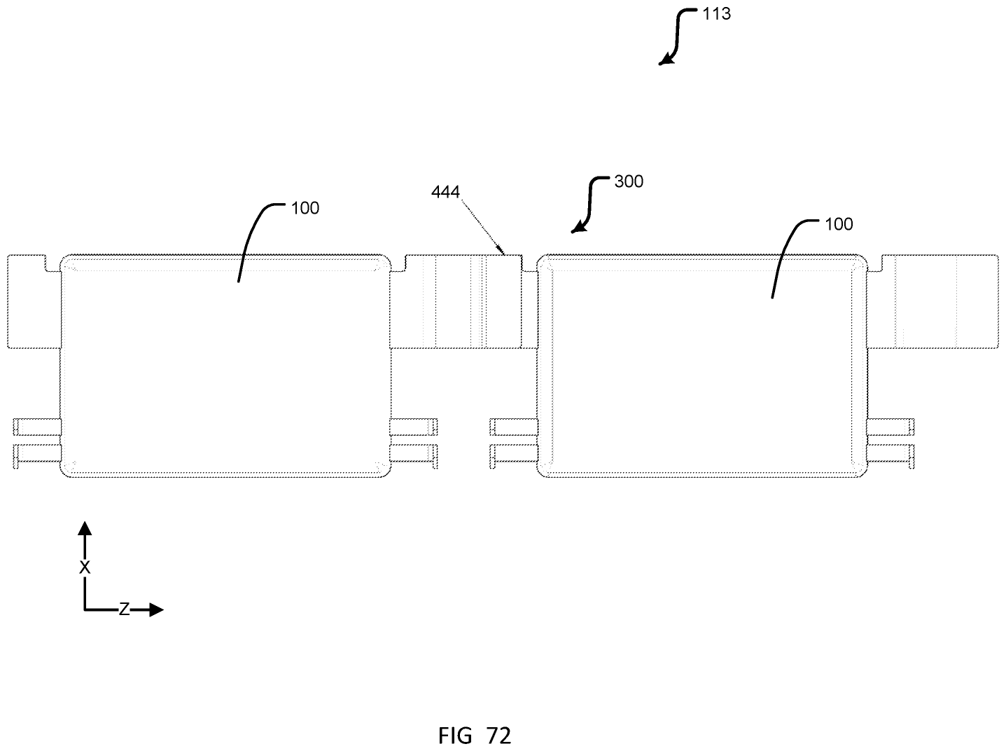

FIG. 72 illustrates a configuration of two implementations of a power package according to aspects of the disclosure.

In particular, FIG. 72 illustrates a configuration 113 of two implementations of the power package 100 according to aspects of the disclosure. In this regard, a set of two implementations of the power package 100 as shown in FIG. 70. In the configuration 113, the two implementations of the power package 100 may have interleaved power connections 444 that are formed by respective implementations of the plurality of power terminals 300. In aspects, an implementation of the plurality of power terminals 300 may be configured as a higher elevation contact from one implementation of the power package 100, which joins with a lower elevation contact implementation of the plurality of power terminals 300 from the other implementation of the power package 100.

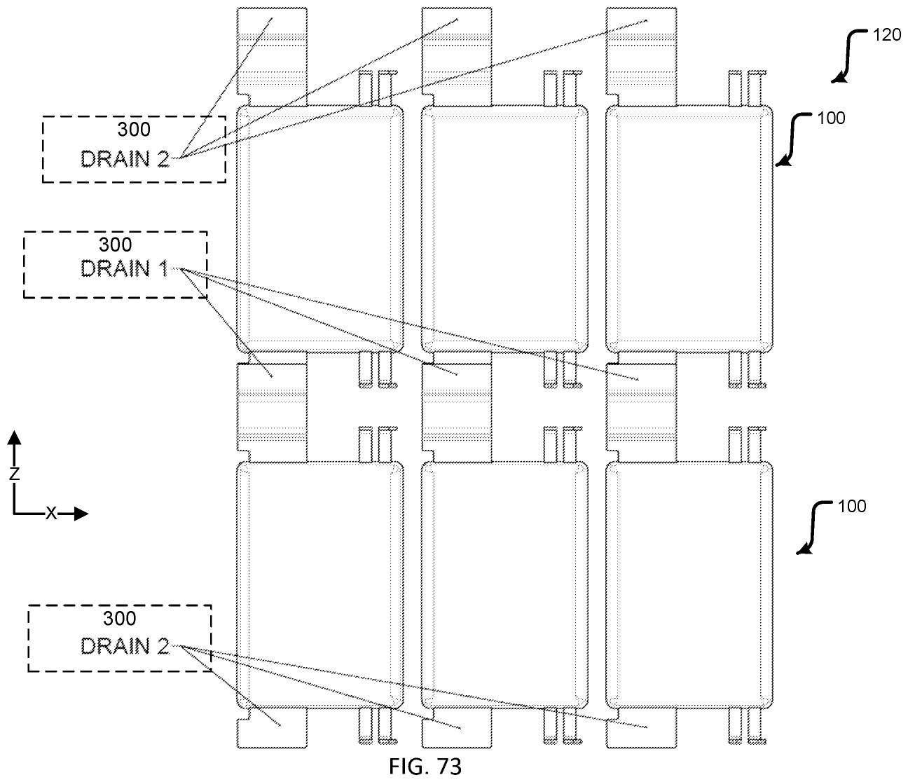

FIG. 73 illustrates a configuration of implementations of a power package according to aspects of the disclosure.

In particular, FIG. 73 illustrates a configuration 120 if more output current is needed. In particular, the configuration 120 illustrates that further paralleling can be achieved with a linear array of implementations of the power package 100.

This is a very high level of modularity and scalability, in which sets of the power package 100 may be configured internally (device count and size) and externally (paralleled packages) to best meet the needs of the system implementing the configuration 120.

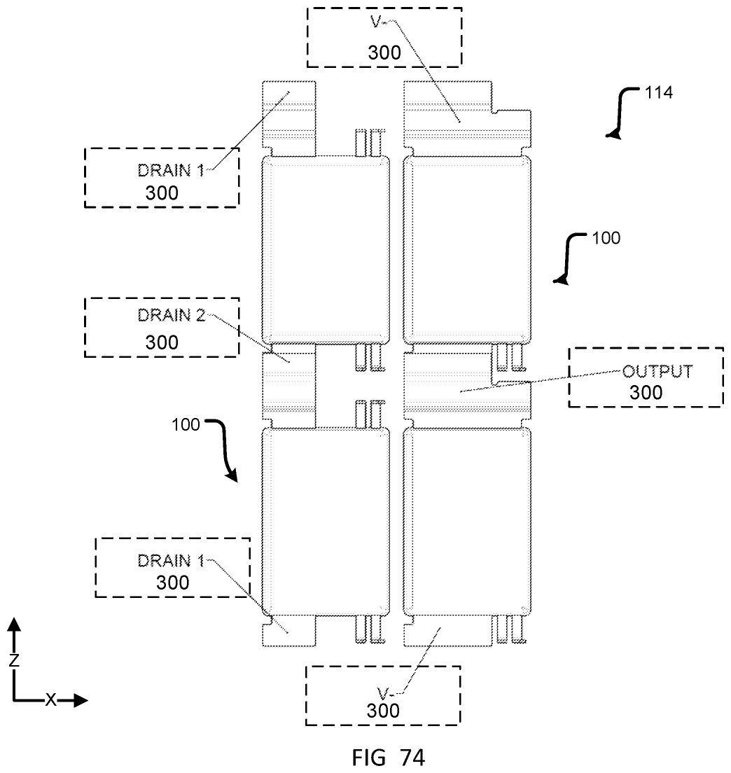

FIG. 74 illustrates a configuration of two implementations of a power package according to aspects of the disclosure.

In particular, FIG. 74 illustrates a configuration 114 if more output current is needed. In particular, the configuration 114 illustrates that further paralleling can be achieved with a linear array implementations of the power package 100. More specifically, a set of two paralleled implementations of the power package 100 is shown in FIG. 74. The interleaved power connections are also depicted, where the higher elevation contact implementation of the plurality of power terminals 300 from one implementation of the power package 100 joins with the lower elevation contact implementation of the plurality of power terminals 300 from the other implementation of the power package 100.

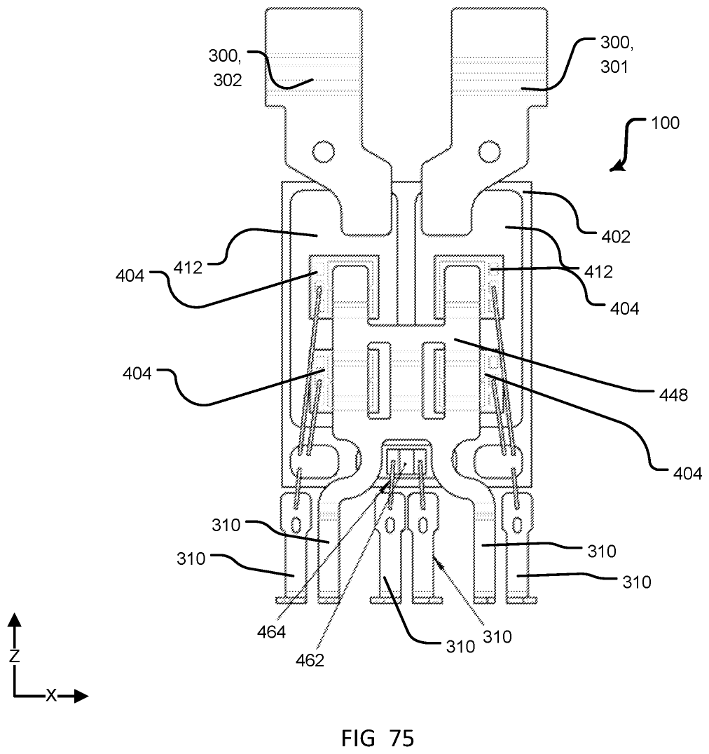

FIG. 75 illustrates a partial top of a power package according to aspects of the disclosure.

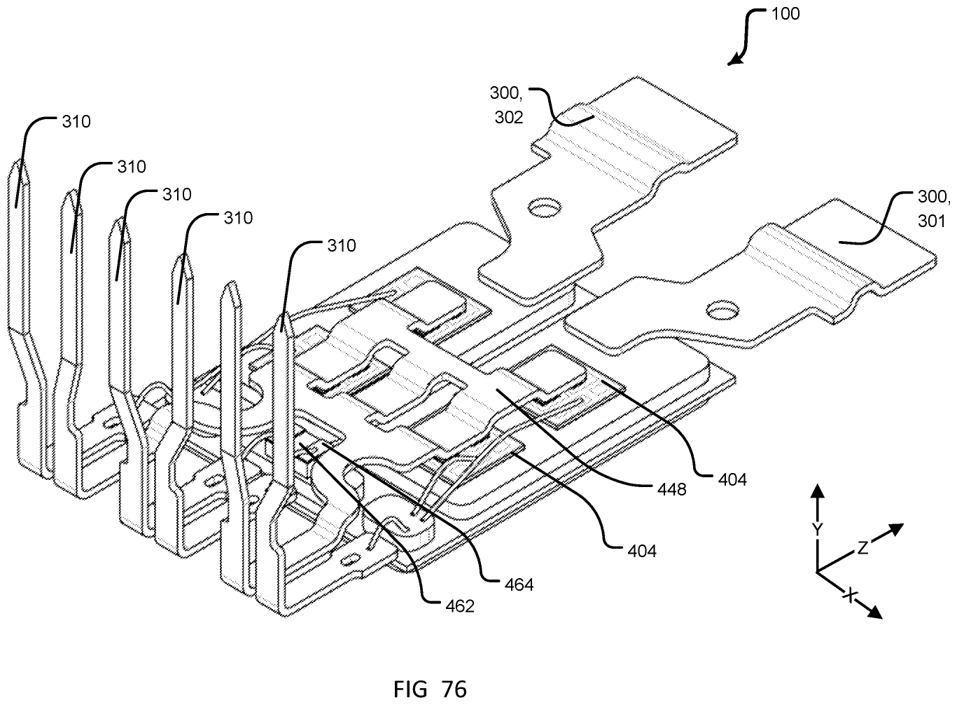

FIG. 76 illustrates a partial perspective view of the power package of FIG. 75.

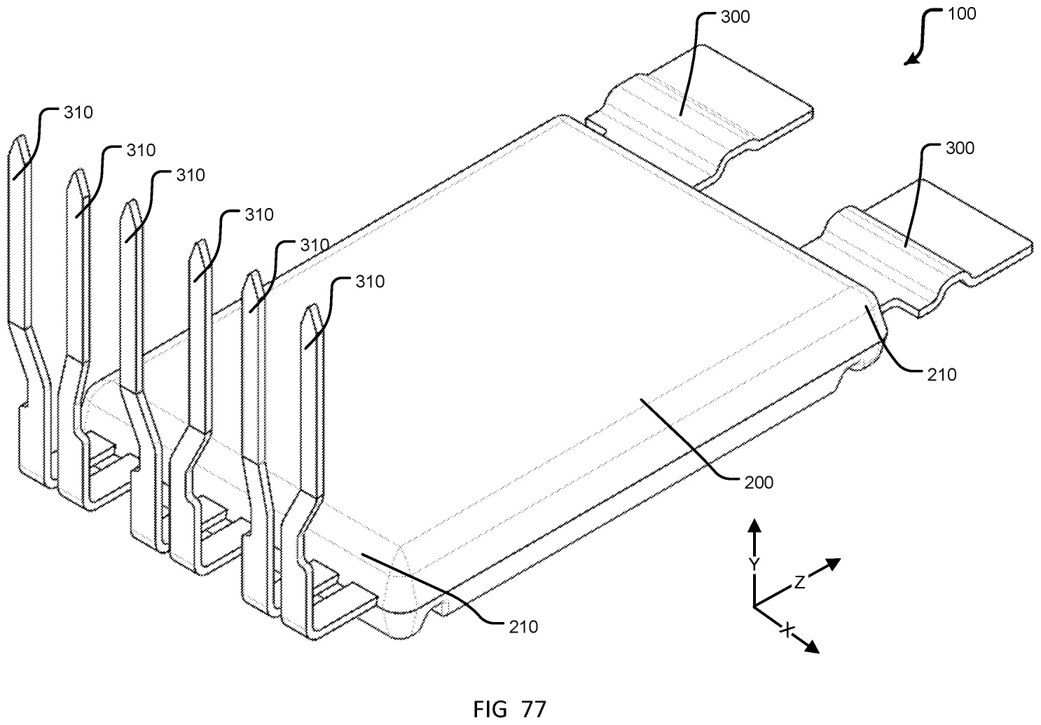

FIG. 77 illustrates a partial perspective view of the power package of FIG. 75.

With reference to FIG. 75, FIG. 76, and FIG. 77, in some implementation cases of the power package 100, sensors may be added to improve product functionality and provide more insight into what is occurring inside of the power package 100 as previously discussed. These sensors may include but are not limited to overcurrent/desaturation, temperature, current, strain, and/or the like.

Sensors come in a variety of formats, some requiring electrical isolation, and some have their own isolation. Most need one or two dedicated signal pins to operate. It should be noted that specific implementation will depend on the type of sensor. In some cases, voltage clearance and creepage distance is not necessary, as it is biased to the same voltage as the other signal pins. In other cases, it may require isolation.

As illustrated in FIG. 75, the power package 100 may include sensor bonds 464 arranged on a sensor 462. Additionally, the sensor 462 may be connected to one or more implementations of the plurality of signal terminals 310 as previously discussed.

Accordingly, the disclosure has set forth a power electronics packages implementing layouts, structures, and/or configurations that can provide increased functionality and/or capability.

The following are a number of nonlimiting EXAMPLES of aspects of the disclosure.

One EXAMPLE: a power package includes a power substrate. The power package in addition includes a first power device on the power substrate. The package moreover includes a housing having housing sides includes at least a first housing side and a second housing side, the housing configured to house at least the power substrate and the first power device. The package also includes a plurality of power terminals extending from at least one of the housing sides. The package further includes the plurality of power terminals includes at least a first power terminal and a second power terminal. The package in addition includes a plurality of signal terminals extending from at least one of the housing sides. The package moreover includes the plurality of signal terminals includes at least a source kelvin signal terminal, a gate driver signal terminal, and at least one additional signal terminal.

The above-noted EXAMPLE may further include any one or a combination of more than one of the following EXAMPLES:

The power package of the above-noted EXAMPLE where the first power terminal extends from the first housing side and the second power terminal extends from the second housing side; and where at least one of the plurality of signal terminals extends from the first housing side and at least one of the plurality of signal terminals extends from the second housing side. The power package of the above-noted EXAMPLE where the first power terminal extends from the first housing side and the second power terminal extends from the second housing side; and where at least two of the plurality of signal terminals extend from the first housing side and at least two of the plurality of signal terminals extend from the second housing side. The configuration of the above-noted EXAMPLE where the plurality of implementations of the power package are arranged in a bridge leg configuration topology. The configuration of the above-noted EXAMPLE where the plurality of implementations of the power package are arranged in a plurality of paralleled bridge leg configuration topologies. The power package of the above-noted EXAMPLE where at least one implementation of the at least one additional signal terminal is configured as an overcurrent/desaturation signal terminal configured to provide overcurrent signals and/or desaturation signals. The power package of the above-noted EXAMPLE where the overcurrent/desaturation signal terminal is connected to a drain pad on the power substrate. The power package of the above-noted EXAMPLE where the overcurrent/desaturation signal terminal is configured to allow a gate driver and/or measurement/instrumentation circuitry to monitor a voltage across a switch position. The power package of the above-noted EXAMPLE where at least one implementation of the at least one additional signal terminal is configured as a current sensing signal terminal; and where the current sensing signal terminal is connected to a current sensor. The power package of the above-noted EXAMPLE where the current sensing signal terminal includes two current sensing terminals. The power package of the above-noted EXAMPLE where the current sensor includes an integrated current sensor implemented with at least one implementation of the first power device. The power package of the above-noted EXAMPLE where the current sensor includes an on-chip current sensor implemented in at least one implementation of the first power device. The power package of the above-noted EXAMPLE where at least one implementation of the at least one additional signal terminal is configured as a temperature sensing terminal. The power package of the above-noted EXAMPLE where the temperature sensing terminal includes two temperature sensing terminals. The power package of the above-noted EXAMPLE where the temperature sensing terminal is connected to a temperature sensor includes: an on-chip temperature sensor implemented with at least one implementation of the first power device, an isolated temperature sensor, a non-isolated temperature sensor, and/or a temperature sensing device integrated with the power substrate. The power package of the above-noted EXAMPLE where at least one implementation of the at least one additional signal terminal is connected to a strain gauge. The power package of the above-noted EXAMPLE where the plurality of signal terminals are symmetrically arranged on the housing sides. The power package of the above-noted EXAMPLE where the plurality of signal terminals are asymmetrically arranged on the housing sides. The power package of the above-noted EXAMPLE where all of the plurality of signal terminals are symmetrically arranged on either the first housing side or the second housing side. The power package of the above-noted EXAMPLE where all of the plurality of signal terminals are asymmetrically arranged on either the first housing side or the second housing side. The power package of the above-noted EXAMPLE where the first power terminal extends from the first housing side and the second power terminal extends from the second housing side; and where all of the plurality of signal terminals extend from the second housing side. The power package of the above-noted EXAMPLE where all of the plurality of signal terminals are on either the first housing side or the second housing side; and where all of the plurality of signal terminals are on a side of one of plurality of power terminals. The power package of the above-noted EXAMPLE where all of the plurality of signal terminals are on either the first housing side or the second housing side; and where all of the plurality of signal terminals are on both sides of one of the plurality of power terminals. The configuration of the above-noted EXAMPLE where all of the plurality of signal terminals of the at least two implementations of the power package are arranged to be clustered along adjacent corners of the at least two implementations of the power package. The power package of the above-noted EXAMPLE further being configured with a common source topology where: the first power terminal extends from the first housing side; the second power terminal extends from the second housing side; a first implementation of the plurality of signal terminals extends from the first housing side; and a second implementation of the plurality of signal terminals extends from the second housing side. The power package of the above-noted EXAMPLE where the first implementation of the plurality of signal terminals is arranged adjacent a third housing side; and where the second implementation of the plurality of signal terminals is arranged adjacent the third housing side. The power package of the above-noted EXAMPLE where the first implementation of the plurality of signal terminals is arranged adjacent a third housing side; and where the second implementation of the plurality of signal terminals is arranged adjacent a fourth housing side. The power package of the above-noted EXAMPLE further being configured with a half-bridge topology where: the plurality of power terminals includes at least a third power terminal; the third power terminal extending from the first housing side; the first power terminal extends from the first housing side; the second power terminal extends from the second housing side; a first implementation of the plurality of signal terminals extends from the first housing side; and a second implementation of the plurality of signal terminals extends from the second housing side. The power package of the above-noted EXAMPLE includes a creepage extender arranged on the first housing side between the third power terminal and the first power terminal. The power package of the above-noted EXAMPLE includes a support sleeve configured to surround and mechanically support at least one of plurality of signal terminals. The power package of the above-noted EXAMPLE further being configured with a common source topology. The power package of the above-noted EXAMPLE where: the first power terminal extends from the first housing side; the second power terminal extends from the first housing side; and the plurality of signal terminals extend from the second housing side. The power package of the above-noted EXAMPLE where: a first implementation of the plurality of signal terminals extends from the first housing side; a second implementation of the plurality of signal terminals extends from the second housing side; the first implementation of the plurality of signal terminals is arranged adjacent a third housing side; and the second implementation of the plurality of signal terminals is arranged adjacent the third housing side. The power package of the above-noted EXAMPLE includes a cascode configuration includes at least one cascode transistor connected in series with the first power device. The power package of the above-noted EXAMPLE where the at least one cascode transistor is stacked on the first power device. The power package of the above-noted EXAMPLE where the cascode configuration includes an electrical connection between the cascode transistor and the first power device. The power package of the above-noted EXAMPLE where: the power substrate includes a first power trace and a second power trace; the first power device includes the first power device on the first power trace; and the first power device includes a second power device on the second power trace. The power package of the above-noted EXAMPLE where the power substrate further includes a first signal trace and a second signal trace; and where the first signal trace and the second signal trace are configured to reduce a wire bond length. The power package of the above-noted EXAMPLE where the first signal trace and the second signal trace are configured as gate bond pads. The power package of the above-noted EXAMPLE where the first signal trace and the second signal trace are configured to accommodate sensing elements. The power package of the above-noted EXAMPLE where the first signal trace and the second signal trace are on opposite ends of the power substrate. The power package of the above-noted EXAMPLE where the plurality of power terminals includes a laterally extending offset portion. The power package of the above-noted EXAMPLE where the plurality of power terminals are further arranged at different elevations for interconnection with another power package. The power package of the above-noted EXAMPLE where the interconnection with the another power package includes an interleaved power connection. The power package of the above-noted EXAMPLE where the plurality of power terminals further includes a bent strain relieving portion. The t-type topology configuration of the above-noted EXAMPLE the T-Type topology configuration includes: a plurality of implementations of the power package configured with a common source topology; and a plurality of implementations of the power package configured with a half bridge topology. The system of the above-noted EXAMPLE where the plurality of implementations of the T-Type topology configuration are arranged in parallel. The system of the above-noted EXAMPLE the system includes a cold plate, where the plurality of implementations of the power package are on the cold plate. The power package of the above-noted EXAMPLE where the plurality of implementations of the power package are on multiple sides of the cold plate. The power package of the above-noted EXAMPLE where the cold plate further includes through holes configured to allow one or more of the plurality of power terminals of the plurality of implementations of the power package to extend. The power package of the above-noted EXAMPLE includes a source clip, where the source clip is configured to connect between a first implementation of the first power device and second implementation of the first power device. The power package of the above-noted EXAMPLE includes a source clip, where the source clip is configured to connect between first implementations of the first power device and second implementations of the first power device. The power package of the above-noted EXAMPLE where the source kelvin signal terminal is implemented with a true source kelvin configuration. The power package of the above-noted EXAMPLE where the source kelvin signal terminal is implemented with a pseudo source kelvin configuration. The power package of the above-noted EXAMPLE where the first power device includes at least one of the following: at least one MOSFET (metal-oxide-semiconductor field-effect transistor), at least one IGBT (insulated-gate bipolar transistor), and/or at least one JFET (Junction Field Effect Transistor). The power package of the above-noted EXAMPLE further being configured to implement one of the following topologies: a single switch topology, a half bridge topology, a full bridge topology, a common source topology, a common drain topology, a three phase bridge topology, a 3 level inverter T-Type topology, a 3 level inverter NPC (neutral point clamped) topology, a 3 level inverter VSC (voltage source converter) topology, a buck topology, a boost topology, a buck-boost topology, or a Ćuk topology.

One EXAMPLE: a power package includes a power substrate. The power package in addition includes a first power device on the power substrate. The package moreover includes a housing having housing sides includes at least a first housing side and a second housing side, the housing 200 configured to house at least the power substrate and the first power device. The package also includes a plurality of power terminals extending from at least one of the housing sides. The package further includes the plurality of power terminals includes at least a first power terminal and a second power terminal. The package in addition includes a plurality of signal terminals extending from at least one of the housing sides. The package moreover includes the plurality of signal terminals includes at least a source kelvin signal terminal and a gate driver signal terminal. The package also includes a common source connection connected between the first power device and a second power device.

The above-noted EXAMPLE may further include any one or a combination of more than one of the following EXAMPLES:

The power package of the above-noted EXAMPLE where: the first power terminal extends from the first housing side; the second power terminal extends from the first housing side; and the plurality of signal terminals extend from the second housing side. The power package of the above-noted EXAMPLE where the first power terminal extends from the first housing side and the second power terminal extends from the second housing side; and where at least one of the plurality of signal terminals extends from the first housing side and at least one of the plurality of signal terminals extends from the second housing side. The power package of the above-noted EXAMPLE where: a first implementation of the plurality of signal terminals extends from the first housing side; a second implementation of the plurality of signal terminals extends from the second housing side; the first implementation of the plurality of signal terminals is arranged adjacent a third housing side; and the second implementation of the plurality of signal terminals is arranged adjacent the third housing side. The power package of the above-noted EXAMPLE includes a cascode configuration includes at least one cascode transistor connected in series with the first power device. The power package of the above-noted EXAMPLE where the at least one cascode transistor is stacked on the first power device. The power package of the above-noted EXAMPLE where the cascode configuration includes an electrical connection between the cascode transistor and the first power device. The power package of the above-noted EXAMPLE where: the power substrate includes a first power trace and a second power trace; the first power device includes the first power device on the first power trace; and the first power device includes the second power device on the second power trace. The power package of the above-noted EXAMPLE where the power substrate further includes a first signal trace and a second signal trace; and where the first signal trace and the second signal trace are configured to reduce a wire bond length. The power package of the above-noted EXAMPLE where the first signal trace and the second signal trace are configured as gate bond pads. The power package of the above-noted EXAMPLE where the first signal trace and the second signal trace are configured to accommodate sensing elements. The power package of the above-noted EXAMPLE where the first signal trace and the second signal trace are on opposite ends of the power substrate. The power package of the above-noted EXAMPLE where the plurality of power terminals includes a laterally extending offset portion. The power package of the above-noted EXAMPLE where the plurality of power terminals are further arranged at different elevations for interconnection with another power package. The power package of the above-noted EXAMPLE where the interconnection with the another power package includes an interleaved power connection. The power package of the above-noted EXAMPLE where the plurality of power terminals further includes a bent strain relieving portion. The t-type topology configuration of the above-noted EXAMPLE the T-Type topology configuration includes: a plurality of implementations of the power package configured with a common source topology; and a plurality of implementations of the power package configured with a half bridge topology. The system of the above-noted EXAMPLE where the plurality of implementations of the T-Type topology configuration are arranged in parallel. The system of the above-noted EXAMPLE the system includes a cold plate, where the plurality of implementations of the power package are on the cold plate. The power package of the above-noted EXAMPLE where the plurality of implementations of the power package are on multiple sides of the cold plate. The power package of the above-noted EXAMPLE where the cold plate further includes through holes configured to allow one or more of the plurality of power terminals of the plurality of implementations of the power package to extend. The power package of the above-noted EXAMPLE includes a source clip, where the source clip is configured to connect between a first implementation of the first power device and second implementation of the first power device. The power package of the above-noted EXAMPLE includes a source clip, where the source clip is configured to connect between first implementations of the first power device and second implementations of the first power device. The power package of the above-noted EXAMPLE where the first power terminal extends from the first housing side and the second power terminal extends from the second housing side; and where at least two of the plurality of signal terminals extend from the first housing side and at least two of the plurality of signal terminals extend from the second housing side. The configuration of the above-noted EXAMPLE where the plurality of implementations of the power package are arranged in a bridge leg configuration topology. The configuration of the above-noted EXAMPLE where the plurality of implementations of the power package are arranged in a plurality of paralleled bridge leg configuration topologies. The power package of the above-noted EXAMPLE where the plurality of signal terminals further includes at least one additional signal terminal; and where at least one implementation of the at least one additional signal terminal is configured as an overcurrent/desaturation signal terminal configured to provide overcurrent signals and/or desaturation signals. The power package of the above-noted EXAMPLE where the overcurrent/desaturation signal terminal is connected to a drain pad on the power substrate. The power package of the above-noted EXAMPLE where the overcurrent/desaturation signal terminal is configured to allow a gate driver and/or measurement/instrumentation circuitry to monitor a voltage across a switch position. The power package of the above-noted EXAMPLE where the plurality of signal terminals further includes at least one additional signal terminal; and where at least one implementation of the at least one additional signal terminal is configured as a current sensing signal terminal; and where the current sensing signal terminal is connected to a current sensor. The power package of the above-noted EXAMPLE where the current sensing signal terminal includes two current sensing terminals. The power package of the above-noted EXAMPLE where the current sensor includes an integrated current sensor implemented with at least one implementation of the first power device. The power package of the above-noted EXAMPLE where the current sensor includes an on-chip current sensor implemented in at least one implementation of the first power device. The power package of the above-noted EXAMPLE where the plurality of signal terminals further includes at least one additional signal terminal; and where at least one implementation of the at least one additional signal terminal is configured as a temperature sensing terminal. The power package of the above-noted EXAMPLE where the temperature sensing terminal includes two temperature sensing terminals. The power package of the above-noted EXAMPLE where the temperature sensing terminal is connected to a temperature sensor includes: an on-chip temperature sensor implemented with at least one implementation of the first power device, an isolated temperature sensor, a non-isolated temperature sensor, and/or a temperature sensing device integrated with the power substrate. The power package of the above-noted EXAMPLE where the plurality of signal terminals further includes at least one additional signal terminal; and where at least one implementation of the at least one additional signal terminal is connected to a strain gauge. The power package of the above-noted EXAMPLE where the plurality of signal terminals are symmetrically arranged on the housing sides. The power package of the above-noted EXAMPLE where the plurality of signal terminals are asymmetrically arranged on the housing sides. The power package of the above-noted EXAMPLE where all of the plurality of signal terminals are symmetrically arranged on either the first housing side or the second housing side. The power package of the above-noted EXAMPLE where all of the plurality of signal terminals are asymmetrically arranged on either the first housing side or the second housing side. The power package of the above-noted EXAMPLE where the first power terminal extends from the first housing side and the second power terminal extends from the second housing side; and where all of the plurality of signal terminals extend from the second housing side. The power package of the above-noted EXAMPLE where all of the plurality of signal terminals are on either the first housing side or the second housing side; and where all of the plurality of signal terminals are on a side of one of plurality of power terminals. The power package of the above-noted EXAMPLE where all of the plurality of signal terminals are on either the first housing side or the second housing side; and where all of the plurality of signal terminals are on both sides of one of the plurality of power terminals. The configuration of the above-noted EXAMPLE where all of the plurality of signal terminals of the at least two implementations of the power package are arranged to be clustered along adjacent corners of the at least two implementations of the power package. The power package of the above-noted EXAMPLE further being configured with a common source topology where: the first power terminal extends from the first housing side; the second power terminal extends from the second housing side; a first implementation of the plurality of signal terminals extends from the first housing side; and a second implementation of the plurality of signal terminals extends from the second housing side. The power package of the above-noted EXAMPLE where the first implementation of the plurality of signal terminals is arranged adjacent a third housing side; and where the second implementation of the plurality of signal terminals is arranged adjacent the third housing side. The power package of the above-noted EXAMPLE where the first implementation of the plurality of signal terminals is arranged adjacent a third housing side; and where the second implementation of the plurality of signal terminals is arranged adjacent a fourth housing side. The power package of the above-noted EXAMPLE further being configured with a half-bridge topology where: the plurality of power terminals includes at least a third power terminal; the third power terminal extending from the first housing side; the first power terminal extends from the first housing side; the second power terminal extends from the second housing side; a first implementation of the plurality of signal terminals extends from the first housing side; and a second implementation of the plurality of signal terminals extends from the second housing side. The power package of the above-noted EXAMPLE includes a creepage extender on the first housing side between the third power terminal and the first power terminal. The power package of the above-noted EXAMPLE includes a support sleeve configured to surround and mechanically support at least one of plurality of signal terminals. The power package of the above-noted EXAMPLE where the source kelvin signal terminal is implemented with a true source kelvin configuration. The power package of the above-noted EXAMPLE where the source kelvin signal terminal is implemented with a pseudo source kelvin configuration. The power package of the above-noted EXAMPLE where the first power device includes at least one of the following: at least one MOSFET (metal-oxide-semiconductor field-effect transistor), at least one IGBT (insulated-gate bipolar transistor), and/or at least one JFET (Junction Field Effect Transistor).

Moreover, the power package 100 may be implemented in numerous circuit topologies including a single switch configuration, half bridge configuration, full bridge configuration, three phase bridge configuration (also called a six pack), buck configuration, boost configuration, buck-boost configuration, ćuk configuration, a common source configuration, a common drain configuration, a neutral point clamp configuration, and/or the like. Applications of the power package 100 may include a power system, a motor system, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, and electric vehicles (EVs), a converter, motor drives, solar inverters, circuit breakers, protection circuits, DC-DC converters, and/or the like.

Aspects of the disclosure have been described above with reference to the accompanying drawings, in which aspects of the disclosure are shown. It will be appreciated, however, that this disclosure may, however, be embodied in many different forms and should not be construed as limited to the aspects set forth above. Rather, these aspects are provided so that this disclosure will be thorough and complete, and will fully convey the scope of the disclosure to those skilled in the art. Additionally, the various aspects described may be implemented separately. Moreover, one or more the various aspects described may be combined. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the disclosure. The term “and/or” includes any and all combinations of one or more of the associated listed items.

The terminology used herein is for the purpose of describing particular aspects only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Aspects of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical aspects of the disclosure and, although specific terms are employed, they are used in a generic and descriptive sense only and not for purposes of limitation, the scope of the disclosure being set forth in the following claims.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure. In this regard, the various aspects, features, components, elements, modules, arrangements, circuits, and the like are contemplated to be interchangeable, mixed, matched, combined, and the like. In this regard, the different features of the disclosure are modular and can be mixed and matched with each other.

1. A power package comprising:
a power substrate;
a first power device on the power substrate;
a housing having housing sides comprising at least a first housing side and a second housing side, the housing configured to house at least the power substrate and the first power device;
a plurality of power terminals extending from at least one of the housing sides;
the plurality of power terminals comprising at least a first power terminal and a second power terminal;
a plurality of signal terminals extending from at least one of the housing sides; and
the plurality of signal terminals comprising at least a source kelvin signal terminal, a gate driver signal terminal, and at least one additional signal terminal.

2. The power package according to claim 1
wherein the first power terminal extends from the first housing side and the second power terminal extends from the second housing side; and
wherein at least one of the plurality of signal terminals extends from the first housing side and at least one of the plurality of signal terminals extends from the second housing side.

3. The power package according to claim 1
wherein the first power terminal extends from the first housing side and the second power terminal extends from the second housing side; and
wherein at least two of the plurality of signal terminals extend from the first housing side and at least two of the plurality of signal terminals extend from the second housing side.

4. A configuration of a plurality of implementations of the power package of claim 1, wherein the plurality of implementations of the power package are arranged in a bridge leg configuration topology.

5. A configuration of a plurality of implementations of the power package of claim 1, wherein the plurality of implementations of the power package are arranged in a plurality of paralleled bridge leg configuration topologies.

6. The power package according to claim 1
wherein at least one implementation of the at least one additional signal terminal is configured as an overcurrent/desaturation signal terminal configured to provide overcurrent signals and/or desaturation signals.

7. The power package according to claim 6 wherein the overcurrent/desaturation signal terminal is connected to a drain pad on the power substrate.

8. The power package according to claim 6 wherein the overcurrent/desaturation signal terminal is configured to allow a gate driver and/or measurement/instrumentation circuitry to monitor a voltage across a switch position.

9. The power package according to claim 1
wherein at least one implementation of the at least one additional signal terminal is configured as a current sensing signal terminal; and
wherein the current sensing signal terminal is connected to a current sensor.

10. The power package according to claim 9 wherein the current sensing signal terminal comprises two current sensing terminals.

11. The power package according to claim 9 wherein the current sensor comprises an integrated current sensor implemented with at least one implementation of the first power device.

12. The power package according to claim 9 wherein the current sensor comprises an on-chip current sensor implemented in at least one implementation of the first power device.

13. The power package according to claim 1 wherein at least one implementation of the at least one additional signal terminal is configured as a temperature sensing terminal.

14. The power package according to claim 13 wherein the temperature sensing terminal comprises two temperature sensing terminals.

15. The power package according to claim 13 wherein the temperature sensing terminal is connected to a temperature sensor comprising: an on-chip temperature sensor implemented with at least one implementation of the first power device, an isolated temperature sensor, a non-isolated temperature sensor, and/or a temperature sensing device integrated with the power substrate.

16. The power package according to claim 1 wherein at least one implementation of the at least one additional signal terminal is connected to a strain gauge.

17. The power package according to claim 1 wherein the plurality of signal terminals are symmetrically arranged on the housing sides.

18. The power package according to claim 1 wherein the plurality of signal terminals are asymmetrically arranged on the housing sides.

19. The power package according to claim 1 wherein all of the plurality of signal terminals are symmetrically arranged on either the first housing side or the second housing side.

20. The power package according to claim 1 wherein all of the plurality of signal terminals are asymmetrically arranged on either the first housing side or the second housing side.

21. The power package according to claim 1
wherein the first power terminal extends from the first housing side and the second power terminal extends from the second housing side; and
wherein all of the plurality of signal terminals extend from the second housing side.

22. The power package according to claim 1
wherein all of the plurality of signal terminals are on either the first housing side or the second housing side; and
wherein all of the plurality of signal terminals are on a side of one of plurality of power terminals.

23. The power package according to claim 1
wherein all of the plurality of signal terminals are on either the first housing side or the second housing side; and
wherein all of the plurality of signal terminals are on both sides of one of the plurality of power terminals.

24. A configuration of at least two implementations of the power package of claim 1,
wherein all of the plurality of signal terminals of the at least two implementations of the power package are arranged to be clustered along adjacent corners of the at least two implementations of the power package.

25. The power package according to claim 1 further being configured with a common source topology wherein:
the first power terminal extends from the first housing side;
the second power terminal extends from the second housing side;
a first implementation of the plurality of signal terminals extends from the first housing side; and
a second implementation of the plurality of signal terminals extends from the second housing side.

26.-29. (canceled)

30. The power package according to claim 1 further comprising a support sleeve configured to surround and mechanically support at least one of plurality of signal terminals.

31.-36. (canceled)

37. The power package according to claim 1 further comprising a cascode configuration comprising at least one cascode transistor connected in series with the first power device.

38. The power package according to claim 37 wherein the at least one cascode transistor is stacked on the first power device.

39. The power package according to claim 37 wherein the cascode configuration comprises an electrical connection between the cascode transistor and the first power device.

40. The power package according to claim 1 further comprising a second power device,
wherein:
the power substrate comprises a first power trace and a second power trace;
the first power device is on the first power trace; and
the second power device is on the second power trace.

41.-48. (canceled)

49. A T-Type topology configuration of a plurality of paralleled implementations of the power package of claim 1, the T-Type topology configuration comprising:
a plurality of implementations of the power package configured with a common source topology; and
a plurality of implementations of the power package configured with a half bridge topology.

50. A system comprising a plurality of implementations of the T-Type topology configuration of claim 49, wherein the plurality of implementations of the T-Type topology configuration are arranged in parallel.

51.-61. (canceled)

62. A power package configured comprising:
a power substrate;
a first power device on the power substrate;
a housing having housing sides comprising at least a first housing side and a second housing side, the housing configured to house at least the power substrate and the first power device;
a plurality of power terminals extending from at least one of the housing sides;
the plurality of power terminals comprising at least a first power terminal and a second power terminal;
a plurality of signal terminals extending from at least one of the housing sides; and
the plurality of signal terminals comprising at least a source kelvin signal terminal and a gate driver signal terminal; and
a common source connection connected between the first power device and a second power device.

63.-121. (canceled)
